(19) United States
(12) Patent Application Publication
(10) Pub. No.: US 2019/0165541 A1
(43) Pub. Date: May 30, 2019

(54) OPTICAL SEMICONDUCTOR INTEGRATED DEVICE, METHOD OF MANUFACTURING OPTICAL SEMICONDUCTOR INTEGRATED DEVICE, AND OPTICAL COMMUNICATION SYSTEM

(71) Applicant: RENESAS ELECTRONICS CORPORATION, Tokyo (JP)

(72) Inventors: Isao WATANABE, Tokyo (JP); Masahide KOBAYASHI, Tokyo (JP); Junichiro SHIMIZU, Tokyo (JP)

(21) Appl. No.: 16/151,124

(22) Filed: Oct. 3, 2018

(30) Foreign Application Priority Data
Nov. 30, 2017 (JP) 2017-230156

(51) Int. Cl. H01S 5/00; H01S 5/026

(52) U.S. Cl. CPC H01S 5/0085; H01S 5/026

(57) ABSTRACT

A laser element and a modulator element respectively include first and second mesa portions provided to be connected above a substrate. The first and second mesa portions are formed using individual mask films (dielectric masks). In the first mesa portion, a p-type first clad layer not containing Al as the uppermost layer thereof covers the upper surface and each of the side surfaces of a multi-layer body (including an n-type optical guide layer, an active layer, a p-type optical guide layer, and a p-type semiconductor layer). In the first mesa portion, the multi-layer body including the semiconductor layers containing Al is covered with the p-type first clad layer not containing Al. This can prevent unneeded aluminum oxide from being generated and improve the crystallinities of the constituent layers of the second mesa portion. It is possible to maintain excellent optical coupling between the first and second mesa portions.

### CROSS-REFERENCE TO RELATED APPLICATIONS

The disclosure of Japanese Patent Application No. 2017-230156 filed on Nov. 30, 2017 including the specification, drawings and abstract is incorporated herein by reference in its entirety.

### BACKGROUND

The present invention relates to an optical semiconductor integrated device and can particularly be used appropriately as an optical semiconductor integrated device in which a semiconductor laser, a modulator element, and the like are monolithically integrated.

As an optical communication semiconductor laser (LD standing for Laser Diode) for use in an over 25 Gbps next-generation data center, a modulator-integrated semiconductor laser (EML standing for Electro-absorption-Modulator integrated Laser) is considered promising. The EML is a module in which a laser element and a modulator element are monolithically integrated and which converts an electric signal to an optical digital signal.

For example, each of Patent Documents 1 to 3 (Japanese Unexamined Patent Publication No. Hei 5(1993)-251812, Japanese Patent No. 5169534, and Japanese Patent No. 5314435) discloses a semiconductor laser using an InAlGaAs-based material.

Also, each of Patent Document 4 (Japanese Patent No. 4002422) and Patent Document 5 (Japanese Patent No. 3146821) discloses a semiconductor laser with an optical modulator.

### RELATED ART DOCUMENTS

### Patent Documents

### [Patent Document 1]

Japanese Unexamined Patent Publication No. Hei 5(1993)-251812

### [Patent Document 2]

Japanese Patent No. 5169534

### [Patent Document 3]

Japanese Patent No. 5314435

### [Patent Document 4]

Japanese Patent No. 4002422

### [Patent Document 5]

Japanese Patent No. 3146821

### SUMMARY

The present inventors have been engaged in the research and development of such an optical semiconductor integrated device (EML) as described above in which a semiconductor laser and a modulator element are monolithically integrated and have actively studied about improvements in the performance thereof. The EML has a laser element made of a multi-layer body including a plurality of semiconductor layers and a modulator element made of a multi-layer body including a plurality of semiconductor layers. By forming the laser element and the modulator element in the same substrate, the EML is formed.

These elements are optically coupled together, but are individually designed and made of the respective multi-layer bodies including the different semiconductor layers. Accordingly, when the laser element and the modulator element are formed in the same substrate, oxidation resulting from the exposure of the semiconductor layers at the end surfaces of the multi-layer bodies including the semiconductor layers leads to a problem, as will be described later in detail. Particularly when semiconductor layers containing Al (aluminum) are used as the semiconductor layers, oxidation of Al forms an unneeded oxide, which degrades the properties and reliabilities of the elements.

Therefore, it is desirable to find a configuration of an optical semiconductor integrated device which allows avoidance of exposure of the end surfaces of the multi-layer bodies including the semiconductor layers and a manufacturing method thereof.

Other problems and novel features of the present invention will become apparent from a statement in the present specification and the accompanying drawings.

The following is a brief description of the outline of a representative one of the embodiments disclosed in the present application.

An optical semiconductor integrated device shown in an embodiment disclosed in the present application includes a first mesa portion provided in a first area of a substrate and included in a laser element and a second mesa portion provided in a second area of the substrate and included in an element other than the laser. The first mesa portion includes a first multi-layer body including first to third semiconductor layers and a fourth semiconductor layer made of a group III-V compound semiconductor and covering an upper surface and each of side surfaces of the first multi-layer body. The first to third semiconductor layers contain an Al element as a constituent element.

A method of manufacturing the optical semiconductor integrated device shown in the embodiment disclosed in the present application is a method of manufacturing an optical semiconductor integrated device including a first mesa portion provided in a first area of a substrate and included in a laser element and a second mesa portion provided in a second area of the substrate and included in an element other than the laser. The first mesa portion and the second mesa portion are formed using individual mask films. When the first mesa portion is formed, a first multi-layer body including first to third semiconductor layers is formed, and an upper surface and each of side surfaces of the first multi-layer body are covered with a fourth semiconductor layer made of a group III-V compound semiconductor. The first to third semiconductor layers contain an Al element as a constituent element.

An optical semiconductor integrated device shown in each of the following representative embodiments disclosed in the present application allows improvements in the properties of the integrated elements and allows improvements in the properties of the optical semiconductor integrated device.

A method of manufacturing the optical semiconductor integrated device shown in each of the following representative embodiments disclosed in the present application allows an optical semiconductor integrated device with excellent properties to be manufactured.

### BRIEF DESCRIPTION OF THE DRAWINGS

FIGS. 1A and 1B are a perspective view and a cross-sectional view each showing respective configurations of mesa portions in an optical semiconductor integrated device in a first embodiment;

FIGS. 2A and 2B are views showing the characteristic features of a manufacturing process of mesa portions in an optical semiconductor integrated device in a second embodiment;

FIGS. 3A and 3B are views showing the characteristic features of the manufacturing process of the mesa portions in the optical semiconductor integrated device in the second embodiment;

FIGS. 4A to 4C are cross-sectional views showing a manufacturing process of an optical semiconductor integrated device in a comparative example;

FIG. 5 is a perspective view showing a manufacturing process of the optical semiconductor integrated device in the first embodiment;

FIG. 6 is a perspective view showing the manufacturing process of the optical semiconductor integrated device in the first embodiment;

FIG. 7 is a perspective view showing the manufacturing process of the optical semiconductor integrated device in the first embodiment;

FIG. 8 is a plan view showing the manufacturing process of the optical semiconductor integrated device in the first embodiment;

FIG. 9 is a cross-sectional view showing the manufacturing process of the optical semiconductor integrated device in the first embodiment;

FIG. 10 is a cross-sectional view showing the manufacturing process of the optical semiconductor integrated device in the first embodiment;

FIG. 11 is a cross-sectional view showing the manufacturing process of the optical semiconductor integrated device in the first embodiment;

FIG. 12 is a perspective view showing the manufacturing process of the optical semiconductor integrated device in the first embodiment;

FIG. 13 is a cross-sectional view showing the manufacturing process of the optical semiconductor integrated device in the first embodiment;

FIG. 14 is a cross-sectional view showing the manufacturing process of the optical semiconductor integrated device in the first embodiment;

FIG. 15 is a cross-sectional view showing the manufacturing process of the optical semiconductor integrated device in the first embodiment;

FIG. 16 is a perspective view showing the manufacturing process of the optical semiconductor integrated device in the first embodiment;

FIG. 17 is a plan view showing the manufacturing process of the optical semiconductor integrated device in the first embodiment;

FIG. 18 is a cross-sectional view showing the manufacturing process of the optical semiconductor integrated device in the first embodiment;

FIG. 19 is a cross-sectional view showing the manufacturing process of the optical semiconductor integrated device in the first embodiment;

FIG. 20 is a cross-sectional view showing the manufacturing process of the optical semiconductor integrated device in the first embodiment;

FIG. 21 is a perspective view showing the manufacturing process of the optical semiconductor integrated device in the first embodiment;

FIG. 22 is a cross-sectional view showing the manufacturing process of the optical semiconductor integrated device in the first embodiment;

FIG. 23 is a cross-sectional view showing the manufacturing process of the optical semiconductor integrated device in the first embodiment;

FIG. 24 is a cross-sectional view showing the manufacturing process of the optical semiconductor integrated device in the first embodiment;

FIG. 25 is a perspective view showing the manufacturing process of the optical semiconductor integrated device in the first embodiment;

FIG. 26 is a cross-sectional view showing the manufacturing process of the optical semiconductor integrated device in the first embodiment;

FIG. 27 is a cross-sectional view showing the manufacturing process of the optical semiconductor integrated device in the first embodiment;

FIG. 28 is a cross-sectional view showing the manufacturing process of the optical semiconductor integrated device in the first embodiment;

FIG. 29 is a perspective view showing the manufacturing process of the optical semiconductor integrated device in the first embodiment;

FIG. 30 is a cross-sectional view showing the manufacturing process of the optical semiconductor integrated device in the first embodiment;

FIG. 31 is a cross-sectional view showing the manufacturing process of the optical semiconductor integrated device in the first embodiment;

FIG. 32 is a cross-sectional view showing the manufacturing process of the optical semiconductor integrated device in the first embodiment;

FIG. 33 is a perspective view showing the manufacturing process of the optical semiconductor integrated device in the first embodiment;

FIG. 34 is a cross-sectional view showing the manufacturing process of the optical semiconductor integrated device in the first embodiment;

FIG. 35 is a cross-sectional view showing the manufacturing process of the optical semiconductor integrated device in the first embodiment;

FIG. 36 is a cross-sectional view showing the manufacturing process of the optical semiconductor integrated device in the first embodiment;

FIG. 37 is a perspective view showing the manufacturing process of the optical semiconductor integrated device in the first embodiment;

FIG. 38 is a cross-sectional view showing the manufacturing process of the optical semiconductor integrated device in the first embodiment;

FIG. 39 is a cross-sectional view showing the manufacturing process of the optical semiconductor integrated device in the first embodiment;

FIG. 40 is a cross-sectional view showing the manufacturing process of the optical semiconductor integrated device in the first embodiment;

FIG. 41 is a perspective view showing the manufacturing process of the optical semiconductor integrated device in the first embodiment;

FIG. 42 is a cross-sectional view showing the manufacturing process of the optical semiconductor integrated device in the first embodiment;

FIG. 43 is a cross-sectional view showing the manufacturing process of the optical semiconductor integrated device in the first embodiment;

FIG. 44 is a cross-sectional view showing the manufacturing process of the optical semiconductor integrated device in the first embodiment;

FIG. 45 is a perspective view showing the manufacturing process of the optical semiconductor integrated device in the first embodiment;

FIG. 46 is a cross-sectional view showing the manufacturing process of the optical semiconductor integrated device in the first embodiment;

FIG. 47 is a cross-sectional view showing the manufacturing process of the optical semiconductor integrated device in the first embodiment;

FIG. 48 is a cross-sectional view showing the manufacturing process of the optical semiconductor integrated device in the first embodiment;

FIG. 49 is a graph showing the relationship between an InP growth temperature and a growth speed;

FIG. 50 is a perspective view showing the respective configurations of the mesa portions in the optical semiconductor integrated device in the second embodiment;

FIG. 51 is a cross-sectional view showing the configurations of the mesa portions in the optical semiconductor integrated device in the second embodiment;

FIG. 52 is a plan view showing the characteristic features of the manufacturing process of the mesa portions in the optical semiconductor integrated device in the second embodiment;

FIG. 53 is a plan view showing the characteristic features of the manufacturing process of the mesa portions in the optical semiconductor integrated device in the second embodiment;

FIG. 54 is a plan view showing the characteristic features of the manufacturing process of the mesa portions in the optical semiconductor integrated device in the second embodiment;

FIG. 55 is a perspective view showing the manufacturing process of the optical semiconductor integrated device in the second embodiment;

FIG. 56 is a perspective view showing the manufacturing process of the optical semiconductor integrated device in the second embodiment;

FIG. 57 is a perspective view showing the manufacturing process of the optical semiconductor integrated device in the second embodiment;

FIG. 58 is a plan view showing the manufacturing process of the optical semiconductor integrated device in the second embodiment;

FIG. 59 is a cross-sectional view showing the manufacturing process of the optical semiconductor integrated device in the second embodiment;

FIG. 60 is a cross-sectional view showing the manufacturing process of the optical semiconductor integrated device in the second embodiment;

FIG. 61 is a cross-sectional view showing the manufacturing process of the optical semiconductor integrated device in the second embodiment;

FIG. 62 is a cross-sectional view showing the manufacturing process of the optical semiconductor integrated device in the second embodiment;

FIG. 63 is a perspective view showing the manufacturing process of the optical semiconductor integrated device in the second embodiment;

FIG. 64 is a cross-sectional view showing the manufacturing process of the optical semiconductor integrated device in the second embodiment;

FIG. 65 is a cross-sectional view showing the manufacturing process of the optical semiconductor integrated device in the second embodiment;

FIG. 66 is a cross-sectional view showing the manufacturing process of the optical semiconductor integrated device in the second embodiment;

FIG. 67 is a cross-sectional view showing the manufacturing process of the optical semiconductor integrated device in the second embodiment;

FIG. 68 is a perspective view showing the manufacturing process of the optical semiconductor integrated device in the second embodiment;

FIG. 69 is a plan view showing the manufacturing process of the optical semiconductor integrated device in the second embodiment;

FIG. 70 is a cross-sectional view showing the manufacturing process of the optical semiconductor integrated device in the second embodiment;

FIG. 71 is a cross-sectional view showing the manufacturing process of the optical semiconductor integrated device in the second embodiment;

FIG. 72 is a cross-sectional view showing the manufacturing process of the optical semiconductor integrated device in the second embodiment;

FIG. 73 is a cross-sectional view showing the manufacturing process of the optical semiconductor integrated device in the second embodiment;

FIG. 74 is a perspective view showing the manufacturing process of the optical semiconductor integrated device in the second embodiment;

FIG. 75 is a cross-sectional view showing the manufacturing process of the optical semiconductor integrated device in the second embodiment;

FIG. 76 is a cross-sectional view showing the manufacturing process of the optical semiconductor integrated device in the second embodiment;

FIG. 77 is a cross-sectional view showing the manufacturing process of the optical semiconductor integrated device in the second embodiment;

FIG. 78 is a cross-sectional view showing the manufacturing process of the optical semiconductor integrated device in the second embodiment;

FIG. 79 is a perspective view showing the manufacturing process of the optical semiconductor integrated device in the second embodiment;

FIG. 80 is a plan view showing the manufacturing process of the optical semiconductor integrated device in the second embodiment;

FIG. 81 is a cross-sectional view showing the manufacturing process of the optical semiconductor integrated device in the second embodiment;

FIG. 82 is a cross-sectional view showing the manufacturing process of the optical semiconductor integrated device in the second embodiment;

FIG. 83 is a cross-sectional view showing the manufacturing process of the optical semiconductor integrated device in the second embodiment;

FIG. 84 is a cross-sectional view showing the manufacturing process of the optical semiconductor integrated device in the second embodiment;

FIG. 85 is a perspective view showing the manufacturing process of the optical semiconductor integrated device in the second embodiment;

FIG. 86 is a cross-sectional view showing the manufacturing process of the optical semiconductor integrated device in the second embodiment;

FIG. 87 is a cross-sectional view showing the manufacturing process of the optical semiconductor integrated device in the second embodiment;

FIG. 88 is a cross-sectional view showing the manufacturing process of the optical semiconductor integrated device in the second embodiment;

FIG. 89 is a cross-sectional view showing the manufacturing process of the optical semiconductor integrated device in the second embodiment;

FIG. 90 is a perspective view showing the manufacturing process of the optical semiconductor integrated device in the second embodiment;

FIG. 91 is a perspective view showing the manufacturing process of the optical semiconductor integrated device in the second embodiment;

FIG. 92 is a perspective view showing the manufacturing process of the optical semiconductor integrated device in the second embodiment;

FIG. 93 is a cross-sectional view showing the manufacturing process of the optical semiconductor integrated device in the second embodiment;

FIG. 94 is a cross-sectional view showing the manufacturing process of the optical semiconductor integrated device in the second embodiment;

FIG. 95 is a cross-sectional view showing the manufacturing process of the optical semiconductor integrated device in the second embodiment;

FIG. 96 is a cross-sectional view showing the manufacturing process of the optical semiconductor integrated device in the second embodiment;

FIG. 97 is a perspective view showing the manufacturing process of the optical semiconductor integrated device in the second embodiment;

FIG. 98 is a perspective view showing the manufacturing process of the optical semiconductor integrated device in the second embodiment;

FIG. 99 is a cross-sectional view showing the manufacturing process of the optical semiconductor integrated device in the second embodiment; and

FIG. 100 is a block diagram showing an example of an optical communication system using an optical semiconductor integrated device in a third embodiment.

### DETAILED DESCRIPTION

In the following embodiments, if necessary for the sake of convenience, each of the embodiments will be described by being divided into a plurality of sections or embodiments.

However, they are by no means irrelevant to each other unless particularly explicitly described otherwise, but are in relations such that one of the sections or embodiments is a modification, an application example, a detailed description, a supplementary description, and so forth of part or the whole of the others. Also, in the following embodiments, when the number and the like (including the number, numerical value, amount, range, and the like) of elements are mentioned, they are not limited to specific numbers unless particularly explicitly described otherwise or unless they are obviously limited to specific numbers in principle. The number and the like of the elements may be not less than or not more than specific numbers.

Also in the following embodiments, the components thereof (including also elements, steps, and the like) are not necessarily indispensable unless particularly explicitly described otherwise or unless the components are considered to be obviously indispensable in principle. Likewise, if the shapes, positional relationships, and the like of the components and the like are mentioned in the following embodiments, the shapes and the like are assumed to include those substantially proximate or similar thereto and the like unless particularly explicitly described otherwise or unless it can be considered that they obviously do not in principle. The same shall apply in regard to the foregoing number and the like (including the number, numerical value, amount, range, and the like).

The following will describe the embodiments in detail on the basis of the drawings. Note that, throughout all the drawings for illustrating the embodiments, members having the same functions are designated by the same or related reference numerals, and a repeated description thereof is omitted. When there are a plurality of similar members (portions), marks may be added to general reference numerals to show individual or specific portions. Also, in the following embodiments, a description of the same or like parts will not be repeated in principle unless particularly necessary.

In the drawings used in the embodiments, hatching may be omitted even in a cross-sectional view for improved clarity of illustration.

In each of the drawings (cross-sectional views, plan views, and perspective views), the sizes of individual portions do not correspond to those in a real device. For improved clarity of illustration, a specific portion may be shown in a relatively large size. Also, in each of the drawings (cross-sectional views, plan views, and perspective views), the corresponding portions may be shown in different sizes.

### First Embodiment

Referring to the drawings, the following will describe an optical semiconductor integrated device according to the present first embodiment. The optical semiconductor integrated device in the present first embodiment is an EML in which a laser element and a modulator element are monolithically integrated. The laser element and the modulator element have respective mesa portions M1 and M2 provided so as to be connected above a substrate.

Hereinbelow, a description will be given first of respective configurations of the mesa portions included in the optical semiconductor integrated device and a manufacturing process thereof and then of a configuration of the entire optical semiconductor integrated device and a manufacturing process thereof.

[Configurations and Manufacturing Process of Mesa Portions]

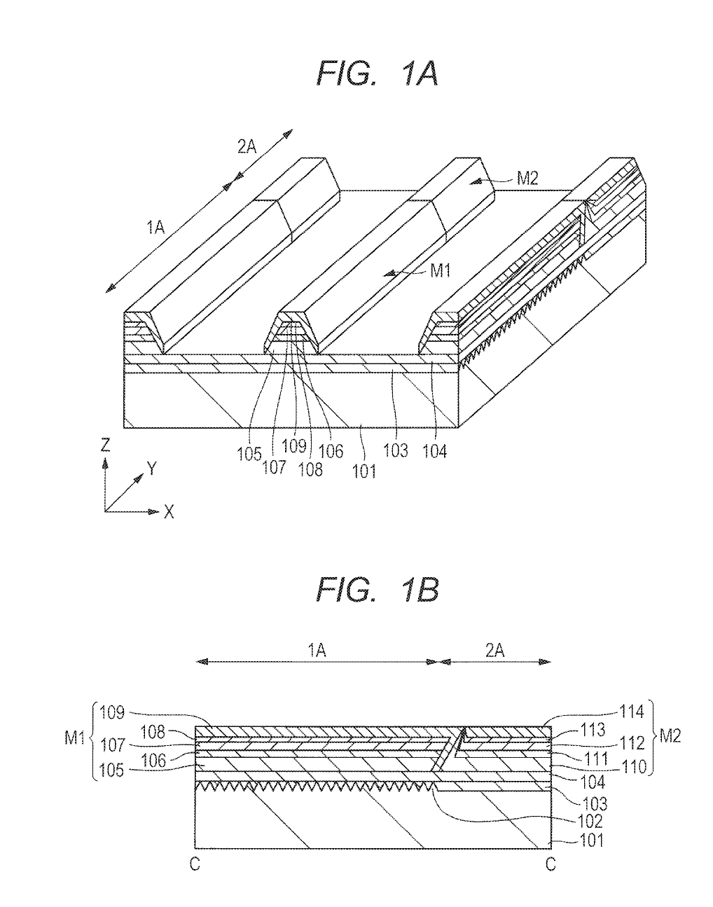

FIGS. 1A and 1B are a perspective view (perspective cross-sectional view) and a cross-sectional view each showing the configurations of the mesa portions of the optical semiconductor integrated device in the present first embodiment. FIG. 1A is the perspective view, while FIG. 1B is the cross-sectional view of each of the mesa portions (M1 and M2) shown in FIG. 1A along a Y-direction.

As shown in FIGS. 1A and 1B, a laser element (semiconductor laser element) is disposed in a first area 1A of a substrate 101, while a modulator element (modulator) is disposed in a second area 2A of the substrate 101. As described above, the laser element and the modulator element include the respective mesa portions M1 and M2 provided over the substrate 101. The mesa portion M1 has a structure in which an active layer 106 made of a group III-V compound semiconductor layer is interposed between group III-V compound semiconductor layers having opposite conductivity types and disposed as an upper layer and a lower layer.

On the other hand, the mesa portion M2 has a structure in which an absorption layer 111 made of a group III-V compound semiconductor layer is interposed between group III-V compound semiconductor layers having opposite conductivity types and disposed as an upper layer and a lower layer.

Specifically, the mesa portion M1 included in the laser element extends in the Y-direction and includes a multi-layer body in which an n-type optical guide layer 105, the active layer 106, a p-type optical guide layer 107, and a p-type semiconductor layer 108 are successively stacked in an upward direction and a p-type first clad layer (protective layer) covering the upper surface and each of the side surfaces of the multi-layer body.

Any of the n-type optical guide layer 105, the active layer 106, the p-type optical guide layer 107, and the p-type semiconductor layer 108 is made of a semiconductor layer containing Al, while the p-type first clad layer 109 is made of a semiconductor layer not containing Al. For example, the n-type optical guide layer 105, the active layer 106, the p-type optical guide layer 107, the p-type semiconductor layer 108, and the p-type first clad layer 109 are respectively made of an n-type AlGaInAs layer (105), an AlGaInAs layer (106), a p-type AlGaInAs layer (107), a p-type AlInAs layer (108), and a p-type InP layer (109).

The mesa portion M2 included in the modulator element extends in the Y-direction and includes a multi-layer body in which a modulator n-type optical guide layer 110, the absorption layer 111, a modulator p-type optical guide layer 112, and a modulator p-type semiconductor layer 113 are successively stacked in the upward direction and a modulator p-type first clad layer 114 covering the upper surface and each of the side surfaces of the multi-layer body.

Any of the modulator n-type optical guide layer 110, the absorption layer 111, the modulator p-type optical guide layer 112, and the modulator p-type semiconductor layer 113 is made of a semiconductor layer containing Al, while the modulator p-type first clad layer 114 is made of a semiconductor layer not containing Al. For example, the modulator n-type optical guide layer 110, the absorption layer 111, the modulator p-type optical guide layer 112, the modulator p-type semiconductor layer 113, and the modulator p-type first clad layer 114 are respectively made of an n-type AlGaInAs layer (110), an AlGaInAs layer (111), a p-type AlGaInAs layer (112), a p-type AlInAs layer (113), and a p-type InP layer (114).

The mesa portions M1 and M2 are formed to be connected such that at least the active layer 106 of the mesa portion M1 is continued to the absorption layer 111 of the mesa portion M2. In other words, the mesa portions M1 and M2 are optically coupled together. As a result, e.g., an optical signal is transmitted from the laser element to the modulator element. Note that, between the multi-layer body of the mesa portion M1 and the multi-layer body of the mesa portion M2, the p-type first clad layer 109 is disposed (FIG. 1B).

The mesa portions M1 and M2 are made of similar constituent layers, but the respective element composition ratios or film thicknesses of the individual layers included in the respective mesa portions may be different. For example, it is preferable to appropriately set an amount of lattice distortion for the absorption layer 111 and the amount of detuning of the optical absorption end wavelength of the active layer 106 from an LD oscillation wavelength. Thus, in order to satisfy the respective properties of the individual elements, the semiconductor layers included in the respective elements are individually adjusted and designed.

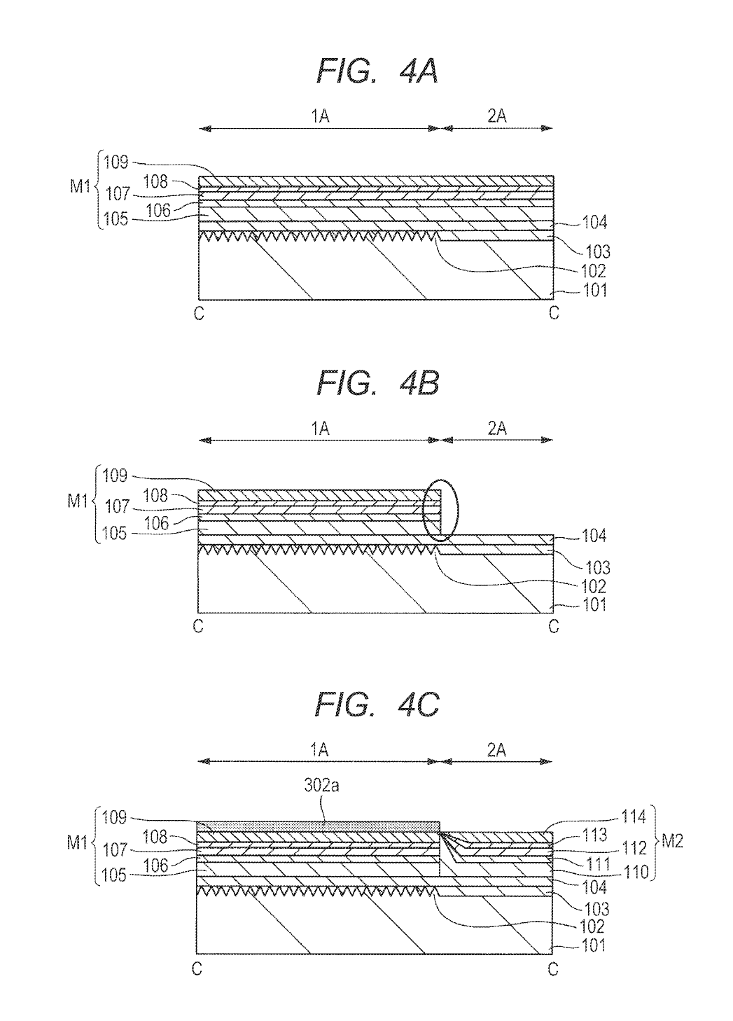

Accordingly, the mesa portions M1 and M2 are preferably formed in different configurations. However, in such a case as in a comparative example described later where the mesa portion M1 is formed and etched, and then the mesa portion M2 is formed, the semiconductor layers included in the mesa portion M1 and containing Al are exposed to form unneeded aluminum oxide. This degrades the property of optical coupling between the mesa portions M1 and M2 and also degrades the respective properties/reliabilities of the laser element and the modulator element (see FIG. 4).

By contrast, by adopting a configuration in which the mesa portions M1 and M2 are formed using individual mask films (dielectric masks) and the upper surface and each of the side surfaces of the foregoing multi-layer body are covered with the p-type first clad layer 109 not containing Al as the uppermost layer of the mesa portion M1, it is possible to prevent the foregoing unneeded aluminum oxide from being generated.

The following will describe a manufacturing process of the mesa portions with reference to the drawings.

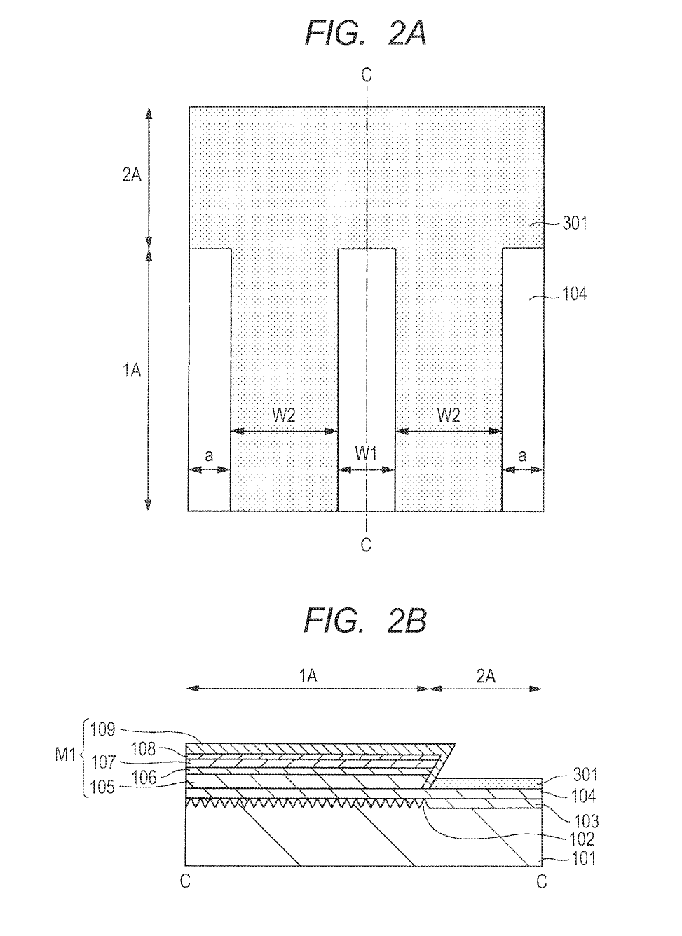

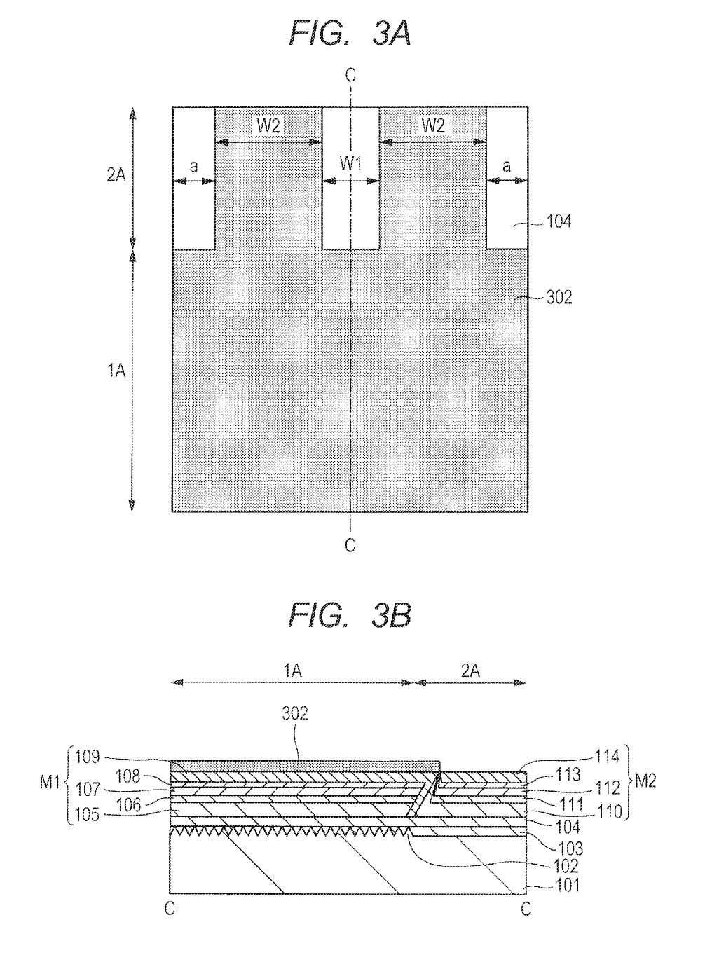

FIGS. 2A, 2B, 3A, and 3B are views showing the characteristic features of the manufacturing process of the mesa portions in the optical semiconductor integrated device in the present first embodiment. FIGS. 2A and 3A show plan views, while FIGS. 2B and 3B show cross-sectional views. Each of the cross-sectional views corresponds to a cross section along the line C-C in each of the plan views. FIGS. 4A to 4C are cross-sectional views showing a manufacturing process of an optical semiconductor integrated device in the comparative example.

First, as shown in FIG. 2A, over an n-type buffer layer (n-type InP layer) 104 over the substrate 101, a mask film 301 made of a silicon oxide film is formed and patterned to form the mask film 301 having an opening corresponding to the region of the first area 1A where the mesa portion M1 is to be formed. Patterning means etching a lower-layer film using a film having an intended shape as a mask and thus processing the lower-layer film into the intended shape.

Next, over the n-type buffer layer (n-type InP layer) 104 exposed from the opening of the mask film 301, the mesa portion M1 is formed (FIG. 2B). Specifically, over the n-type buffer layer (n-type InP layer) 104 exposed from the opening of the mask film 301, the n-type optical guide layer 105, the active layer 106, the p-type optical guide layer 107, and the p-type semiconductor layer 108 are successively grown to form a multi-layer body. Subsequently, over the upper surface and each of the side surfaces of the foregoing multi-layer body, the p-type first clad layer 109 is grown. Each of the layers can be formed by an MOVPE (Metal Organic Vapor Phase Epitaxy) method. In accordance with the MOVPE method, by changing raw-material gases, it is possible to continuously crystal-grow the individual layers included in the mesa portion. Then, the substrate 101 is retrieved from an MOVPE device, and the mask film (silicon oxide film) 301 over the substrate 101 is removed therefrom by etching.

For example, when the substrate 101 is retrieved from the MOVPE device, the substrate 101 may be exposed to atmosphere. Also, in a cleaning step or a drying step performed after the etching of the mask film (silicon oxide film) 301, the substrate 101 may come into contact with a cleaning liquid or a gas containing oxygen. In a temperature rising step during second growth also, the substrate 101 may be oxidized. When the multi-layer body made of the semiconductor layers containing Al is exposed in such a step, Al may be oxidized to generate unneeded aluminum oxide. However, in the present first embodiment, the upper surface and each of the side surfaces of the foregoing multi-layer body are covered with the p-type first clad layer 109, and therefore it is possible to prevent the unneeded aluminum oxide from being generated.

Next, as shown in FIG. 3A, a mask film 302 made of a silicon oxide film is formed over the mesa portion M1 and the n-type buffer layer (n-type InP layer) 104 each located over the substrate 101 and patterned to form the mask film 302 having an opening corresponding to the region of the second area 2A where the mesa portion M2 is to be formed.

Next, over the n-type buffer layer (n-type InP layer) 104 exposed from the opening of the mask film 302, the mesa portion M2 is formed (FIG. 3B). Specifically, over the n-type buffer layer (n-type InP layer) 104 exposed from the opening of the mask film 302, the modulator n-type optical guide layer 110, the absorption layer 111, the modulator p-type optical guide layer 112, and the modulator p-type semiconductor layer 113 are successively grown to form a multi-layer body.

Subsequently, over the upper surface and each of the side surfaces of the foregoing multi-layer body, the modulator p-type first clad layer 114 is formed. Each of the layers can be formed by an MOVPE method. Then, the substrate 101 is retrieved from the MOVPE device, and the mask film (silicon oxide film) 302 over the substrate 101 is removed therefrom by etching.

Thus, the mesa portion M1 in the first area 1A and the mesa portion M2 in the second area 2A can be formed.

By contrast, in the case in the comparative example (FIGS. 4A and 4B), e.g., a mask film having openings corresponding to the respective regions of the first area 1A and the second area 2A where the mesa portions (M1 and M2) are to be formed is formed and, over the n-type buffer layer (n-type InP layer) 104 exposed from the openings of the mask film, the mesa portions are formed. Specifically, over the n-type buffer layer 104 exposed from the openings of the mask film, the n-type optical guide layer 105, the active layer 106, the p-type optical guide layer 107, the p-type semiconductor layer 108, and the p-type first clad layer 109 are successively grown to form the mesa portions, as shown in FIG. 4A. Then, the mesa portion in the second area 2A is removed therefrom by etching (FIG. 4B).

Next, as shown in FIG. 4C, a mask film 302a having an opening corresponding to the region of the second area 2A where the mesa portion is to be formed is formed and, over the n-type buffer layer 104 exposed from the mask film 302a, the mesa portion M2 is formed. Specifically, over the n-type buffer layer 104 exposed from the opening of the mask film 302a, the modulator n-type optical guide layer 110, the absorption layer 111, the modulator p-type optical guide layer 112, the modulator p-type semiconductor layer 113, and the modulator p-type first clad layer 114 are successively grown. Then, the mask film (silicon oxide film) 302a over the substrate 101 is removed therefrom by etching.

In the case in the foregoing comparative example, during the etching for the mesa portion M1, the semiconductor layers containing Al (105 to 108) are exposed at the end surface of the mesa portion M1 (in the encircled portion in FIG. 4B). Upon retrieval of the substrate 101 from the MOVPE device described above or the like, the substrate 101 is exposed to atmosphere to form unneeded aluminum oxide. The aluminum oxide inhibits crystal growth of the constituent layers (110 to 114) of the mesa portion M2 and degrades the properties/reliabilities of the laser element and the modulator element. In addition, the aluminum oxide inhibits optical coupling between the laser element and the modulator element.

By contrast, according to the present first embodiment, as described above, the configuration is adopted in which the mesa portions M1 and M2 are formed using the masks (301 and 302), while the multi-layer body of the mesa portion M1 is covered with the p-type first clad layer 109 not containing Al. This can prevent the foregoing unneeded aluminum oxide from being generated.

Thus, it is possible to improve the properties of the elements (such as the laser element and the modulator element) integrated in the optical semiconductor integrated device and improve the properties of the optical semiconductor integrated device.

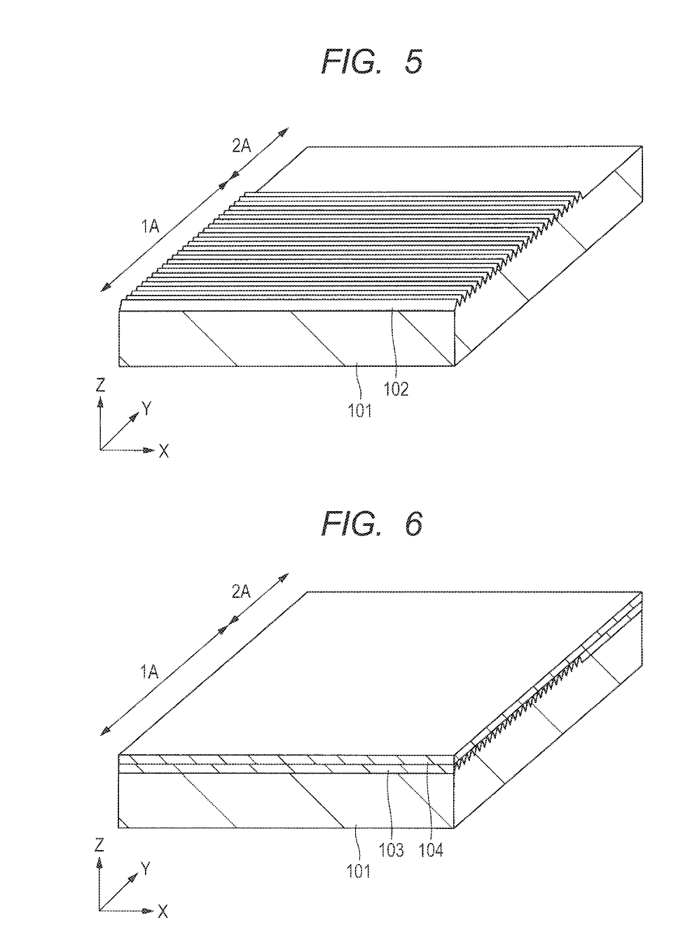

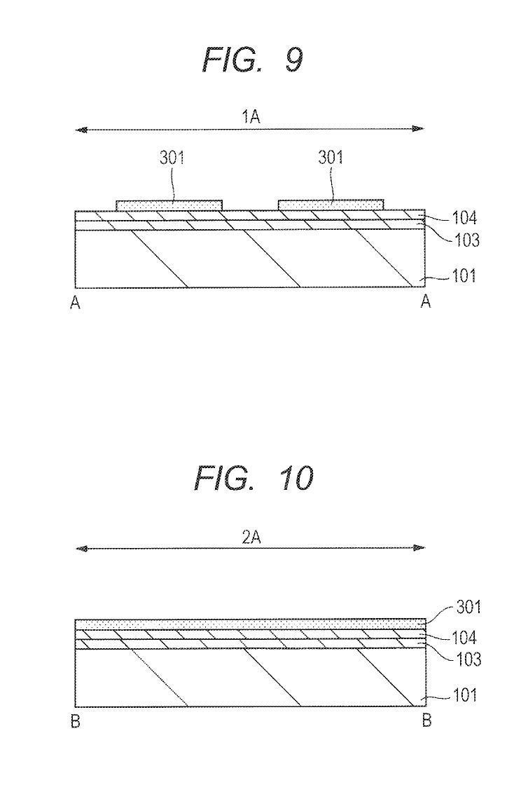

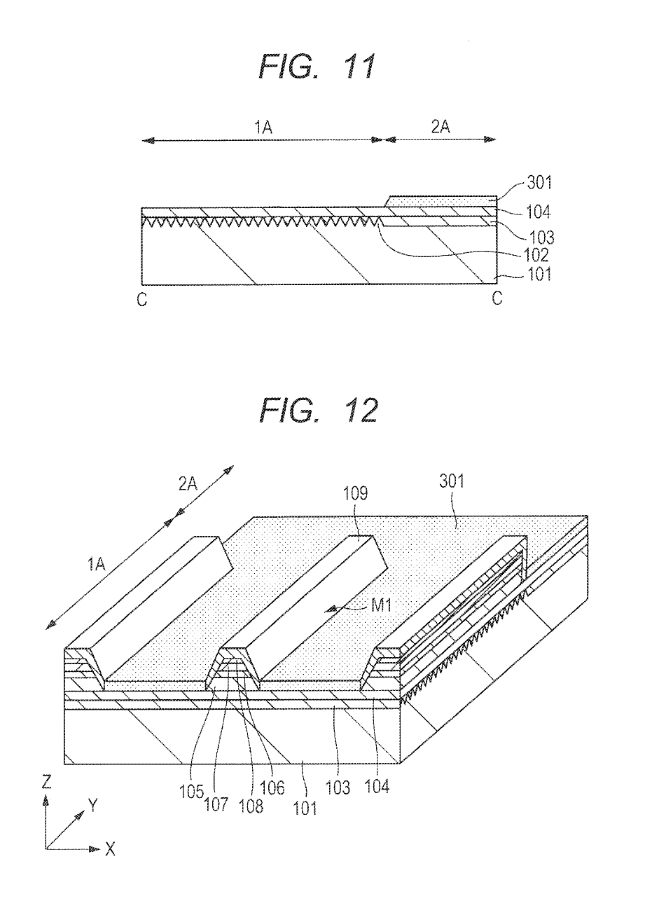

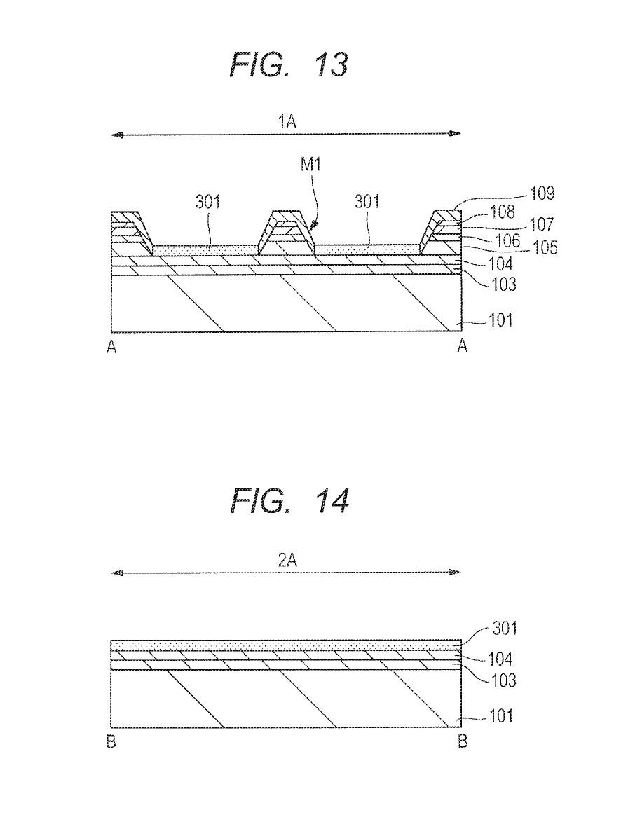

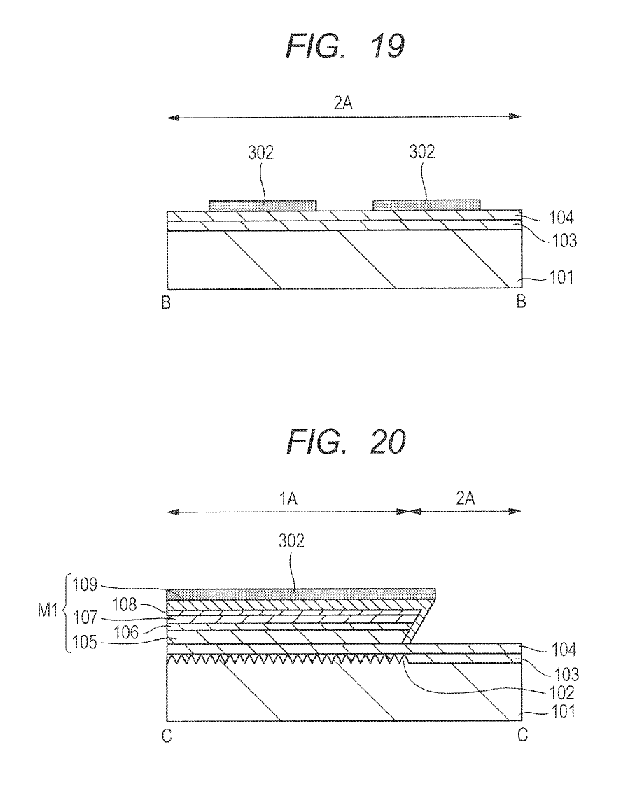

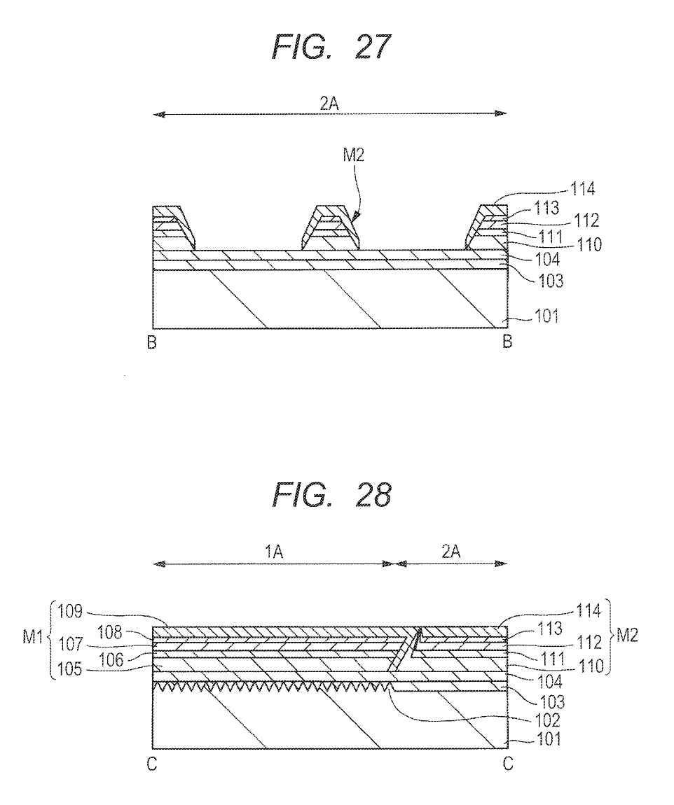

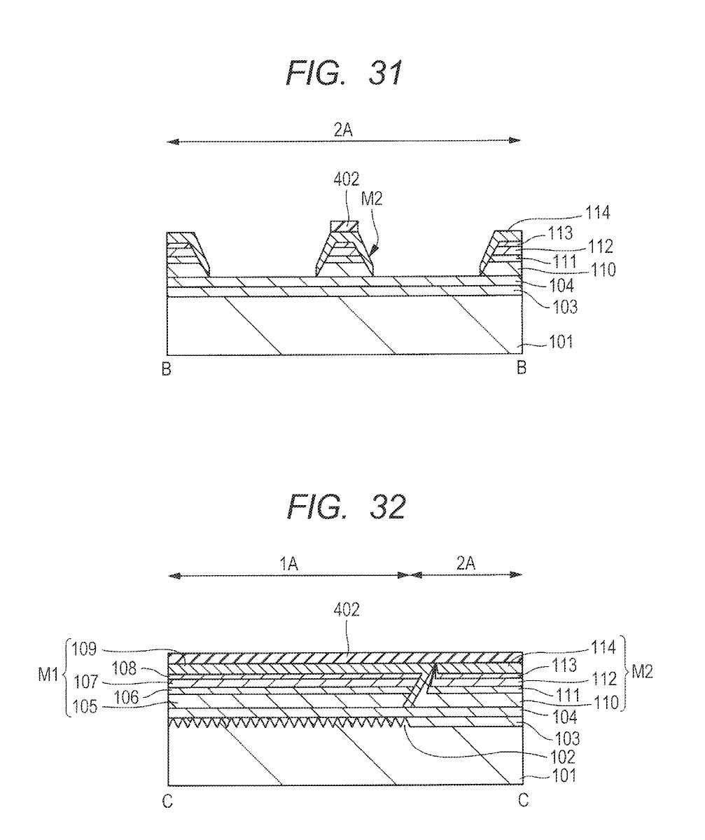

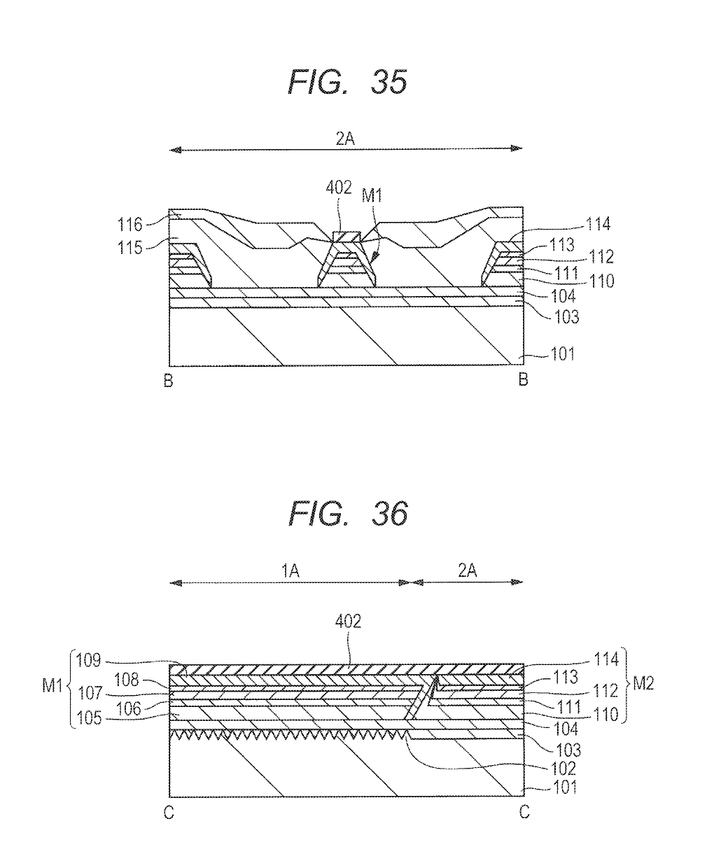

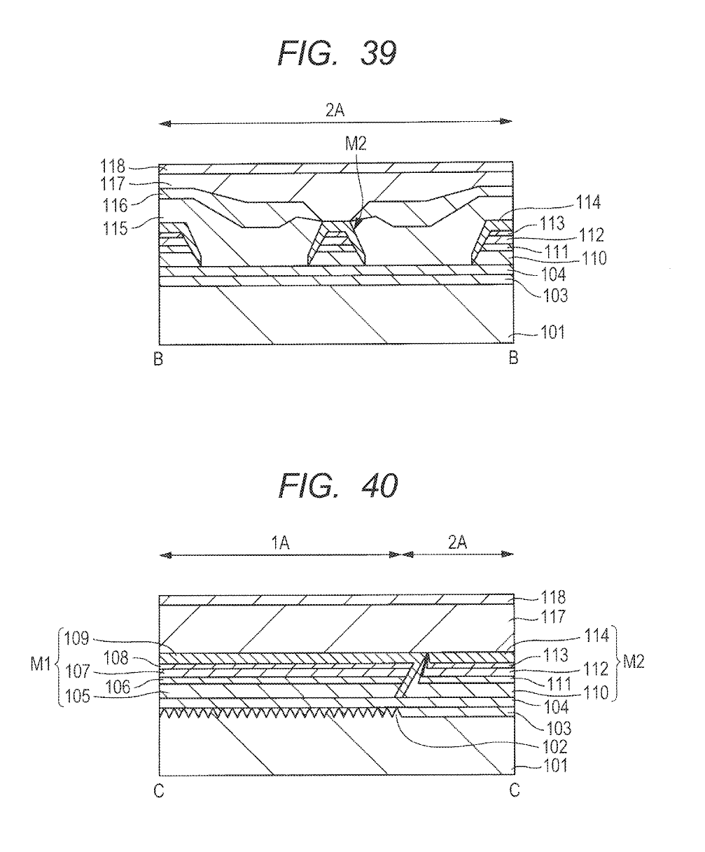

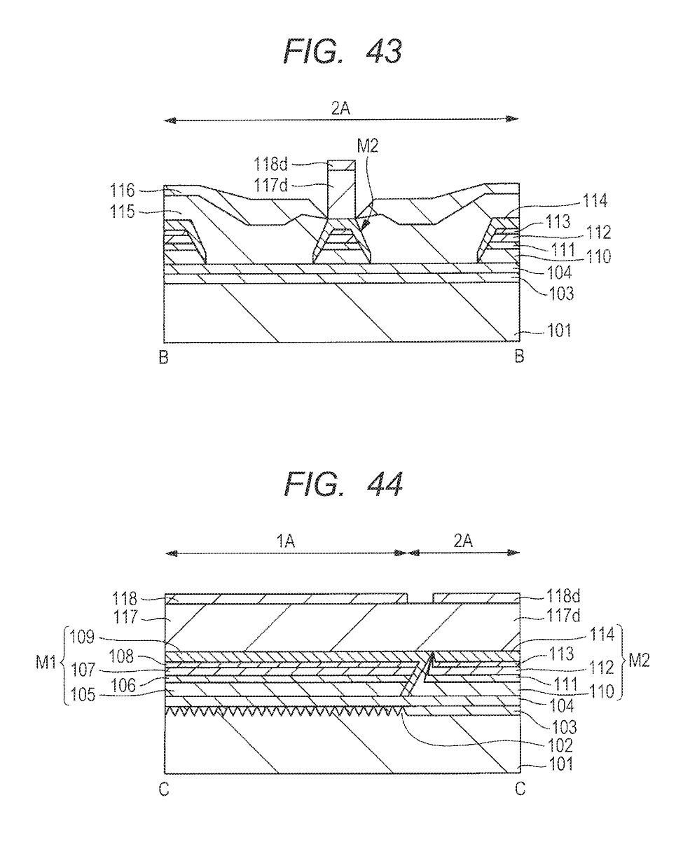

Next, referring to the drawings, a description will be given of a structure of the optical semiconductor integrated device in the present first embodiment and a manufacturing process thereof. FIGS. 5 to 48 are views (perspective views, cross-sectional views, and plan views) showing a manufacturing process of the optical semiconductor integrated device in the present first embodiment. The cross-sectional views correspond to cross-sectional portions along the lines A-A, B-B, or C-C in the plan views.

[Description of Structure]

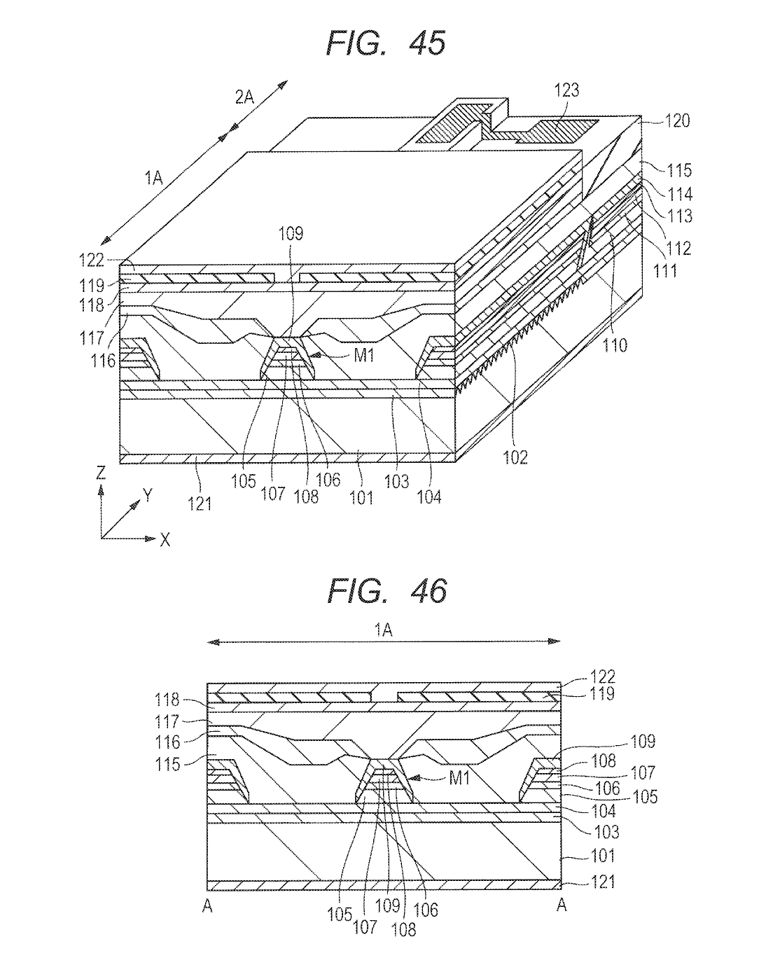

The following will describe the structure of the optical semiconductor integrated device in the present first embodiment with reference to FIGS. 45 to 48 as final step views.

The optical semiconductor integrated device in the present first embodiment shown in FIGS. 45 to 48 includes the substrate 101, a diffraction grating 102 disposed in the surface portion of the substrate 101, an n-type guide layer 103, and the n-type buffer layer 104, which are successively stacked in an upward direction.

The substrate 101 is made of, e.g., an n-type InP layer. The substrate 101 functions also as an n-type clad layer. The diffraction grating 102 is provided in the first area 1A and made of the depressions/projections of the surface portion of the substrate 101. The n-type guide layer 103 is provided so as to fill up the space over the second area 2A of the substrate 101 and the depressions of the surface portion of the substrate 101 included in the diffraction grating 102. The n-type guide layer 103 is made of, e.g., an n-type InGaAsP layer. The n-type buffer layer 104 is made of, e.g., an n-type InP layer.

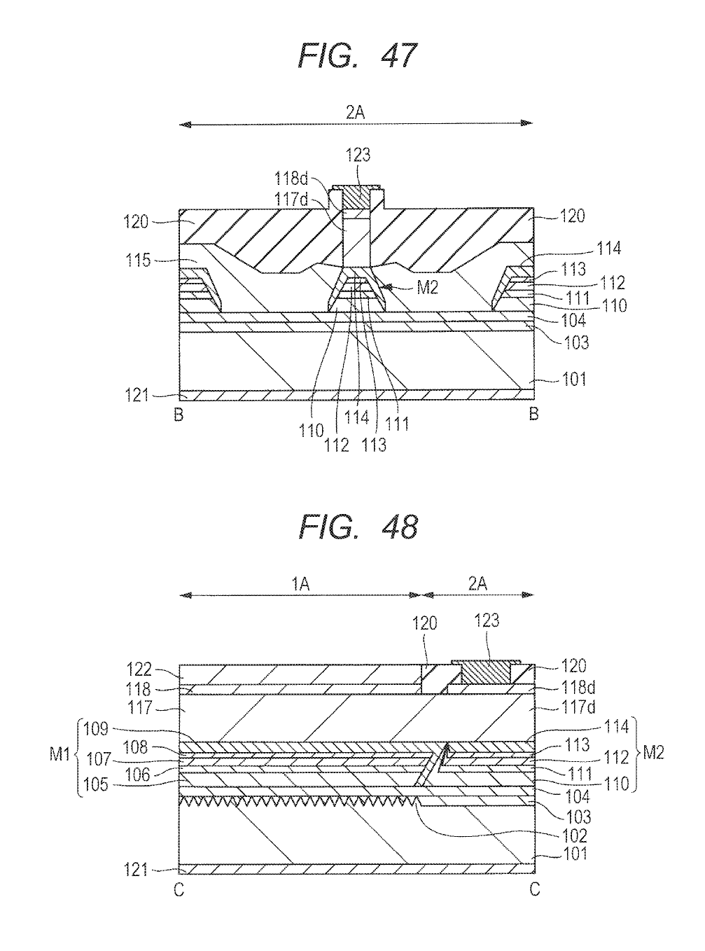

In the first area 1A of the substrate 101, the laser element is provided (see FIG. 46) while, in the second area 2A of the substrate 101, the modulator element is provided (see FIG. 47).

<Laser Element>

In the first area 1A of the substrate 101, at the generally middle portion of the foregoing n-type buffer layer 104, the mesa portion M1 is provided to extend in the Y-direction (FIG. 45). As shown in FIG. 46 and the like, the mesa portion M1 includes a multi-layer body in which the n-type optical guide layer 105, the active layer 106, the p-type optical guide layer 107, and the p-type semiconductor layer 108 are successively stacked in the upward direction and the p-type first clad layer 109 covering the upper surface and each of the side surfaces of the multi-layer body.

In addition, current block layers 115 and 116 are provided so as to fill up the spaces on both sides of the mesa portion M1. Over the mesa portion M1 and over the current block layers 115 and 116, a p-type second clad layer 117 and a p-type contact layer 118 are successively disposed in the upward direction.

Over the uppermost p-type contact layer 118, a p-side electrode 122 is disposed. Under the back surface of the n-type substrate 101, an n-side electrode 121 is disposed. Note that, between the p-type contact layer 118 and the p-side electrode 122, an insulating film 119 is provided. Above the mesa portion M1, the p-type contact layer 118 and the p-type electrode 122 are coupled together.

Thus, the mesa portion M1 of the laser element has a structure in which the active layer 106 is interposed between the group III-V compound semiconductor layers having the opposite conductivity types and located as the upper layer and the lower layer. Over the mesa portion M1, the p-side electrode 122 is disposed while, under the mesa portion M1, the n-side electrode 121 is disposed (double-hetero structure).

The active layer of the laser element has a refractive index larger than those of the layers located thereabove and therebelow (such as the layers 105, 107, and 108). When voltages are applied to the active layer from the electrodes (122 and 121) located thereabove and therebelow, electrons and holes flow into the active layer to be recombined in the active layer and emit light. Since the refractive indices of the layers located above and below the active layer are lower than the refractive index of the active layer, the light is confined to the active layer. As a result of being reflected by the diffraction grating 102 of the active layer, the light reciprocates in the active layer, while being amplified, to cause stimulated emission and laser oscillation.

<Modulator Element>

In the second area 2A of the substrate 101, at the generally middle portion of the foregoing n-type buffer layer 104, the mesa portion M2 is provided to extend in the Y-direction (FIGS. 1A, 1B, and 45). As shown in FIG. 47 and the like, the mesa portion M2 includes a multi-layer body in which the modulator n-type optical guide layer 110, the absorption layer 111, the modulator p-type optical guide layer 112, and the modulator p-type semiconductor layer 113 are successively stacked in the upward direction and the modulator p-type first clad layer 114 covering the upper surface and each of the side surfaces of the multi-layer body.

In addition, the current block layer 115 is provided so as to fill up the spaces on both sides of the mesa portion M2. Over the mesa portion M2, a p-type second clad layer 117d and a p-type contact layer 118d are successively disposed in the upward direction. On both sides of the resulting multi-layer body (117d and 118d), a modulator insulating film 120 is provided (FIG. 47). The p-type second clad layer 117d in the second area 2A is equal in level to the p-type second clad layer 117 in the first area 1A and coupled to the p-type second clad layer 117 in the first area 1A. The p-type contact layer 118d in the second area 2A is equal in level to the p-type contact layer 118 in the first area 1A and is not coupled to (is isolated from) the p-type contact layer 118 in the first area 1A.

Over the p-type contact layer 118d, a modulator p-type electrode 123 is disposed. As described above, under the back surface of the n-type substrate 101, the n-side electrode 121 is disposed. Note that the p-type contact layer 118d and the modulator p-type electrode 123 are coupled together via the contact hole provided in the modulator insulating film 120.

Thus, the mesa portion M2 of the modulator element has a structure in which the absorption layer 111 is interposed between the group III-V compound semiconductor layers having the opposite conductivity types and disposed as the upper layer and the lower layer. Over the mesa portion M2, the modulator p-type electrode 123 is disposed while, under the mesa portion M2, the n-side electrode 121 is disposed.

In the mesa portion M2 of the modulator element, the input light (optical signal) has the amplitude thereof varied by the voltages (external signals) applied to the upper and lower electrodes (123 and 122).

As described above, to improve the respective properties of the individual elements, the respective layers included in the mesa portions M1 and M2 may have different element composition ratios or different film thicknesses. For example, the respective AlGaInAs layers forming the active layer 106 and the absorption layer 111 may have different element composition ratios or different film thicknesses. For example, X1 in an Alₓ₁Ga_{Y1}In_{1-X1-Y1}As layer may be different from X2 in an Alₓ₂Ga_{Y2}In_{1-X2-Y2}As layer. Also, the respective AlGaInAs layers forming the active layer 106 and the absorption layer 111 may have different film thicknesses. Note only the active layer 106, but also the layers located above and below the active layer 106 and the constituent layers of the mesa portion M2 corresponding thereto may also have different element composition ratios or different film thicknesses.

Thus, according to the present first embodiment, the laser element and the modulator element can be independently designed to have optimal structures, and optimal crystallization conditions (such as growth temperatures) can be set therefor. This allows the respective element properties (such as the maximum optical output property of the laser element and the extinction ratio property of the modulator element) to be independently optimized. Specifically, with the optical semiconductor integrated device in the present first embodiment, in high-speed optical communication at, e.g., 25 Gbps or higher, an excellent transmission property can be implemented.

Also, according to the present first embodiment, in the mesa portion M1, the foregoing multi-layer body including the semiconductor layers containing Al is covered with the p-type first clad layer 109 not containing Al (see FIG. 48). This can prevent such unneeded aluminum oxide as generated in the foregoing comparative example from being generated and improve the crystallinities of the constituent layers of the mesa portion M2. This can also allow excellent optical coupling between the mesa portions M1 and M2 to be maintained.

Also, in the present embodiment, in the mesa portion M2, the foregoing multi-layer body including the semiconductor layers containing Al is covered with the p-type first clad layer 109 not containing Al. Accordingly, it is possible to prevent unneeded aluminum oxide from being generated and improve the crystallinity of the current block layer 115 formed on both sides of the mesa portion M2.

Thus, in the optical semiconductor integrated device in the present first embodiment, it is possible to improve the crystallinities of the respective layers included in the laser element and the modulator element. As a result, it is possible to significantly suppress sudden element deterioration specific to an Al-based device during a long-period and high-temperature operation at, e.g., 85° C. and implement a high-reliability/long-life device.

[Description of Manufacturing Method]

Next, referring to FIGS. 5 to 48, a method of manufacturing the optical semiconductor integrated device in the present first embodiment will be described, while a configuration of the optical semiconductor integrated device will be more clearly shown.

As described above, the optical semiconductor integrated device in the present first embodiment includes the laser element formed in the first area 1A of the substrate 101 and the modulator element formed in the second area 2A of the substrate 101. In other words, in the following steps, the laser element is formed in the first area 1A of the substrate 101, while the modulator element is formed in the second area 2A of the substrate 101.

As shown in FIG. 5, as the substrate 101, a substrate made of indium phosphorus (InP) in which, e.g., an n-type impurity is introduced is provided. The surface (growth surface) of the substrate has a (100) plane. Note that a substrate in which n-type InP is grown over a supporting substrate such as a silicon carbide substrate or a sapphire substrate may also be used. The substrate 101 has the first area 1A and the second area 2A. The first area 1A is the region where the laser element is to be formed, while the second area 2A is the region where the modulator element is to be formed.

Next, in the surface portion of the first area 1A of the substrate 101, the diffraction grating 102 is formed. For example, over the substrate 101, a photoresist film (not shown) in the form of a stripe is formed using an electron beam exposure method, an interference exposure method, or the like. Using the photoresist film as a mask, the surface portion of the substrate 101 is wet-etched to be formed with the depressions. Then, the photoresist film is removed. This allows the diffraction grating 102 in which the linear projections and depressions are alternately arranged to be formed. The widths of the depressions and the pitch thereof (width of each of the projections) are, e.g., about 200 nm.

Then, as shown in FIG. 6, the n-type guide layer 103 is formed so as to fill up the depressions of the diffraction grating 102 and the second area 2A. Then, over the n-type guide layer 103, the n-type buffer layer 104 is formed. For example, over the foregoing diffraction grating 102, as the n-type guide layer 103, an n-type InGaAsP layer is formed. For example, using an MOVPE device, the n-type guide layer (n-type InGaAsP layer) 103 is crystal-grown, while a carrier gas and raw material gases are introduced into the device. As the carrier gas, hydrogen, nitrogen, or a gas mixture of hydrogen and nitrogen is used.

As the raw material gases, gases containing the constituent elements of the group III-V compound semiconductor layers are used. For example, when the n-type guide layer (n-type InGaAsP layer) 103 is deposited, as the respective raw materials of In, Ga, As, and P, trimethyl indium (TMIn), triethyl gallium (TEGa), AsH₃, and PH₃ are used while, as the raw material of an n-type impurity, disilane (Si₂H₆) is used.

The n-type guide layer (n-type InGaAsP layer) 103 has a thickness of, e.g., about 30 nm and an n-type impurity concentration (carrier concentration) of about 1×10¹⁸ cm⁻³. Subsequently, over the n-type guide layer (n-type InGaAsP layer) 103, as the n-type buffer layer 104, an n-type InP layer is formed. For example, the supply of the foregoing triethyl gallium (TEGa) and AsH₃ is stopped, and an n-type InP layer is formed. The n-type buffer layer (n-type InP layer) 104 has a thickness of, e.g., about 30 nm and an n-type impurity concentration (carrier concentration) of about 1×10¹⁸ cm⁻³. A composition wavelength equivalent to the band gap of the n-type buffer layer (n-type InP layer) 104 is about 1130 nm to 1170 nm.

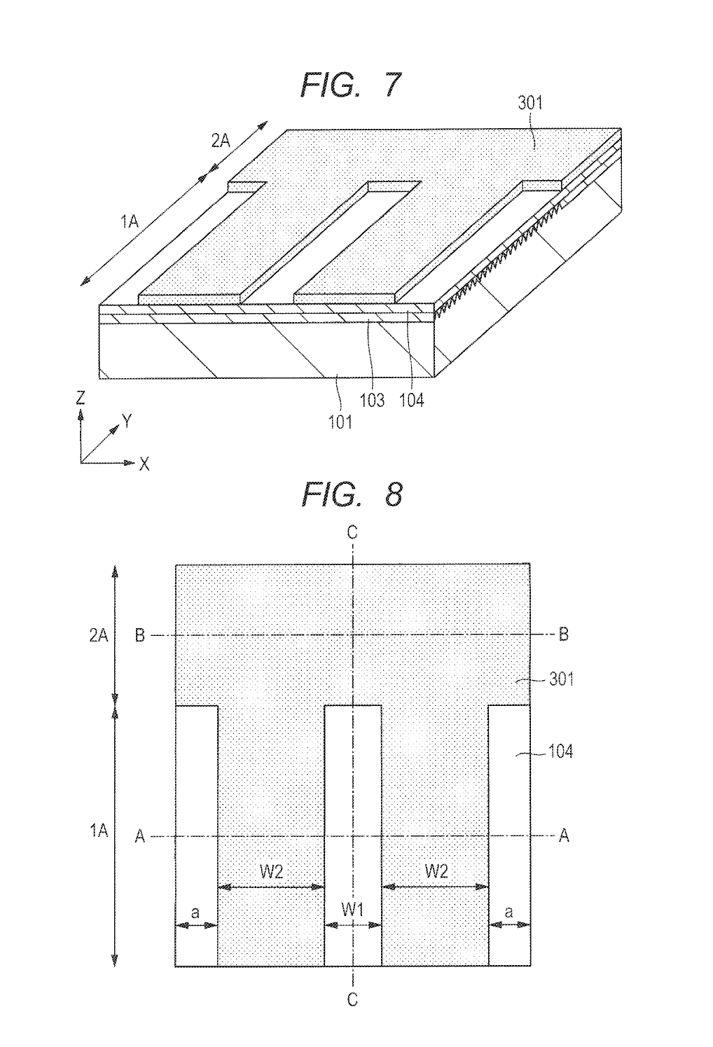

Next, as shown in FIGS. 7 to 11, the substrate 101 is retrieved from the MOVPE device and, over the n-type buffer layer (n-type InP layer) 104, the mask film 301 is formed. For example, over the n-type buffer layer (n-type InP layer) 104, as the mask film 301, a silicon oxide film is deposited to a thickness of about 100 nm using a thermal CVD method or the like. Then, over the mask film (silicon oxide film) 301, a photoresist film (not shown) having an opening corresponding to the region of the first area 1A where the mesa portion (M1) is to be formed is formed. Using the photoresist film as a mask, the mask film (silicon oxide film) 301 is etched. Thus, the mask film 301 having the opening corresponding to the region of the first area 1A where the mesa portion is to be formed is formed and, in the region of the first area 1A where the mesa portion M1 is to be formed, the n-type buffer layer (n-type InP layer) 104 is exposed. As shown in FIG. 8, the region where the n-type buffer layer (n-type InP layer) 104 is exposed, i.e., the region where the mesa portion M1 is to be formed has a generally rectangular shape in plan view and a width (W1) of, e.g., about 1 to 2 m. The mask film 301 in the first area 1A has a generally rectangular shape in plan view and a width (W2) of about 3 to 20 m. The direction in which the mask film 301 in the first area 1A extends is a [011] direction. Note that, outside the mask film 301, there is an area a where the n-type buffer layer (n-type InP layer) 104 is exposed.

Next, as shown in FIGS. 12 to 15, over the n-type buffer layer (n-type InP layer) 104 exposed from the opening of the mask film 301, the mesa portion M1 is formed.

Specifically, over the n-type buffer layer (n-type InP layer) 104 exposed from the opening of the mask film 301, the n-type optical guide layer 105, the active layer 106, the p-type optical guide layer 107, the p-type semiconductor layer 108, and the p-type first clad layer 109 are successively grown. In the growth step, the layers are not grown over the mask film 301 so that the mesa portion M1 is formed over the n-type buffer layer (n-type InP layer) 104 exposed from the opening of the mask film 301.

For example, the substrate 101 is placed in the MOVPE device and, over the n-type buffer layer (n-type InP layer) 104, as the n-type optical guide layer 105, an n-type AlGaInAs layer is formed. For example, the n-type optical guide layer (n-type AlGaInAs layer) 105 is crystal-grown, while a carrier gas and raw material gases are introduced into the device. As the carrier gas, hydrogen, nitrogen, or a gas mixture of hydrogen and nitrogen is used. As the raw material gases, trimethyl aluminum (TMAl), triethyl gallium (TEGa), trimethyl indium (TMIn), and AsH₃ as the gases containing the constituent elements of the group III-V compound semiconductor layer are used while, as the raw material of an n-type impurity, disilane (Si₂H₆) is used. The n-type optical guide layer (n-type AlGaInAs layer) 105 has a thickness of, e.g., about 50 nm and an n-type impurity concentration (carrier concentration) of about 1×10¹⁷ cm⁻³.

Subsequently, over the n-type optical guide layer (n-type AlGaInAs layer) 105, as the active layer 106, a multiquantum well structure including AlGaInAs well layers and AlGaInAs barrier layers which are different in the composition of group III elements and alternately stacked is crystal-grown. When the active layer (AlGaInAs well layers and AlGaInAs barrier layers) 106 is deposited, as the respective raw materials of Al, Ga, In, and As, trimethyl aluminum (TMAl), triethyl gallium (TEGa), trimethyl indium (TMIn), and AsH₃ are used, and the flow rates of the raw materials of the group III elements (Al, Ga, In) are changed. This allows the AlGaInAs well layers and the AlGaInAs barrier layers which are different in the composition of the group III elements to be alternately stacked. Each of the AlGaInAs well layers is non-doped and has a film thickness of about 5 nm, while each of the AlGaInAs barrier layers is non-doped and has a film thickness of about 10 nm. The AlGaInAs well layer has a compressive strain, while the AlGaInAs barrier layer has a tensile strain, so that the active layer 106 has a strain compensation structure. The total film thickness of the active layer 106 is, e.g., about 100 to 200 nm. The layer configuration of the active layer may be designed appropriately in accordance with the intended use thereof.

Subsequently, over the active layer (AlGaInAs well layers and AlGaInAs barrier layers) 106, as the p-type optical guide layer 107, a p-type AlGaInAs layer is formed. When the p-type optical guide layer (p-type AlGaInAs layer) 107 is deposited, as the respective raw materials of Al, Ga, In, and As, trimethyl aluminum (TMAl), triethyl gallium (TEGa), trimethyl indium (TMIn), and AsH₃ are used while, as the raw material of a p-type impurity, diethyl zinc (DEZn) is used. The p-type optical guide layer (p-type AlGaInAs layer) 107 has a thickness of, e.g., about 50 nm and a p-type impurity concentration (carrier concentration) of about 5×10¹⁷ cm⁻³.

Subsequently, over the p-type optical guide layer (p-type AlGaInAs layer) 107, as the p-type semiconductor layer 108, a p-type AlInAs layer is formed. When the p-type semiconductor layer (p-type AlInAs layer) 108 is deposited, as the respective raw materials of Al, In, and As, trimethyl aluminum (TMAl), trimethyl indium (TMIn), and AsH₃ are used while, as the raw material of a p-type impurity, diethyl zinc (DEZn) is used. The p-type semiconductor layer (p-type AlInAs layer) 108 has a thickness of, e.g., about 20 nm and a p-type impurity concentration (carrier concentration) of about 1×10¹⁸ cm⁻³. By the steps described heretofore, over the n-type buffer layer (n-type InP layer) 104 exposed from the opening of the mask film 301, the multi-layer body is formed in which the n-type optical guide layer 105, the active layer 106, the p-type optical guide layer 107, and the p-type semiconductor layer 108 are successively stacked in the upward direction.

Subsequently, as the p-type first clad layer 109, a p-type InP layer is formed so as to cover the upper surface and each of the side surfaces of the foregoing multi-layer body. For example, when the p-type first clad layer (p-type InP layer) 109 is deposited, as the respective raw materials of In and P, e.g., trimethyl indium (TMIn) and PH₃ are used while, as the raw material of a p-type impurity, diethyl zinc (DEZn) is used. The p-type first clad layer (p-type InP layer) 109 has a thickness of, e.g., about 50 nm to 200 nm and a p-type impurity concentration (carrier concentration) of about 1×10¹⁸ cm⁻³.

Thus, the mesa portion M1 including the foregoing multi-layer body (the n-type optical guide layer 105, the active layer 106, the p-type optical guide layer 107, and the p-type semiconductor layer 108) and the p-type first clad layer (p-type InP layer) 109 covering the foregoing multi-layer body can be formed. Thus, in accordance with the MOVPE method, by changing the raw material gases, it is possible to continuously form the individual layers included in the mesa portion. Note that, in the present first embodiment, over the n-type buffer layer (n-type InP layer) 104 exposed in the opening (area a in FIG. 8) outside the mask film 301 also, the same structure as the mesa portion is grown, but does not function as a laser (see the both end portions in FIG. 12).

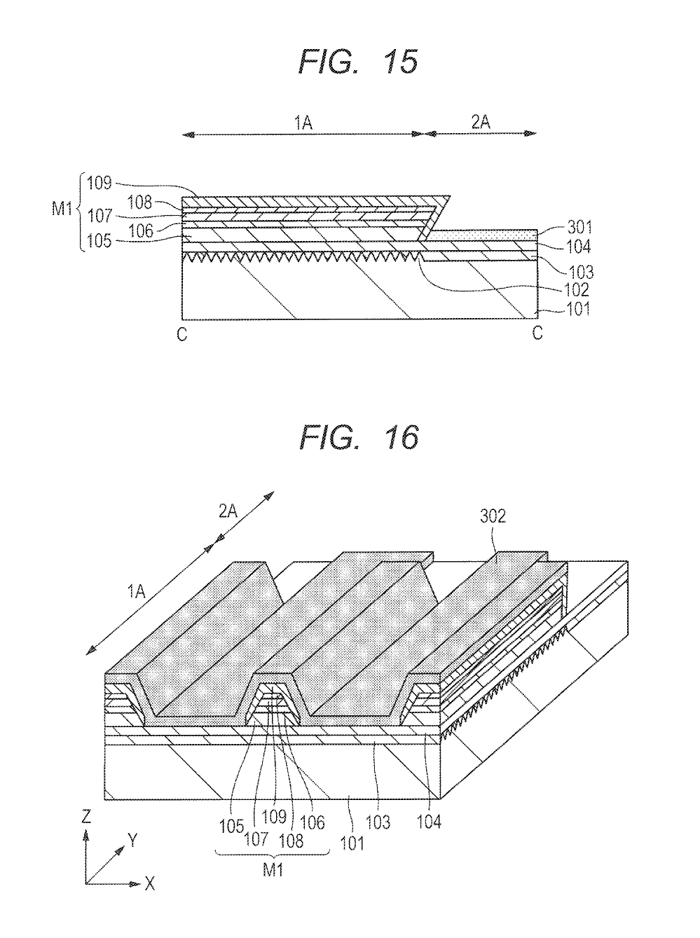

A description will be given herein of the respective shapes of the foregoing multi-layer body (the n-type optical guide layer 105, the active layer 106, the p-type optical guide layer 107, and the p-type semiconductor layer 108) and the mesa portion M2 including the foregoing multi-layer body. As shown in FIG. 15, the respective cross-sectional shapes of the foregoing multi-layer film and the mesa portion M1 in the X-direction (i.e., direction perpendicular to the mesa portion in the form of a stripe) are mesa shapes. In other words, the side walls of the foregoing multi-layer film and the mesa portion M1 extending in the X-direction show upwardly tapered shapes. As also shown in FIG. 15, the respective cross-sectional shapes of the foregoing multi-layer film and the mesa portion M1 in the Y-direction (i.e., direction parallel with the mesa portion in the form of a stripe) are inverted mesa shapes or shapes similar thereto. In other words, the side walls of the foregoing multi-layer film and the mesa portion M1 extending in the Y-direction show downwardly tapered shapes or shapes similar thereto. In still other words, of the foregoing multi-layer film and the mesa portion M1, the side walls closer to the boundary with the mesa portion M2 have downwardly tapered shapes or shapes similar thereto. Note that, of the foregoing multi-layer film and the mesa portion M1, the side surfaces (end surfaces) opposite to those closer to the boundary with the mesa portion M2 are cleaved surfaces described later.

Thus, according to the present first embodiment, the p-type first clad layer (p-type InP layer) 109 is grown so as to cover each of the side surfaces of the foregoing multi-layer body (the n-type optical guide layer 105, the active layer 106, the p-type optical guide layer 107, and the p-type semiconductor layer 108). Accordingly, even when the foregoing multi-layer body includes the semiconductor layers containing Al (the n-type optical guide layer (n-type AlGaInAs layer) 105, the active layer (AlGaInAs well layers and AlGaInAs barrier layers) 106, the p-type optical guide layer (p-type AlGaInAs layer) 107, and the p-type semiconductor layer (p-type AlInAs layer) 108), it is possible to prevent these layers from being oxidized without exposing these layers to atmosphere.

Next, the substrate 101 is retrieved from the MOVPE device, and the mask film (silicon oxide film) 301 over the substrate 101 is removed therefrom by etching.

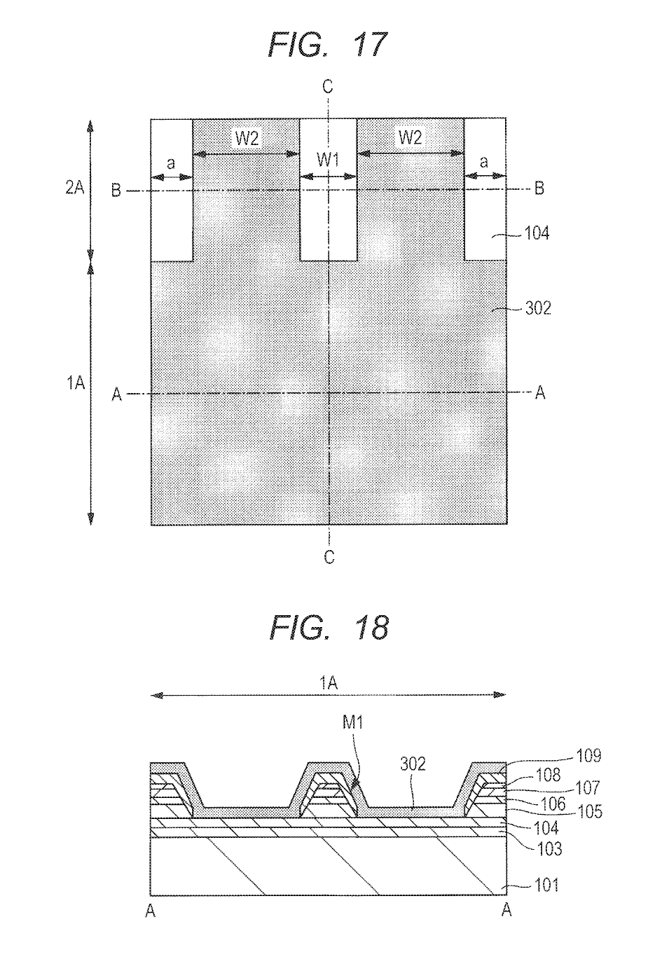

Next, as shown in FIGS. 16 to 20, over the mesa portion M1 and the n-type buffer layer (n-type InP layer) 104 over the first area 1A of the substrate 101, the mask film 302 is formed. For example, over the mesa portion M1 and the n-type buffer layer (n-type InP layer) 104 in the first area 1A, as the mask film 302, a silicon oxide film is deposited to a thickness of about 100 nm using a thermal CVD method or the like. Then, over the mask film (silicon oxide film) 302, a photoresist film (not shown) having an opening corresponding to the region of the second area 2A where the mesa portion M2 is to be formed is formed and, using the photoresist film as a mask, the mask film (silicon oxide film) 302 is etched. Thus, the mask film 302 having the opening corresponding to the region of the second area 2A where the mesa portion M2 is to be formed is formed and, in the region of the second area 2A where the mesa portion M2 is to be formed, the n-type buffer layer (n-type InP layer) 104 is exposed. As shown in FIG. 17, the region of the second area 2A where the n-type buffer layer (n-type InP layer) 104 is exposed, i.e., the region where the mesa portion M2 is to be formed has a generally rectangular shape in plan view and a width (W1) of, e.g., about 1 to 2 μm. The mask film 302 in the second area 2A has a generally rectangular shape in plan view and a width (W2) of, e.g., about 3 to 20 μm. The direction in which the mask film 302 in the second area 2A extends is the [011] direction. Note that there is the area a outside the mask film 302 where the n-type buffer layer (n-type InP layer) 104 is exposed.

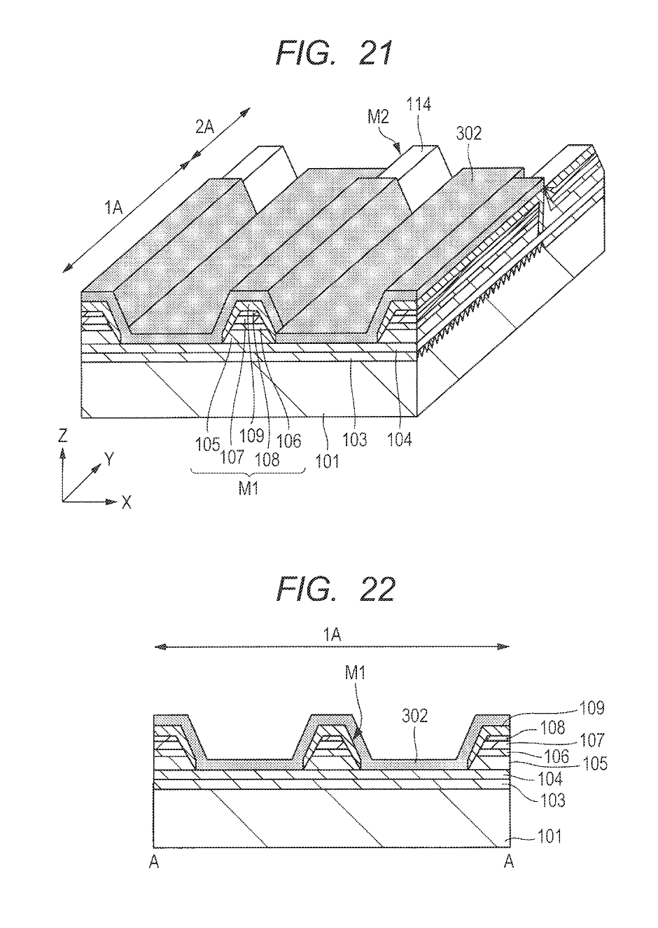

Next, as shown in FIGS. 21 to 24, over the n-type buffer layer (n-type InP layer) 104 exposed from the opening of the mask film 302, the mesa portion M2 is formed.

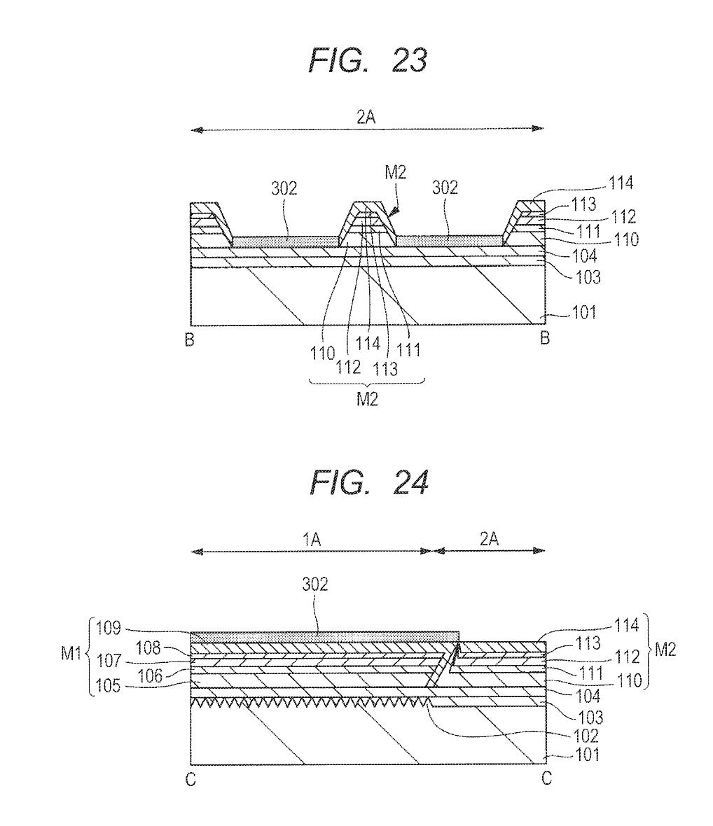

Specifically, as shown in, e.g., FIGS. 23 and 24, over the n-type buffer layer (n-type InP layer) 104 exposed from the opening of the mask film 302, the modulator n-type optical guide layer 110, the absorption layer 111, the modulator p-type optical guide layer 112, the modulator p-type semiconductor layer 113, and the modulator p-type first clad layer 114 are successively grown. In the growth step, the layers are not grown over the mask film 302 so that, in the second area 2A, over the n-type buffer layer (n-type InP layer) 104 exposed from the opening of the mask film 302, the mesa portion M2 is formed.

For example, the substrate 101 is placed in the MOVPE device and, over the n-type buffer layer (n-type InP) layer 104, as the modulator n-type optical guide layer 110, an n-type AlGaInAs layer is formed. For example, the modulator n-type optical guide layer (n-type AlGaInAs layer) 110 is crystal-grown, while a carrier gas and raw material gases are introduced into the device. As the carrier gas, hydrogen, nitrogen, or a gas mixture of hydrogen and nitrogen is used. As the raw material gases, trimethyl aluminum (TMAl), triethyl gallium (TEGa), trimethyl indium (TMIn), and AsH₃ as the gases containing the constituent elements of the group III-V compound semiconductor layer are used while, as the raw material of an n-type impurity, disilane (Si₂H₆) is used. The modulator n-type optical guide layer (n-type AlGaInAs layer) 110 has a thickness of, e.g., about 50 nm and an n-type impurity concentration (carrier concentration) of about 1×10¹⁷ cm⁻³.

Subsequently, over the modulator n-type optical guide layer (n-type AlGaInAs layer) 110, as the absorption layer 111, a multiquantum well structure including AlGaInAs well layers and AlGaInAs barrier layers which are different in the composition of group III elements and alternately stacked is crystal-grown. When the absorption layer (AlGaInAs well layers and AlGaInAs barrier layers) 111 is deposited, as the respective raw materials of Al, Ga, In, and As, trimethyl aluminum (TMAl), triethyl gallium (TEGa), trimethyl indium (TMIn), and AsH₃ are used, and the flow rates of the raw materials of the group III elements (Al, Ga, In) are changed. This allows the AlGaInAs well layers and the AlGaInAs barrier layers which are different in the composition of the group III elements to be alternately stacked. Each of the AlGaInAs well layers is non-doped and has a film thickness of about 4.5 nm, while each of the AlGaInAs barrier layers is non-doped and has a film thickness of about 10 nm. The AlGaInAs well layer has a compressive strain, while the AlGaInAs barrier layer has a tensile strain, so that the absorption layer 111 has a strain compensation structure. The total film thickness of the absorption layer 111 is about 100 to 200 nm. For the absorption layer 111, a combination of the presence/absence of a lattice strain and the direction of the lattice strain, the amount of the strain, and the amount of the detuning of the optical absorption end wavelength of the absorption layer 111 from an LD oscillation wavelength are set by appropriately adjusting the compositions of the well layers and the barrier layers, the film thicknesses thereof, the numbers of the stacked layers, or the like.

Subsequently, over the absorption layer (AlGaInAs well layers and AlGaInAs barrier layers) 111, as the modulator p-type optical guide layer 112, a p-type AlGaInAs layer is formed. When the modulator p-type optical guide layer (p-type AlGaInAs layer) 112 is deposited, as the respective raw materials of Al, Ga, In, and As, trimethyl aluminum (TMAl), triethyl gallium (TEGa), trimethyl indium (TMIn), and AsH₃ are used while, as the raw material of a p-type impurity, diethyl zinc (DEZn) is used. The modulator p-type optical guide layer (p-type AlGaInAs layer) 112 has a thickness of, e.g., about 50 nm and a p-type impurity concentration (carrier concentration) of about 5×10¹⁷ cm⁻³.

Subsequently, over the modulator p-type optical guide layer (p-type AlGaInAs layer) 112, as the modulator p-type semiconductor layer 113, a p-type AlInAs layer is formed. When the modulator p-type semiconductor layer (p-type AlInAs layer) 113 is deposited, as the respective raw materials of Al, In, and As, trimethyl aluminum (TMAl), trimethyl indium (TMIn), and AsH₃ are used while, as the raw material of a p-type impurity, diethyl zinc (DEZn) is used. The modulator p-type semiconductor layer (p-type AlInAs layer) 113 has a thickness of, e.g., about 20 nm and a p-type impurity concentration (carrier concentration) of about 1×10¹⁸ cm⁻³. By the steps described heretofore, over the n-type buffer layer (n-type InP layer) 104 exposed from the opening of the mask film 302, the multi-layer body is formed in which the modulator n-type optical guide layer (n-type AlGaInAs layer) 110, the absorption layer 111, the modulator p-type optical guide layer (p-type AlGaInAs layer) 112, and the modulator p-type semiconductor layer (p-type AlInAs layer) 113 are successively stacked in the upward direction.

Subsequently, as the modulator p-type first clad layer 114, a p-type InP layer is formed so as to cover the upper surface and each of the side surfaces of the foregoing multi-layer body. For example, when the p-type first clad layer (p-type InP layer) 114 is deposited, as the respective raw materials of In and P, e.g., trimethyl indium (TMIn) and PH₃ are used while, as the raw material of a p-type impurity, diethyl zinc (DEZn) is used. The modulator p-type first clad layer (p-type InP layer) 114 has a thickness of, e.g., about 50 nm to 200 nm and a p-type impurity concentration (carrier concentration) of about 1×10¹⁸ cm⁻³.

Thus, the mesa portion M2 including the foregoing multi-layer body (the modulator n-type optical guide layer 110, the absorption layer 111, the modulator p-type optical guide layer 112, and the modulator p-type semiconductor layer 113) and the modulator p-type first clad layer (p-type InP layer) 114 covering the foregoing multi-layer body can be formed. Thus, in accordance with the MOVPE method, by changing the raw material gases, it is possible to continuously form the individual layers included in the mesa portion. Note that, in the present first embodiment, over the n-type buffer layer (n-type InP layer) 104 exposed in the opening (area a in FIG. 17) outside the mask film 302 also, the same structure as the mesa portion is grown, but does not function as a modulator element (see the both end portions of the second area 2A in FIG. 21).

A description will be given herein of the respective shapes of the foregoing multi-layer body (the modulator n-type optical guide layer 110, the absorption layer 111, the modulator p-type optical guide layer 112, and the modulator p-type semiconductor layer 113) and the mesa portion M2 including the foregoing multi-layer body. As shown in FIG. 23, the respective cross-sectional shapes of the foregoing multi-layer film and the mesa portion M2 in the X-direction (i.e., direction perpendicular to the mesa portion in the form of a stripe) are mesa shapes. In other words, the side walls of the foregoing multi-layer film and the mesa portion M2 extending in the X-direction show upwardly tapered shapes. As also shown in FIG. 24, the respective cross-sectional shapes of the foregoing multi-layer film and the mesa portion M2 in the Y-direction (i.e., direction parallel with the mesa portion in the form of a stripe) are mesa shapes. In other words, the side walls of the foregoing multi-layer film and the mesa portion M2 extending in the Y-direction have upwardly tapered shapes. In still other words, of the foregoing multi-layer film and the mesa portion M2, the side walls closer to the boundary with the mesa portion M1 have upwardly tapered shapes.

Note that, of the foregoing multi-layer film and the mesa portion M2, the side surfaces (end surfaces) opposite to those closer to the boundary with the mesa portion M1 may also be the cleaved surfaces described later.

Thus, according to the present first embodiment, the modulator p-type first clad layer (p-type InP layer) 114 is grown so as to cover each of the side surfaces of the foregoing multi-layer body (the modulator n-type optical guide layer 110, the absorption layer 111, the modulator p-type optical guide layer 112, and the modulator p-type semiconductor layer 113). Accordingly, even when the foregoing multi-layer body includes the semiconductor layers containing Al (the modulator n-type optical guide layer (n-type AlGaInAs layer) 110, the absorption layer 111, the modulator p-type optical guide layer (p-type AlGaInAs layer) 112, and the modulator p-type semiconductor layer (p-type AlInAs layer) 113), it is possible to prevent these layers from being oxidized without exposing these layers to atmosphere.

Next, the substrate 101 is retrieved from the MOVPE device, and the mask film (silicon oxide film) 302 over the substrate 101 is removed therefrom by etching.

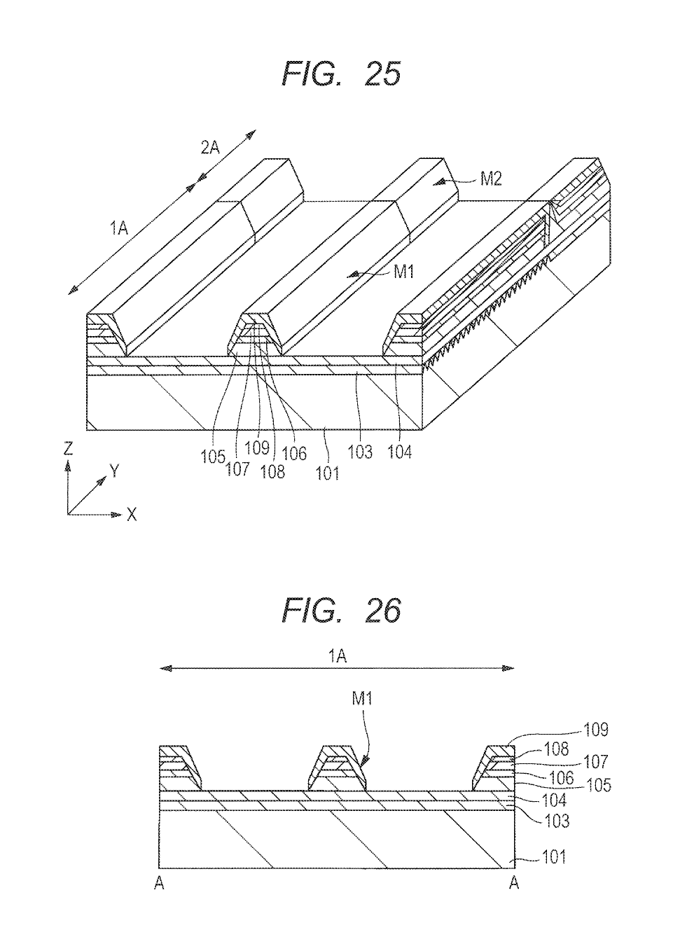

By the steps described heretofore, the mesa portion M1 over the first area 1A of the substrate 101 and the mesa portion M2 in the second area 2A of the substrate 101 are formed (FIGS. 25 to 28).

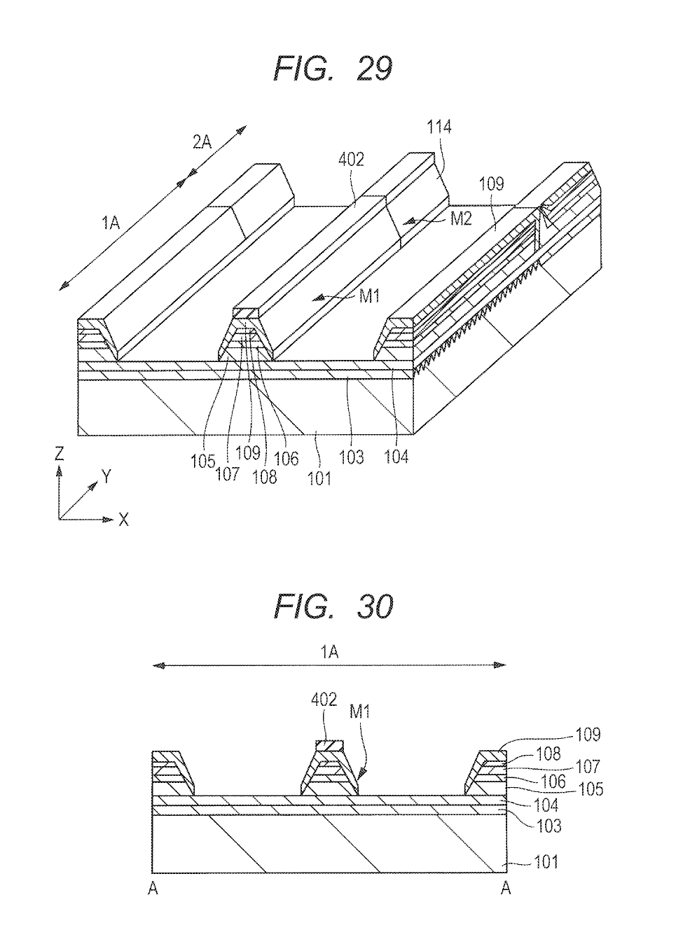

Next, as shown in FIGS. 29 to 32, over the upper surfaces of the mesa portions M1 and M2, a mask film 402 is formed. For example, over the entire surface of the substrate 101, a silicon oxide film is deposited using a thermal CVD method or the like, and a photoresist film (not shown) is formed only over the upper surfaces of the mesa portions. Then, using the photoresist film as a mask, the silicon oxide film is removed, and then the photoresist film is removed. Thus, only over the upper surfaces of the mesa portions, the mask film 402 made of the silicon oxide film is formed.

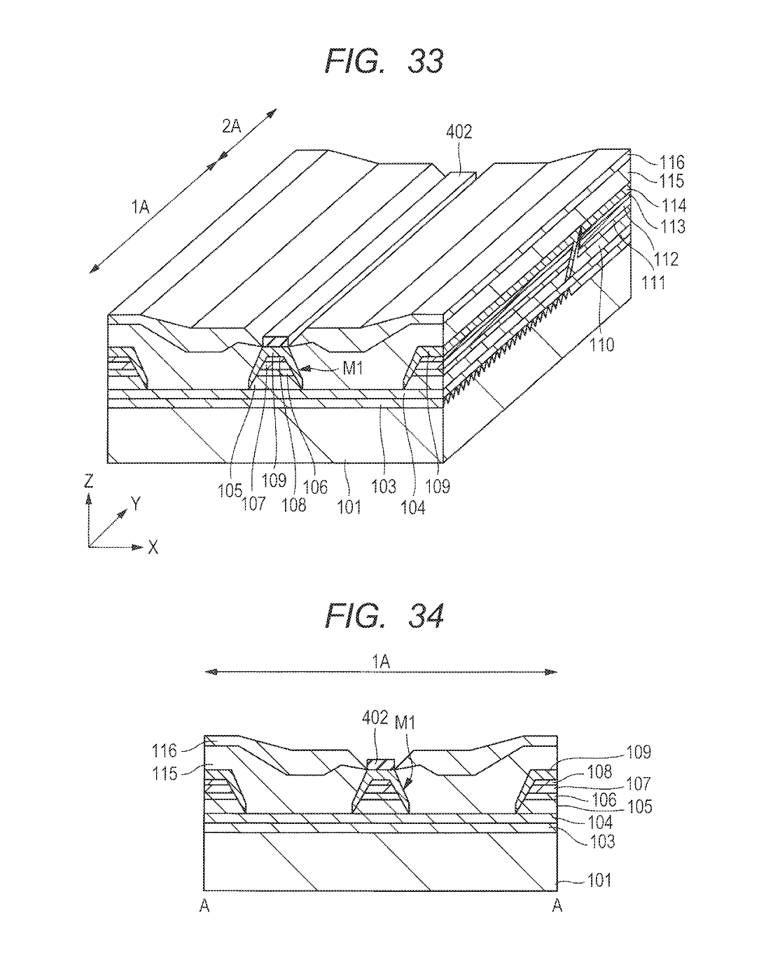

Then, as shown in FIGS. 33 to 36, the current block layers 115 and 116 are formed so as to fill up the spaces on both sides of the mesa portions. For example, the substrate 101 is placed in the MOVPE device and, over the region other than the mask film 402, i.e., over each of the side surfaces of the mesa portions M1 and M2 and over the n-type buffer layer (n-type InP layer) 104 on both sides of the mesa portions M1 and M2, an InP layer doped with Fe (Fe-doped InP layer) is formed as the current block layer 115. This layer serves as a high-resistance layer since Fe introduced therein traps electrons.

For example, the current block layer (Fe-doped InP layer) 115 is crystal-grown, while a carrier gas and raw-material gases are introduced into the device. For example, when the current block layer (Fe-doped InP layer) 115 is deposited, as the respective raw materials of In and P, trimethyl indium (TMIn) and PH₃ are used, and ferrocene is used to introduce Fe. The current block layer (Fe-doped InP layer) 115 has a thickness of, e.g., about 600 nm and an impurity (Fe) concentration (electron trap concentration) of about 1×10¹⁷ cm⁻³.

Subsequently, over the current block layer (Fe-doped InP layer) 115, an n-type InP layer is formed as the current block layer 116.

For example, when the current block layer (n-type InP layer) 116 is deposited, as the respective raw materials of In and P, trimethyl indium (TMIn) and PH₃ are used while, as the raw material of an n-type impurity, disilane (Si₂H₆) is used. The current block layer (n-type InP layer) 116 has a thickness of, e.g., about 200 nm and an n-type impurity concentration (carrier concentration) of about 1×10¹⁸ cm⁻³.

Next, the substrate 101 is retrieved from the MOVPE device, and the mask film (silicon oxide film) 402 over the substrate 101 is removed therefrom by etching.

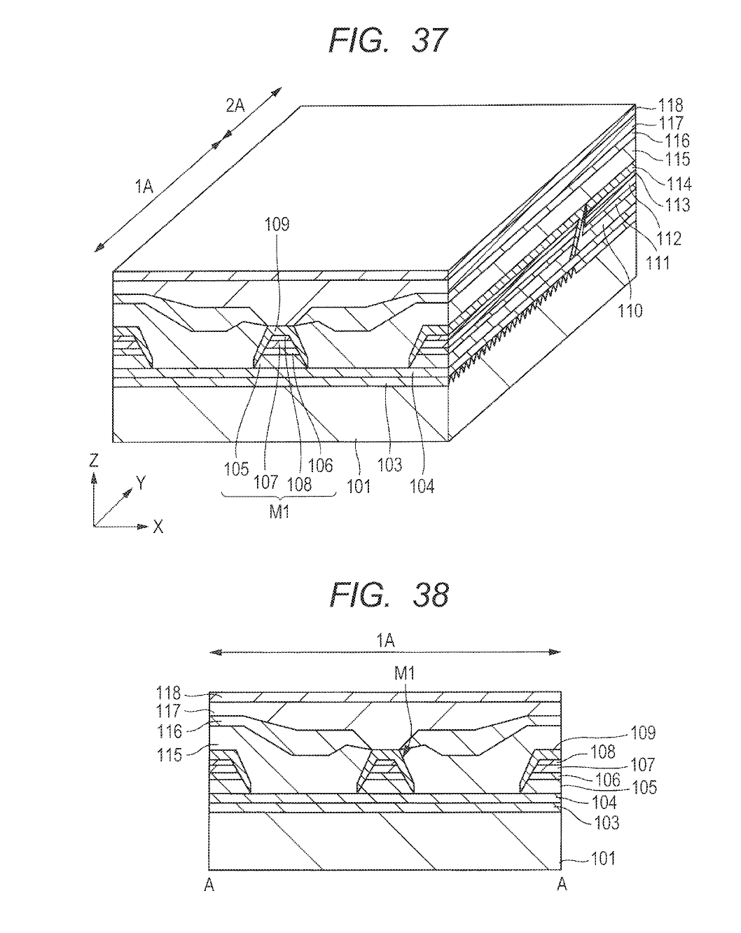

Next, as shown in FIGS. 37 to 40, over the upper surfaces of the mesa portions M1 and M2 and over the current block layer (n-type InP layer) 116, the p-type second clad layer 117 is formed. For example, the substrate 101 is placed in the MOVPE device and, over the upper surfaces of the mesa portions M1 and M2 and over the current block layer (n-type InP layer) 116, a p-type InP layer is formed as the p-type second clad layer 117. For example, when the p-type second clad layer (p-type InP layer) 117 is deposited, as the respective raw materials of In and P, trimethyl indium (TMIn) and PH₃ are used while, as the raw material of a p-type impurity, diethyl zinc (DEZn) is used. The p-type second clad layer (p-type InP layer) 117 has a thickness of, e.g., about 1500 nm and a p-type impurity concentration (carrier concentration) of about 1×10¹⁸ cm⁻³. Subsequently, over the p-type second clad layer (p-type InP layer) 117, as the p-type contact layer 118, a p-type InGaAs layer is formed.

For example, when the p-type contact layer (p-type InGaAs layer) 118 is deposited, as the respective raw materials of In, Ga, and As, trimethyl indium (TMIn), triethyl gallium (TEGa), and AsH₃ are used while, as the raw material of a p-type impurity, diethyl zinc (DEZn) is used. The p-type contact layer (p-type InGaAs layer) 118 has a thickness of, e.g., about 300 nm and a p-type impurity concentration (carrier concentration) of about 1×10¹⁹ cm⁻³.

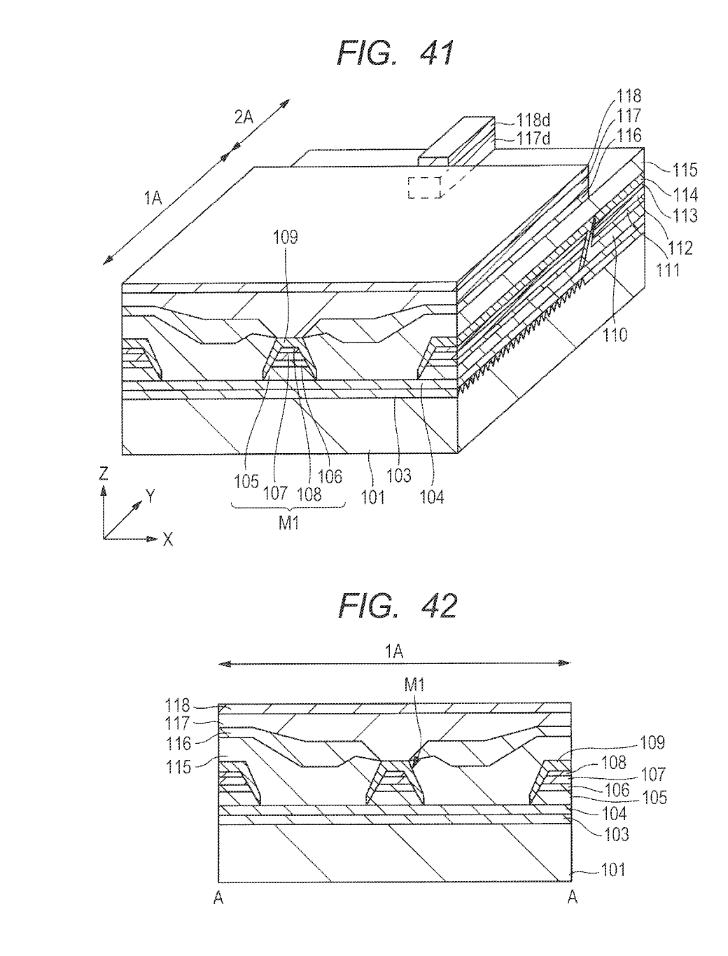

Next, as shown in FIGS. 41 to 44, in the second area 2A, a multi-layer body including the p-type second clad layer 117 and the p-type contact layer 118 is patterned. For example, a photoresist film (not shown) is formed only over the first area 1A and over the mesa portion M2 in the second area 2A. Using the photoresist film as a mask, a multi-layer body including the current block layer 116, the p-type second clad layer 117, and the p-type contact layer 118 is etched. As a result, in the second area 2A, a cubic multi-layer body including the p-type second clad layer 117d and the p-type contact layer 118d is disposed over the mesa portion M2 in the second area 2A. Then, at the boundary portion between the first area 1A and the second area 2A, the p-type contact layer 118d is removed by etching. Note that this multi-layer body and the first area 1A are coupled together by the p-type second clad layer 117, while the p-type contact layer 118 in the first area 1A and the p-type contact layer 118d in the second area 2A are in discrete patterns. The distance between these patterns is, e.g., about several tens of micrometers to several hundreds of micrometers (FIG. 44). Thus, the first area 1A and the second area 2A are isolated from each other. Note that it may also be possible to implant proton ions into the p-type second clad layer 117 between the p-type contact layer 118 and the p-type contact layer 118d in the second area 2A and thus increase the isolation resistance therebetween.

Next, as shown in FIGS. 45 to 48, in the first area 1A, the LD insulating film 119 is formed while, in the second area 2A, the modulator insulating film 120 is formed. For example, over the substrate 101, a silicon oxide film is deposited using a thermal CVD method or the like and patterned to be removed from over the mesa portion M1 and the second area 2A. Note that the silicon oxide film may also be left in the second area 2A. Then, over the substrate 101, as the modulator insulating film 120, an organic insulating film is formed. For example, onto the entire surface of the substrate 101, polyimide is applied and heated to form a polyimide film. Then, the polyimide film is etched back to leave the modulator insulating film 120 in the second area 2A.

Next, the modulator insulating film 120 over the p-type contact layer 118d is removed by etching to form the contact hole (see FIGS. 47 and 48). Then, over the entire surface of the substrate 101, a palladium (Pd) film and a platinum (Pt) film are successively formed by a vapor deposition method or the like. Then, a multi-layer film (not shown) including the palladium (Pd) film and the platinum (Pt) film is patterned to form the LD p-side electrode 122 over the p-type contact layer 118 in the first area 1A and form the modulator p-type electrode 123 over the p-type contact layer 118d in the second area 2A. Then, by performing a heating process, the metals forming each of the electrodes are alloyed to make an ohmic contact with the semiconductor layer.

Next, assuming that the back surface of the substrate 101 is the upper surface thereof, the back surface of the substrate 101 is polished to reduce the film thickness of the substrate 101. Then, over the back surface of the substrate 101, e.g., a titanium (Ti) film and a gold (Au) film are successively formed by a vapor deposition method or the like. Then, a heating process is performed to alloy these metals and form the n-side electrode 121.

Then, the substrate (wafer) 101 having a plurality of chip regions is cut into the individual chip regions. First, the substrate 101 is cleaved into the individual chip regions. Specifically, the substrate 101 is cleaved along a line of cleavage between a given chip region and a chip region adjacent thereto. Thus, cleavage surfaces (surfaces extending in the X-direction) are formed. Then, an anti-reflection film is formed over one of the cleavage surfaces, while a high-reflection film is formed over the other cleavage surface. The anti-reflection film is formed over the cleavage surface belonging the second area 2A. As the anti-reflection film, a dielectric film structure having a reflectivity of, e.g., 0.1% is used. This structure is formed by, e.g., a sputtering method or the like. The high-reflection film is formed over the cleavage surface belonging to the first area 1A (i.e., the front surface in FIG. 45). As the high-reflection film, a dielectric multi-layer body having a reflectivity of, e.g., not less than 75% is used. Each of the layers is formed by, e.g., a sputtering method or the like. Then, the substrate 101 is further cut along the sides of the chip regions extending in the Y-direction. Thus, the chip pieces are cut out. In the optical semiconductor integrated device, the length of the resonator of the laser element (length of the mesa portion in the Y-direction) is, e.g., 150 μm to 200 μm, while the length of the resonator of the modulator element (length of the mesa portion in the Y-direction) is, e.g., 50 μm to 200 μm.

By the foregoing steps, the optical semiconductor integrated device (EML in which the laser element and the modulator element are monolithically integrated) in the present first embodiment can be formed.

[Film Deposition Conditions for Semiconductor Layers Included in Mesa Portions]

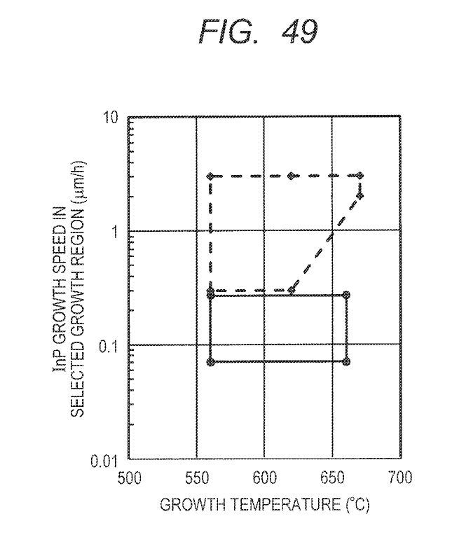

In the multi-layer body (the n-type optical guide layer 105, the active layer 106, the p-type optical guide layer 107, and the p-type semiconductor layer 108) included in the mesa portion M1, the upper layers are successively grown over the lower layers, but the upper layers are not grown over the side surfaces of the lower layers. It is preferable to select such growth conditions as described above. In particular, a semiconductor layer containing As (arsenic) mostly shows such a growth property as described above and is therefore appropriate as the constituent layer of the multi-layer body. By contrast, the p-type first clad layer 109 needs to cover not only the upper surface of the multi-layer body, but also each of the side surfaces thereof. When a semiconductor layer containing P (phosphorus) is used as the p-type first clad layer 109, the P-containing semiconductor layer mostly shows a growth property such that the P-containing semiconductor layer is grown also over the side walls, as described above. Accordingly, the P-containing semiconductor layer is appropriate as a cover layer for the multi-layer body. In addition, by adjusting a growth temperature and a growth speed as growth conditions for the p-type first clad layer (p-type InP layer) 109 such that the growth temperature and the growth speed fall within the region enclosed by the solid line in the graph shown in FIG. 49, the property of covering the multi-layer body can further be improved. FIG. 49 is a graph showing the relationship between an InP growth temperature and a growth speed, in which the ordinate axis represents the InP growth speed (μm/h) in a selected growth region and the abscissa axis shows the growth temperature (OC).

For example, when it is assumed that growth conditions include a growth temperature Tg (OC) and a growth speed Rg (m/h), the growth conditions are preferably a combination of the growth temperature and the growth speed which is determined within the region defined by connecting the four points (Tg,Rg)=(560,0.27) (660,0.27) (660,0.07) (560,0.07) (range enclosed by the solid line in FIG. 49). By using the growth conditions, the p-type InP first clad layer 109 is allowed to more reliably cover the entire circumferences of the multi-layer bodies included in the mesa portions M1 and M2, resulting in an enhanced protective effect. Note that the range enclosed by the broken line in FIG. 49 is the range of InP film deposition conditions in Patent Document 4 described above.

### Embodiment 2

In the first embodiment, the mesa portions M1 and M2 are directly coupled together via the p-type first clad layer 109. However, an optical waveguide may also be provided between the mesa portions M1 and M2. Note that the same portions as in the case in the first embodiment are designated by the same reference numerals and a detailed description thereof is omitted.

Referring to the drawings, the following will describe an optical semiconductor integrated device in the present second embodiment in detail. The optical semiconductor integrated device in the present second embodiment is an EML in which a laser element and a modulator element are monolithically integrated. The laser element and the modulator element are optically coupled together via an optical waveguide. The laser element, the modulator element, and the optical waveguide respectively have the mesa portions M1 and M2 and a mesa portion M3 which are provided so as to be connected above a substrate.

By thus providing the optical waveguide between the laser element and the modulator element, the accuracy of isolation between the laser element and the modulator element is enhanced and the interference between the elements is reduced to allow, e.g., an optical waveform during high-speed modulation to be excellently maintained. Specifically, wavelength fluctuations and an eye opening can be improved.

First, a description will be given herein of respective configurations of the mesa portions included in the optical semiconductor integrated device and a manufacturing process thereof and then of a configuration of the entire optical semiconductor integrated device and a manufacturing process thereof.

### [Configurations of Mesa Portions and Manufacturing Process]

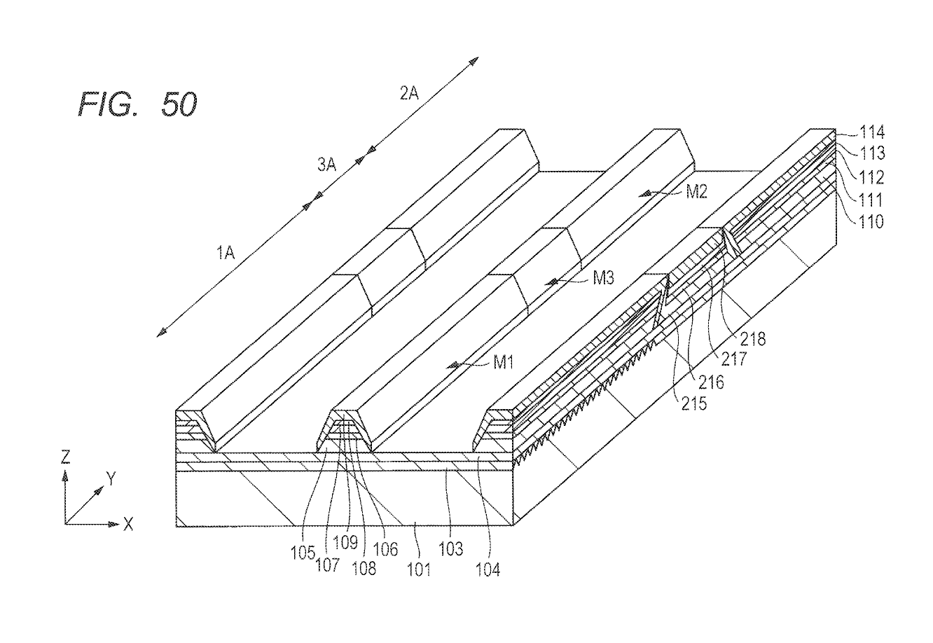

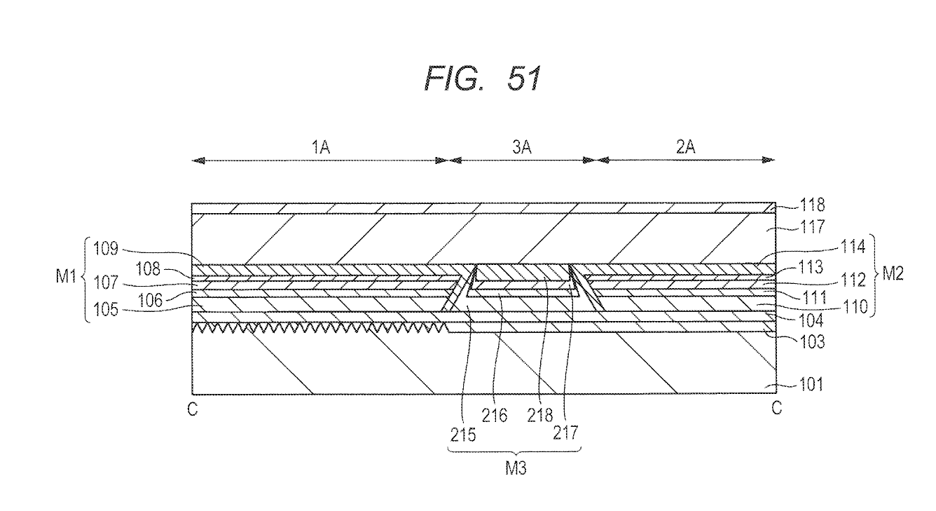

FIG. 50 is a perspective view showing the configurations of the mesa portions of the optical semiconductor integrated device in the present second embodiment. FIG. 51 is a cross-sectional view.

Since the mesa portions M1 and M2 forming the laser element and the modulator element which are shown in FIG. 50 have the same configurations as those in the case in the first embodiment, a description thereof is omitted.

As shown in FIGS. 50 and 51, the optical waveguide is disposed in a third area 3A of the substrate 101. The optical waveguide has the mesa portion M3, and the mesa portion M3 extends in the Y-direction so as to connect the mesa portions M1 and M2. The mesa portion M3 includes a waveguide non-doped optical guide layer 215, a waveguide core layer 216, a waveguide non-doped optical guide layer 217, and a waveguide non-doped first clad layer (protective layer) 218. Note that, in the mesa portion M3, a layer corresponding to the p-type semiconductor layer 108 of the mesa portion M1 may also be provided.

Any of the waveguide non-doped optical guide layer 215, the waveguide core layer 216, and the waveguide non-doped optical guide layer 217 is made of a semiconductor layer containing Al, while the waveguide non-doped first clad layer 218 is made of a semiconductor layer not containing Al. For example, the waveguide non-doped optical guide layer 215, the waveguide core layer 216, the waveguide non-doped optical guide layer 217, and the waveguide non-doped first clad layer 218 are made of a non-doped AlGaInAs layer (215), an AlGaInAs layer (216), a non-doped AlGaInAs layer (217), and a non-doped InP layer (218). By thus using the non-doped layers as the layers of the mesa portion M3 included in the optical waveguide, it is possible to reduce an optical absorption loss in the optical waveguide and a leakage current from the laser element to the optical waveguide. In addition, the optical waveguide accelerates the dissipation of heat generated in the laser element and reduces the influence of the thermal saturation of an optical output and a modulation speed in the high-temperature operation of the device, resulting in improvements in the properties of the device during the high-temperature operation thereof. The waveguide region may also include an InGaAsP-based layer not containing Al.

Referring to the drawings, the following will describe a manufacturing process of the mesa portions.

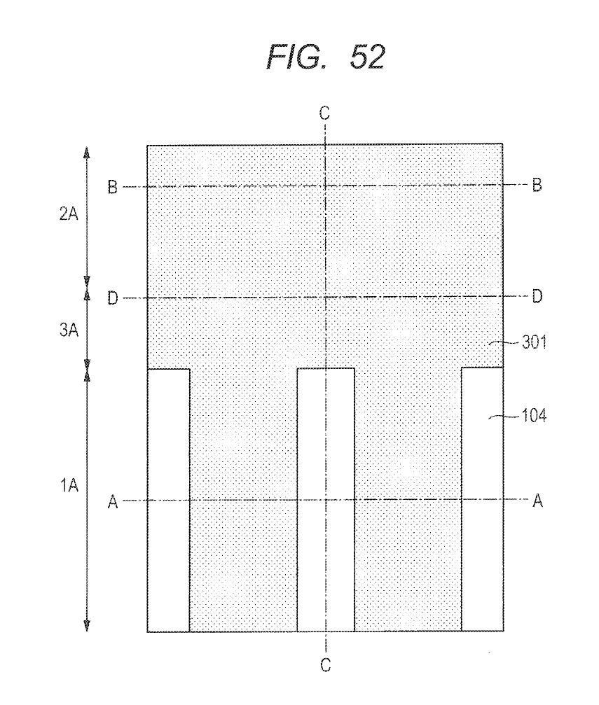

FIGS. 52 to 54 are plan views showing the characteristic features of the manufacturing process of the mesa portions in the optical semiconductor integrated device in the present second embodiment.

First, in the same manner as in the case in the first embodiment, the mask film 301 having the opening corresponding to the region of the first area 1A where the mesa portion is to be formed is formed (FIG. 52). Then, over the n-type buffer layer (n-type InP layer) 104 exposed from the opening of the mask film 301, the mesa portion M1 is formed. Specifically, over the n-type buffer layer (n-type InP layer) 104 exposed from the opening of the mask film 301, the n-type optical guide layer 105, the active layer 106, the p-type optical guide layer 107, and the p-type semiconductor layer 108 are successively grown to form a multi-layer body. Subsequently, over the upper surface and each of the side surfaces of the foregoing multi-layer body, the p-type first clad layer 109 is grown. Then, the substrate 101 is retrieved from an MOVPE device, and the mask film (silicon oxide film) 301 over the substrate 101 is removed therefrom by etching.

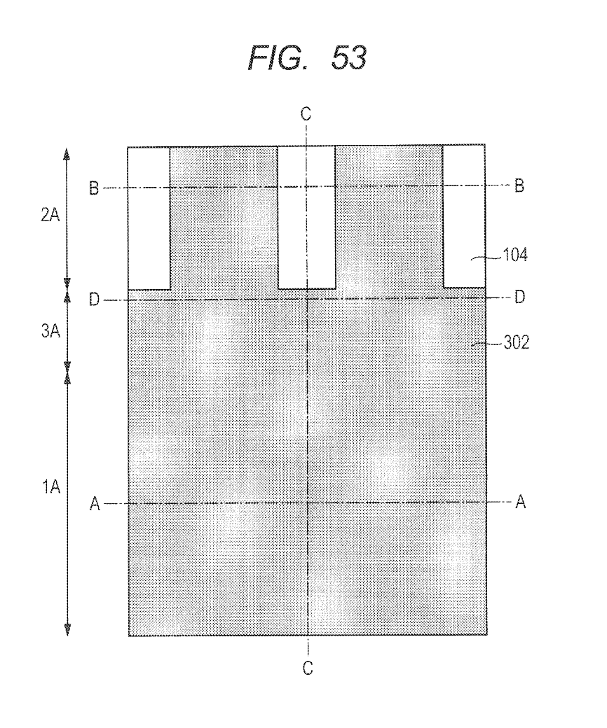

Then, in the same manner as in the case in the first embodiment, the mask film 302 having the opening corresponding to the region of the second area 2A where the mesa portion is to be formed is formed (FIG. 53). Then, over the n-type buffer layer (n-type InP layer) 104 exposed from the opening of the mask film 302, the mesa portion M2 is formed. Specifically, over the n-type buffer layer (n-type InP layer) 104 exposed from the opening of the mask film 302, the modulator n-type optical guide layer 110, the absorption layer 111, the modulator p-type optical guide layer 112, and the modulator p-type semiconductor layer 113 are successively grown to form a multi-layer body. Subsequently, over the upper surface and each of the side surfaces of the foregoing multi-layer body, the modulator p-type first clad layer 114 is formed. Each of the layers can be formed by an MOVPE method. Then, the substrate 101 is retrieved from an MOVPE device, and the mask film (silicon oxide film) 302 over the substrate 101 is removed therefrom by etching.

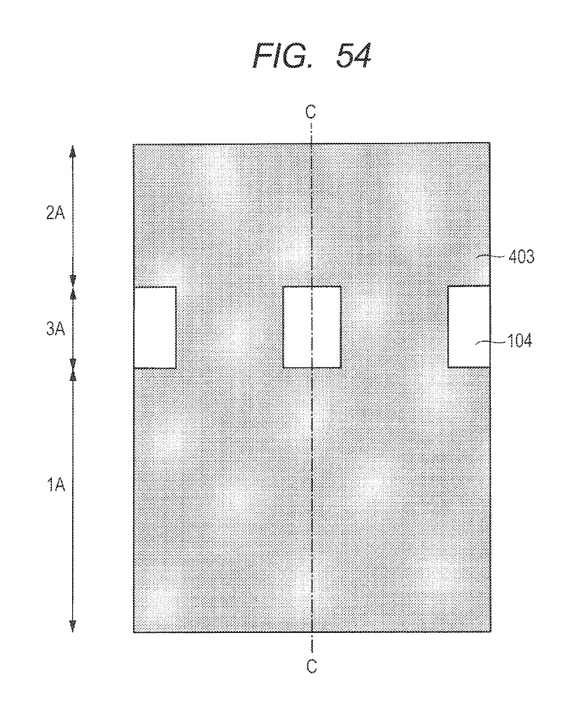

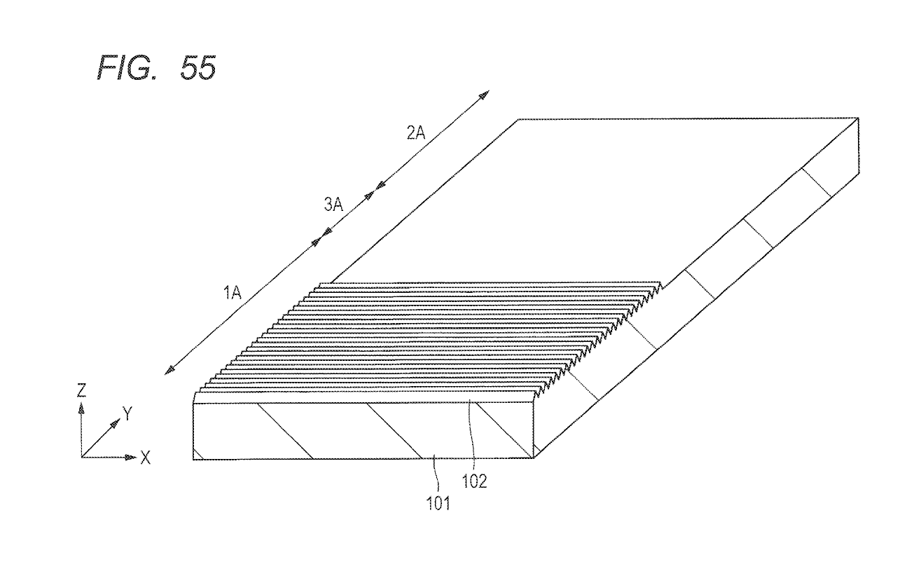

Next, a mask film 403 having an opening corresponding to the region of the third area 3A where the mesa portion is to be formed is formed (FIG. 54). Then, over the n-type buffer layer (n-type InP layer) 104 exposed from the opening of the mask film 403, the mesa portion M3 is formed. Specifically, over the n-type buffer layer (n-type InP layer) 104 exposed from the opening of the mask film 403, the waveguide non-doped optical guide layer 215, the waveguide core layer 216, and the waveguide non-doped optical guide layer 217 are successively grown to form a multi-layer body. Subsequently, over the upper surface of the foregoing multi-layer body, the waveguide non-doped first clad layer 218 is formed. Each of the layers can be formed by an MOVPE method. Then, the substrate 101 is retrieved from an MOVPE device, and the mask film (silicon oxide film) 403 over the substrate 101 is removed therefrom by etching.

Thus, the mesa portion M1 in the first area 1A, the mesa portion M2 in the second area 2A, and the mesa portion M3 in the third area 3A can be formed.

In the case in the present second embodiment also, as described in detail in the first embodiment, it is possible to prevent unneeded aluminum oxide from being generated.

Specifically, according to the present second embodiment, as described above, the configuration is adopted in which the mesa portions M1, M2, and M3 are formed using the masks (301, 302, and 403), while the multi-layer bodies of the mesa portions M1, M2, and M3 are covered with the first clad layers (109, 114, and 218) not containing Al. This can prevent the unneeded aluminum oxide described in the first embodiment from being generated.

Thus, it is possible to improve the properties of the elements (such as the laser element and the modulator element) integrated in the optical semiconductor integrated device and improve the properties of the optical semiconductor integrated device.

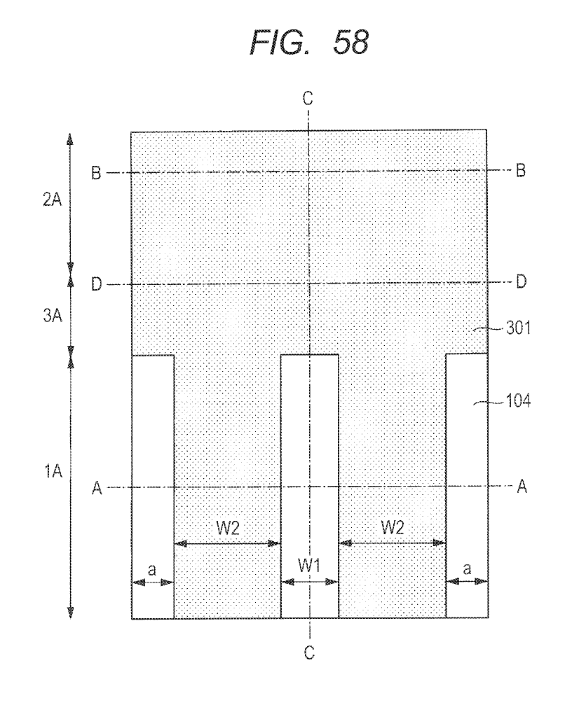

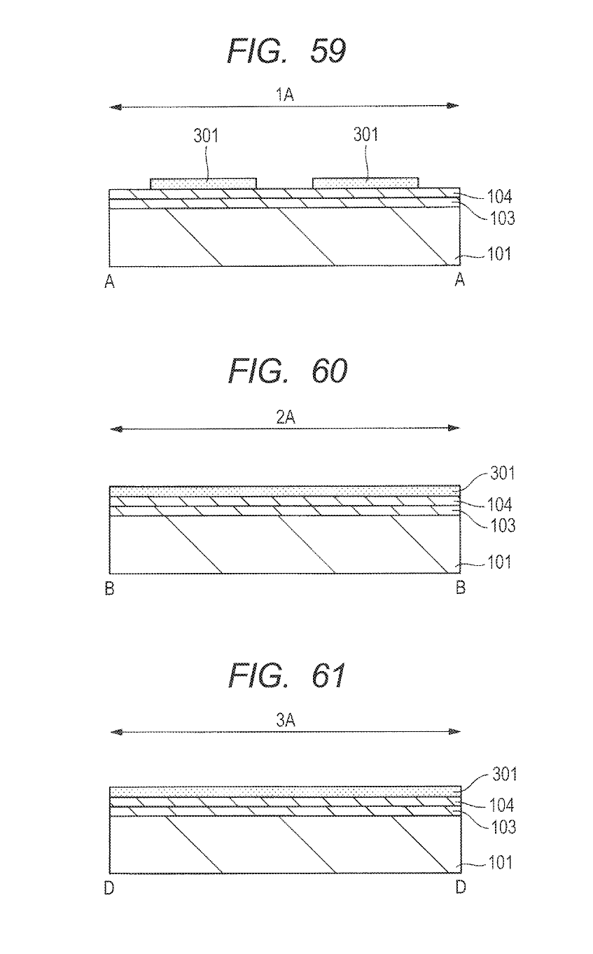

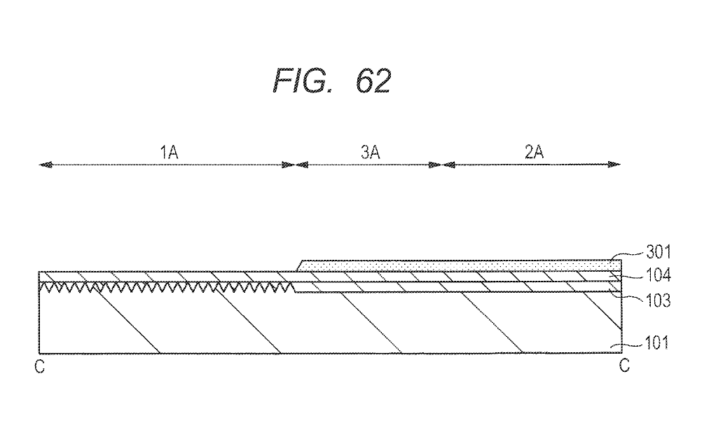

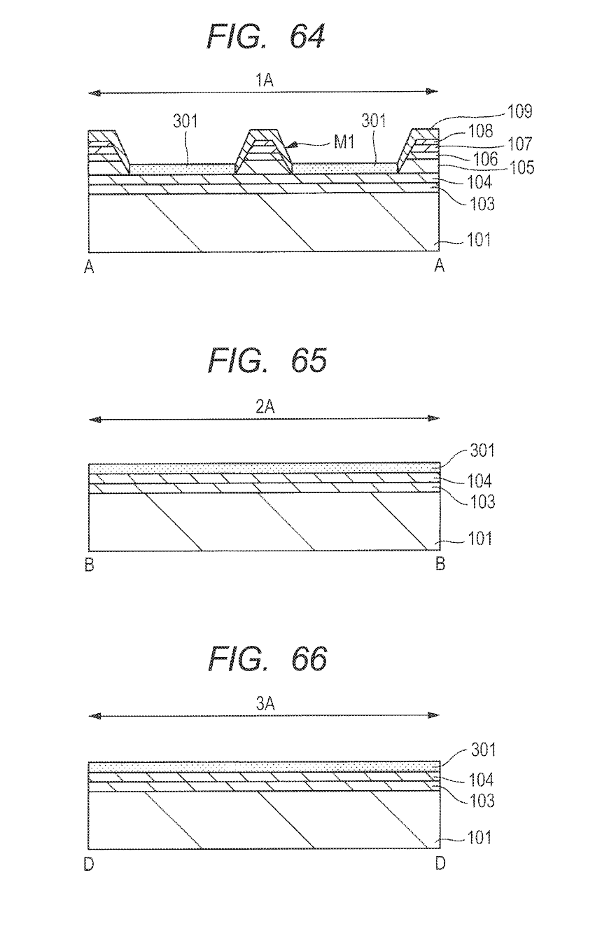

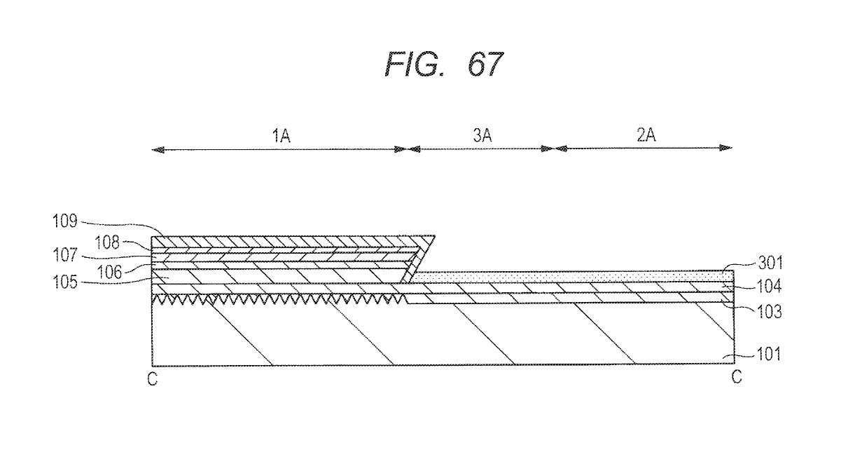

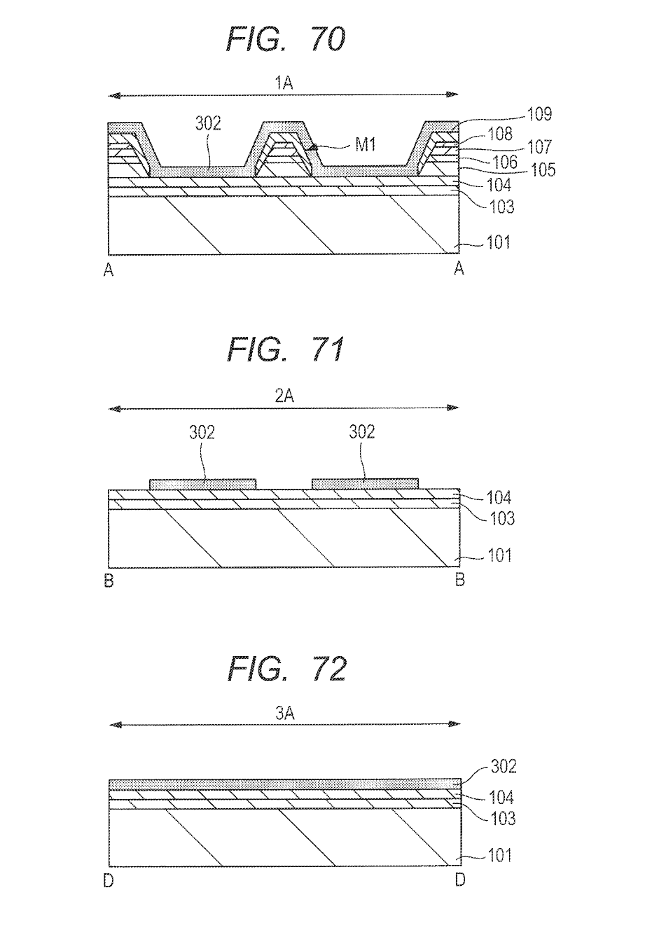

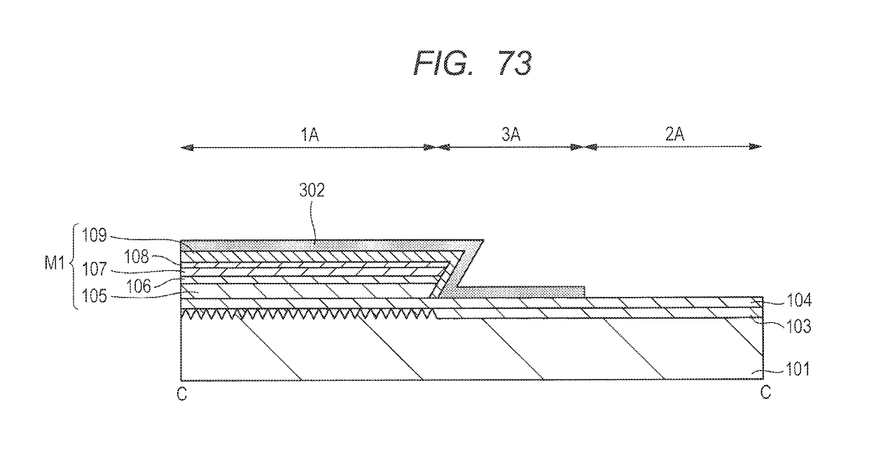

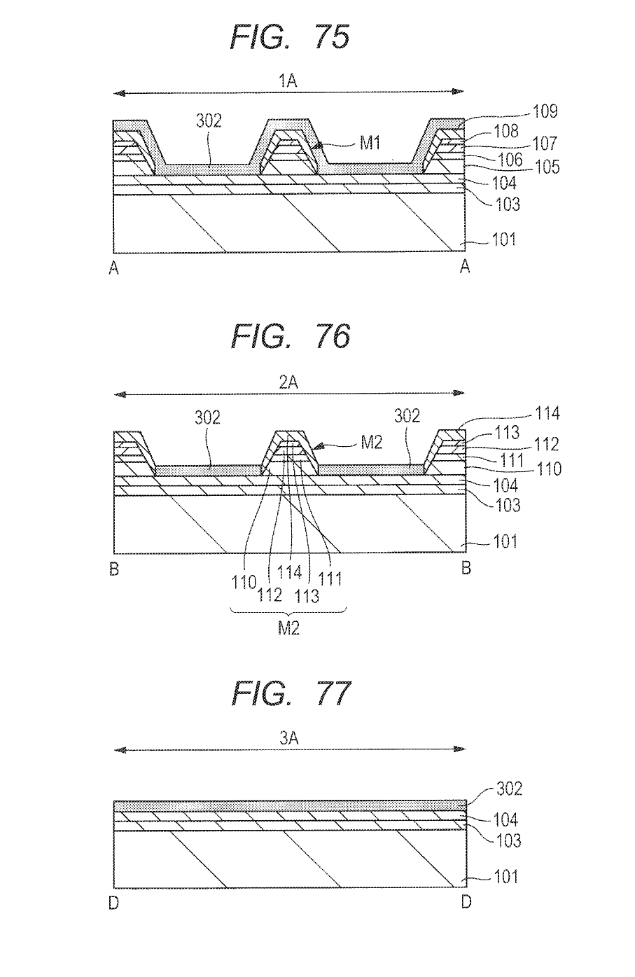

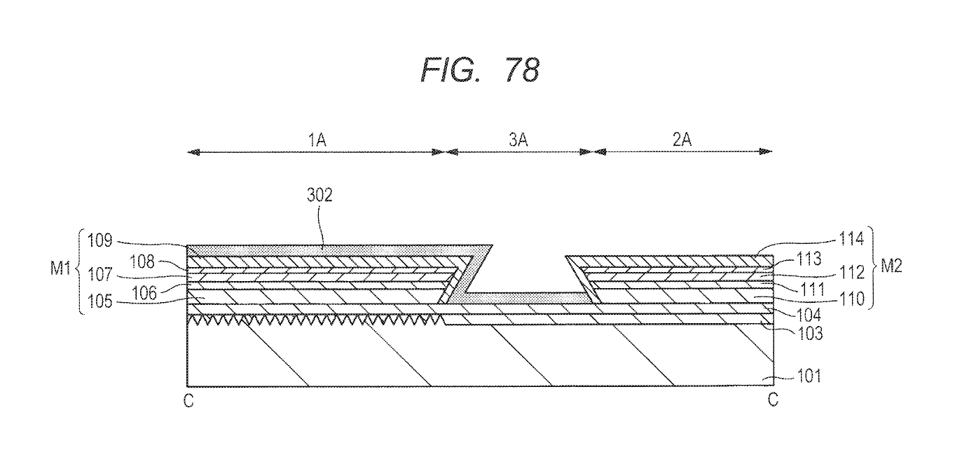

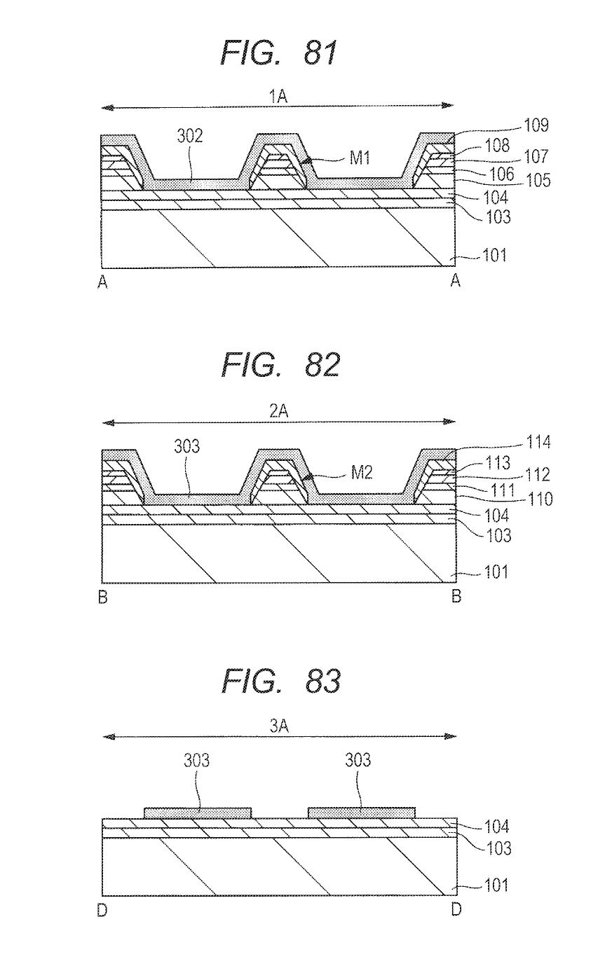

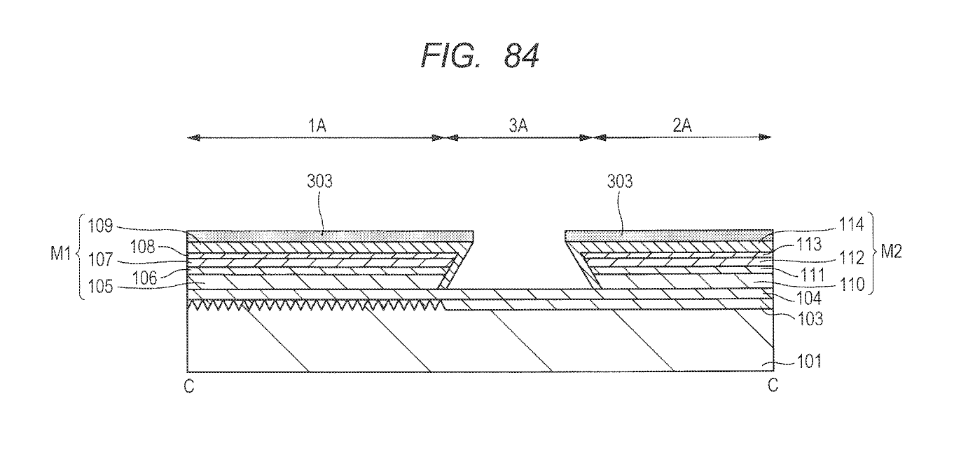

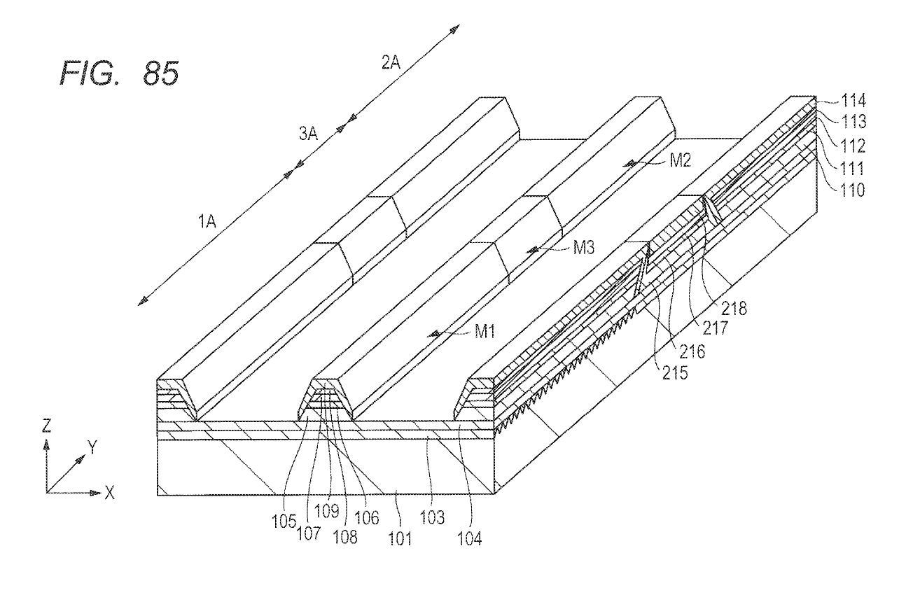

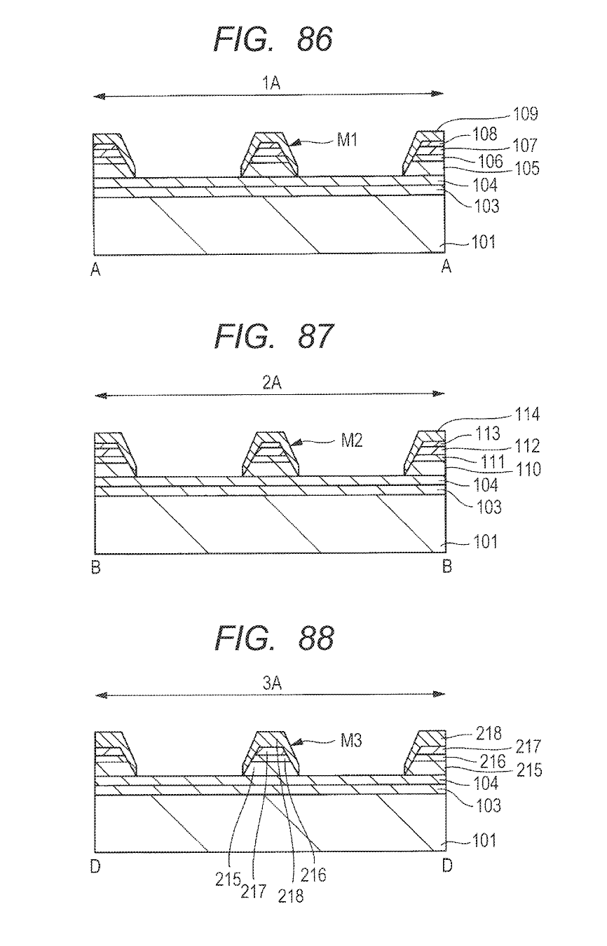

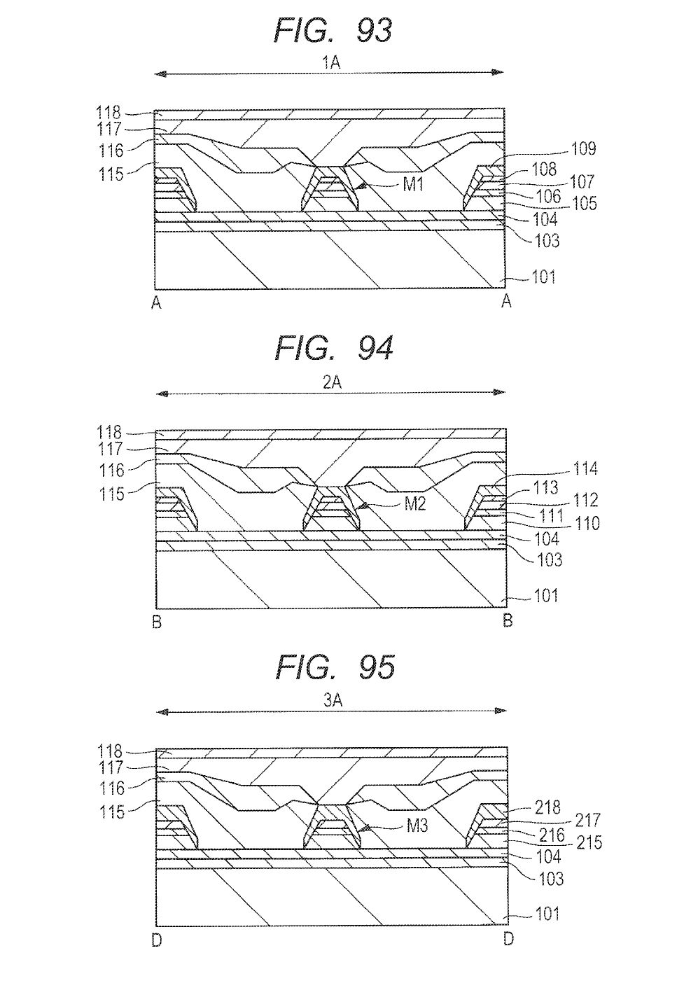

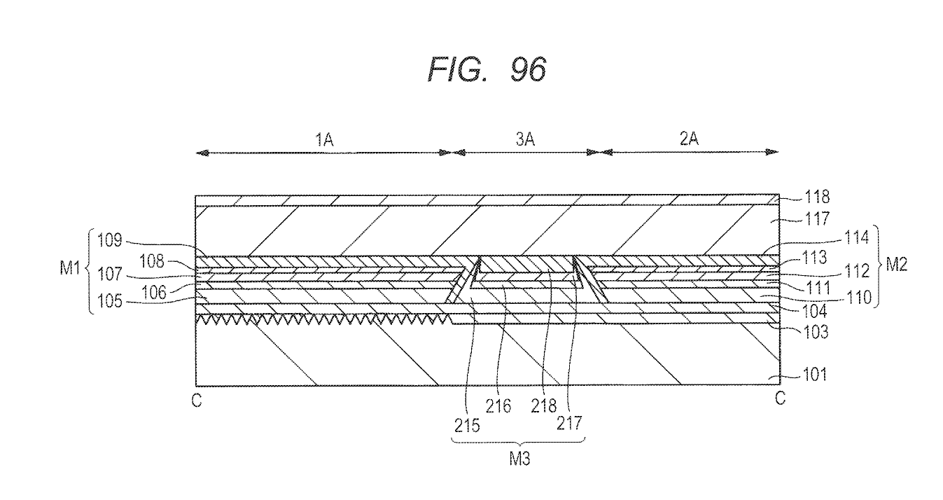

Next, referring to the drawings, a description will be given of a structure of the optical semiconductor integrated device in the present second embodiment and a manufacturing process thereof. FIGS. 55 to 99 are views (perspective views, cross-sectional views, and plan views) showing the manufacturing process of the optical semiconductor integrated device in the present second embodiment. The cross-sectional views correspond to cross-sectional portions along the lines A-A, B-B, C-C, and D-D in the plan views.

[Description of Structure]

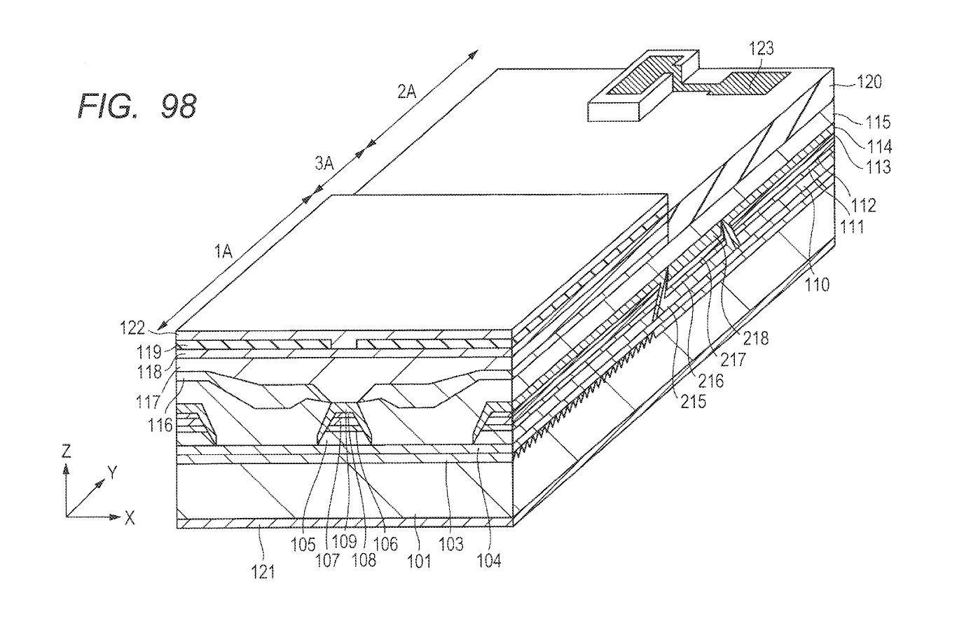

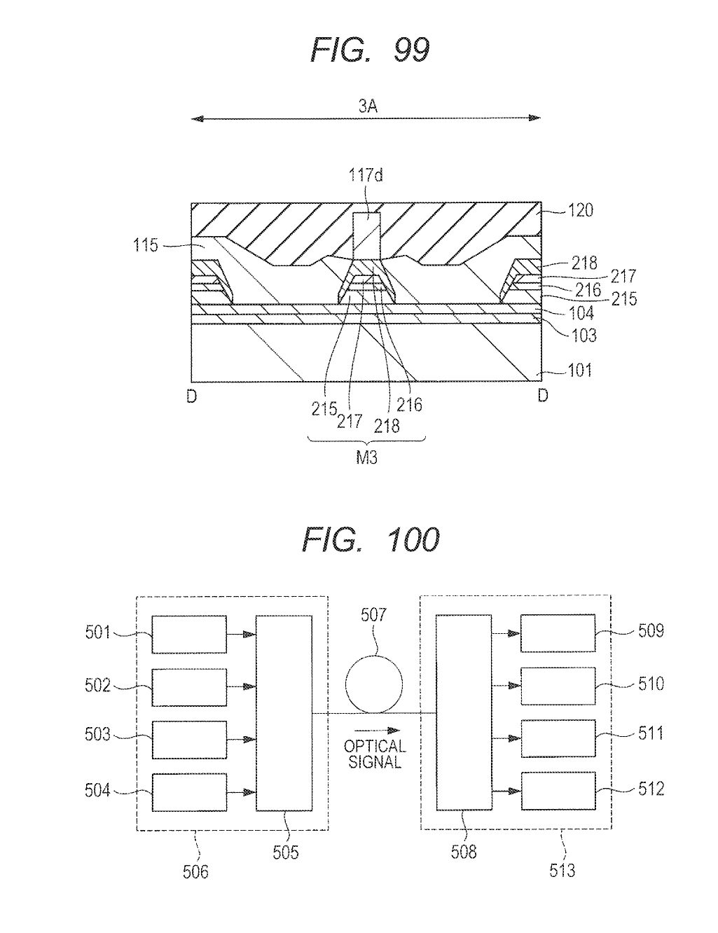

The following will describe the structure of the optical semiconductor integrated device in the present second embodiment with reference to FIGS. 98 and 99 as final step views. FIG. 99 is a cross-sectional view of the third area 3A in FIG. 98 along the X-direction.

The optical semiconductor integrated device in the present second embodiment shown in FIG. 98 includes the substrate 101, the diffraction grating 102 disposed in the surface portion of the substrate 101, the n-type guide layer 103, and the n-type buffer layer 104, which are successively disposed in the upward direction.

The substrate 101 is made of, e.g., an n-type InP layer. The substrate 101 functions also as an n-type clad layer. The diffraction grating 102 is made of the depressions/projections of the surface portion of the substrate 101. The n-type guide layer 103 is provided so as to fill up the space over the second area 2A and the third area 3A of the substrate 101 and the depressions of the surface portion of the substrate 101 included in the diffraction grating 102. The n-type guide layer 103 is made of, e.g., an n-type InGaAsP layer. The n-type buffer layer 104 is made of, e.g., an n-type InP layer.

In the first area 1A of the substrate 101, the laser element is provided. In the second area 2A of the substrate 101, the modulator element is provided. In the third area 3A of the substrate 101, the optical waveguide is provided. The third area 3A is located between the first area 1A and the second area 2A. The optical waveguide is provided so as to optically couple together the laser element and the modulator element.

<Laser Element>

A configuration of the laser element is the same as in the case in the first embodiment (see FIG. 46). In the first area 1A of the substrate 101, at the generally middle portion of the foregoing n-type buffer layer 104, the mesa portion M1 is provided to extend in the Y-direction. The mesa portion M1 has the multi-layer body in which the n-type optical guide layer 105, the active layer 106, the p-type optical guide layer 107, and the p-type semiconductor layer 108 are successively stacked in the upward direction and the p-type first clad layer 109 covering the upper surface and each of the side surfaces of the multi-layer body.

In addition, the current block layers 115 and 116 are provided so as to fill up the spaces on both sides of the mesa portion M1. Over the mesa portion M1 and over the current block layers 115 and 116, the p-type second clad layer 117 and the p-type contact layer 118 are successively disposed in the upward direction.

Thus, the laser element has a structure in which the active layer 106 is interposed between the group III-V compound semiconductor layers having the opposite conductivity types and located as the upper layer and the lower layer.

Over the uppermost p-type contact layer 118, the p-side electrode 122 is disposed. Under the back surface of the n-type substrate 101, the n-side electrode 121 is disposed. Note that, between the p-type contact layer 118 and the p-side electrode 122, the LD insulating film 119 is provided. Above the mesa portion M1, the p-type contact layer 118 and the p-type electrode 122 are coupled together.

<Modulator Element>

A configuration of the modulator element is the same as in the case in the first embodiment (see FIG. 47). In the second area 2A of the substrate 101, at the generally middle portion of the foregoing n-type buffer layer 104, the mesa portion M2 is provided to extend in the Y-direction. The mesa portion M2 has the multi-layer body in which the modulator n-type optical guide layer 110, the absorption layer 111, the modulator p-type optical guide layer 112, and the modulator p-type semiconductor layer 113 are successively stacked in the upward direction and the modulator p-type optical guide layer 112 covering the upper surface and each of the side surfaces of the multi-layer body.

In addition, the current block layer 115 is provided so as to fill up the spaces on both sides of the mesa portion M2. Over the mesa portion M2, the p-type second clad layer 117d and the p-type contact layer 118d are successively disposed in the upward direction. On both sides of the resulting multi-layer body (117d and 118d), the modulator insulating film 120 is provided (FIG. 47). The p-type second clad layer 117d in the second area 2A is equal in level to the p-type second clad layer 117 in the first area 1A and coupled to the p-type second clad layer 117 in the first area 1A. The p-type contact layer 118d in the second area 2A is equal in level to the p-type contact layer 118 in the first area 1A and is not coupled to (is isolated from) the p-type contact layer 118 in the first area 1A.

Thus, the modulator element has the structure in which the absorption layer 111 is interposed between the group III-V compound semiconductor layers having the opposite conductivity types and disposed as the upper layer and the lower layer.

Over the p-type contact layer 118d, the modulator p-type electrode 123 is placed. As described above, under the back surface of the n-type substrate 101, the n-side electrode 121 is disposed. Note that the p-type contact layer 118d and the modulator p-type electrode 123 are coupled together via the contact hole provided in the modulator insulating film 120.

<Optical Waveguide>

In the third area 3A of the substrate 101, at the generally middle portion of the foregoing n-type buffer layer 104, the mesa portion M3 is provided to extend in the Y-direction (FIG. 50). As shown in FIG. 99, the mesa portion M3 has a multi-layer body in which the waveguide non-doped optical guide layer 215, the waveguide core layer 216, and the waveguide non-doped optical guide layer 217 are successively stacked in the upward direction and the waveguide non-doped first clad layer 218 covering the multi-layer body.

In addition, the current block layer 115 is provided so as to fill up the spaces on both sides of the mesa portion M3. Over the mesa portion M3, the p-type second clad layer 117d is disposed and, on both sides of the p-type second clad layer 117d, the modulator insulating film 120 is provided (FIG. 99). The p-type second clad layer 117d in the third area 3A is equal in level to the p-type second clad layer 117 in the first area 1A and coupled to the p-type second clad layer 117 in the first area 1A.

As described above, to improve the respective properties of the individual elements, the respective layers included in the mesa portions may have different element composition ratios or different film thicknesses. Also, in the mesa portion M3, a layer corresponding to the p-type semiconductor layer 108 of the mesa portion M1 is not provided so that the mesa portion M3 includes the four semiconductor layers. Thus, the numbers of the constituent layers of the mesa portions M1 to M3, the element composition ratios of the constituent layers thereof, and the film thicknesses of the constituent layers thereof may also differ from each other.

Thus, according to the present second embodiment, the respective configurations of the laser element, the modulator element, and the optical waveguide can be independently designed, and optimal crystallization conditions (such as growth temperatures) can be set therefor. This allows the respective element properties (such as the maximum optical output property of the laser element and the extinction ratio property of the modulator element) to be independently optimized.

In addition, in the present second embodiment, in the mesa portions M1 to M3, the foregoing multi-layer bodies including the semiconductor layers containing Al are covered with the first clad layers (109, 114, and 218) not containing Al. This can prevent unneeded aluminum oxide from being generated and improve the crystallinities of the constituent layers of the device. This can also allow excellent optical coupling between the mesa portions M1 and M3 and between the mesa portions M2 and M3 to be maintained.

[Description of Manufacturing Method]

Next, referring to FIGS. 55 to 99, a method of manufacturing the optical semiconductor integrated device in the present second embodiment will be described, while a configuration of the optical semiconductor integrated device will be more clearly shown. Since the configurations of the first area and the second area in the present second embodiment are the same as the configurations of the first area and the second area in the first embodiment, the manufacturing processes of these configurations in the first and second embodiments have many common steps. Accordingly, a detailed description of the same steps as in the first embodiment is omitted.

As described above, the optical semiconductor integrated device in the present second embodiment includes the laser element formed in the first area 1A of the substrate 101, the modulator element formed in the second area 2A of the substrate 101, and the optical waveguide formed in the third area 3A of the substrate 101. The third area 3A is located between the first area 1A and the second area 2A. The optical waveguide has the function of optically coupling together the laser element and the modulator element.

As shown in FIG. 55, in the same manner as in the first embodiment, a substrate made of indium phosphorus (InP) in which, e.g., an n-type impurity is introduced is provided, and the diffraction grating 102 is formed therein.

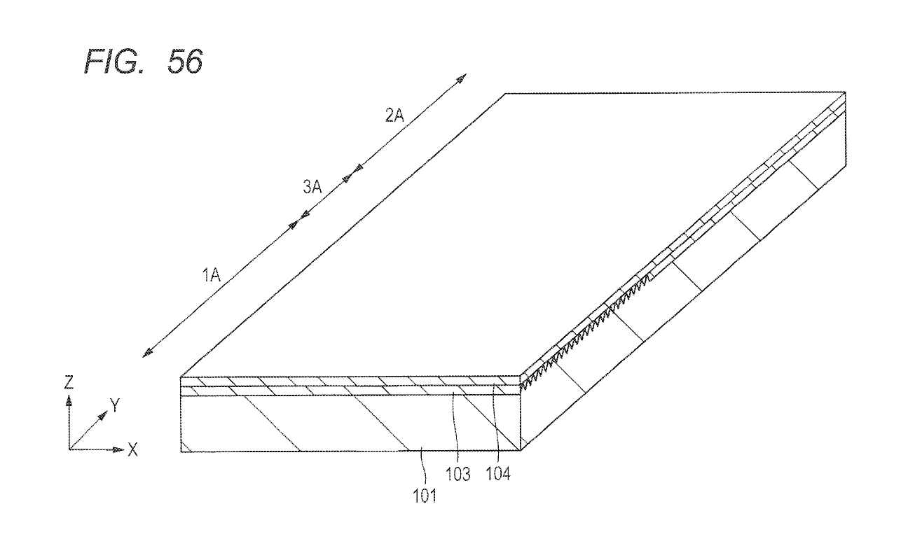

Next, as shown in FIG. 56, in the same manner as in the first embodiment, the n-type guide layer 103 is formed so as to fill up the space over the second area 2A and the third area 3A of the substrate 101 and the depressions of the diffraction grating 102 using an MOVPE method. Then, over the n-type guide layer 103, the n-type buffer layer 104 is further formed.

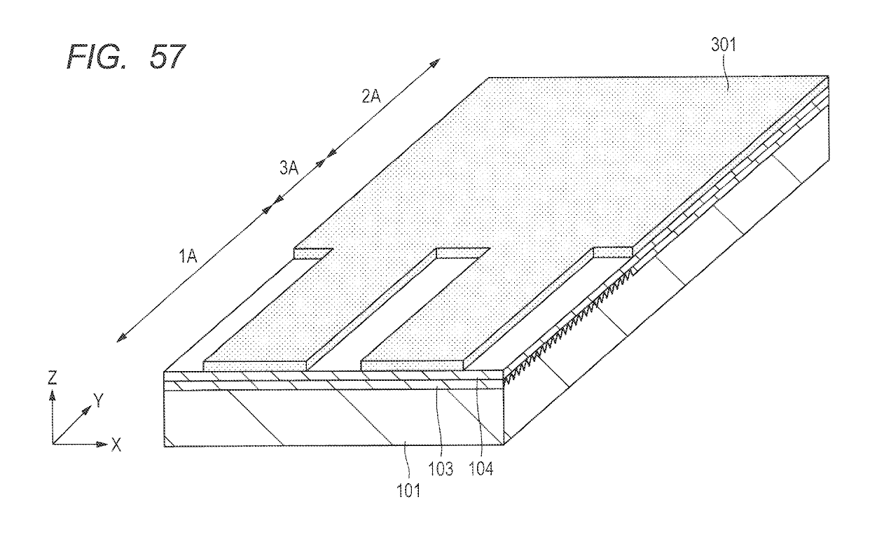

Next, the substrate 101 is retrieved from an MOVPE device and, as shown in FIGS. 57 to 62, over the n-type buffer layer (n-type InP layer) 104, the mask film 301 having the opening corresponding to the region of the first area 1A where the mesa portion M1 is to be formed is formed. The mask film 301 can be formed in the same manner as in the case in the first embodiment.

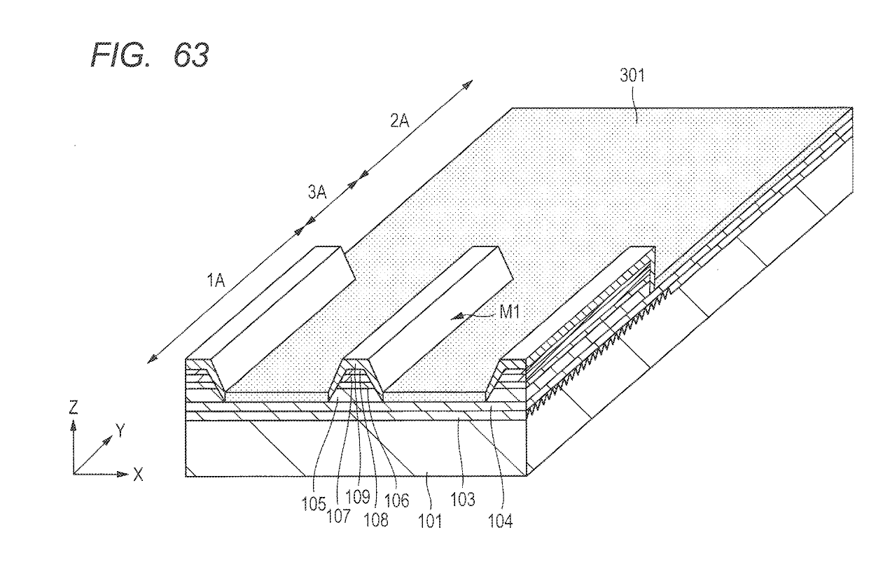

Next, as shown in FIGS. 63 to 57, over the n-type buffer layer (n-type InP layer) 104 exposed from the opening of the mask film 301, the mesa portion M1 is formed. In the same manner as in the case in the first embodiment, using an MOVPE method, the multi-layer body (the n-type optical guide layer (n-type AlGaInAs layer) 105, the active layer (AlGaInAs well layers and AlGaInAs barrier layers) 106, the p-type optical guide layer (p-type AlGaInAs layer) 107, and the p-type semiconductor layer (p-type AlInAs layer) 108) is formed. The p-type first clad layer (p-type InP layer) 109 is formed so as to cover the upper surface and each of the side surfaces of the multi-layer body.

Then, the substrate 101 is retrieved from the MOVPE device, and the mask film (silicon oxide film) 301 over the substrate 101 is removed therefrom by etching.

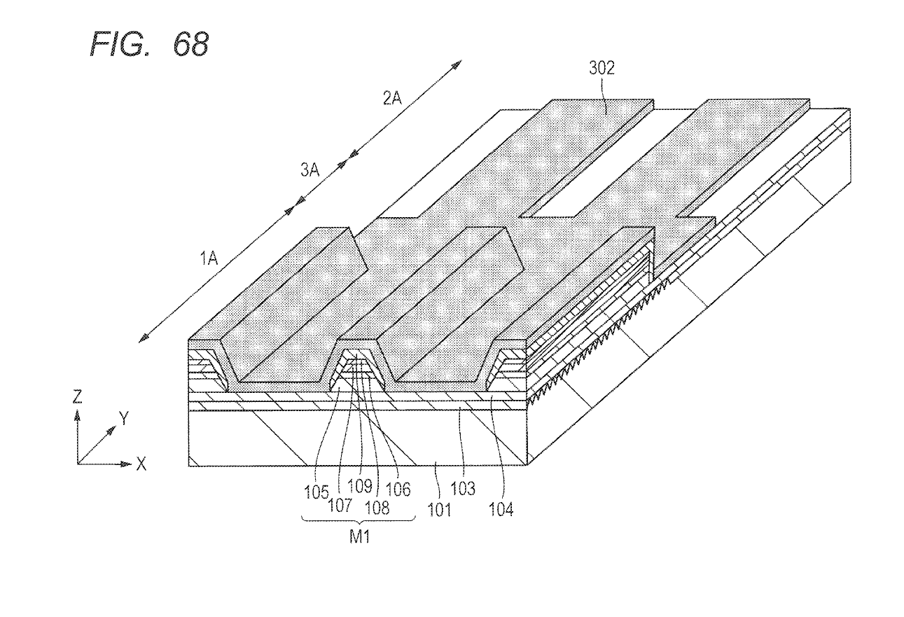

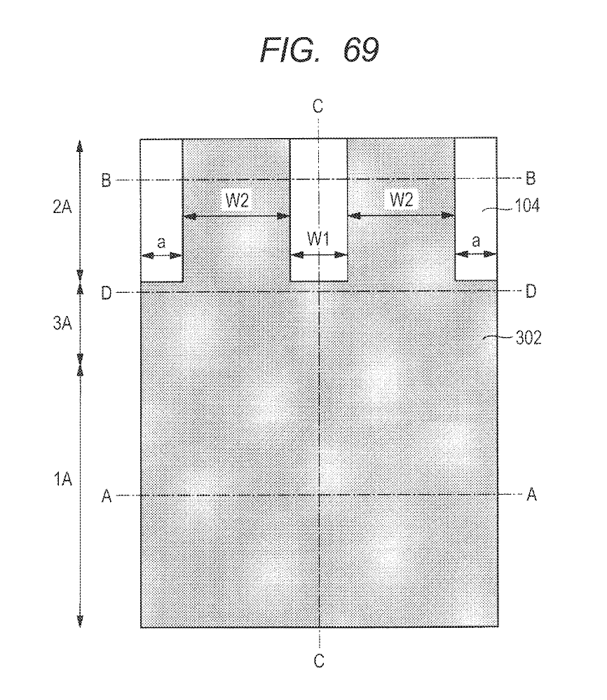

Next, as shown in FIGS. 68 to 73, the substrate 101 is retrieved from the MOVPE device and, over the mesa portion M1 and over the n-type buffer layer (n-type InP layer) 104, the mask film 302 having the opening corresponding to the region of the second area 2A where the mesa portion is to be formed is formed. The mask film 302 can be formed in the same manner as in the case in the first embodiment.

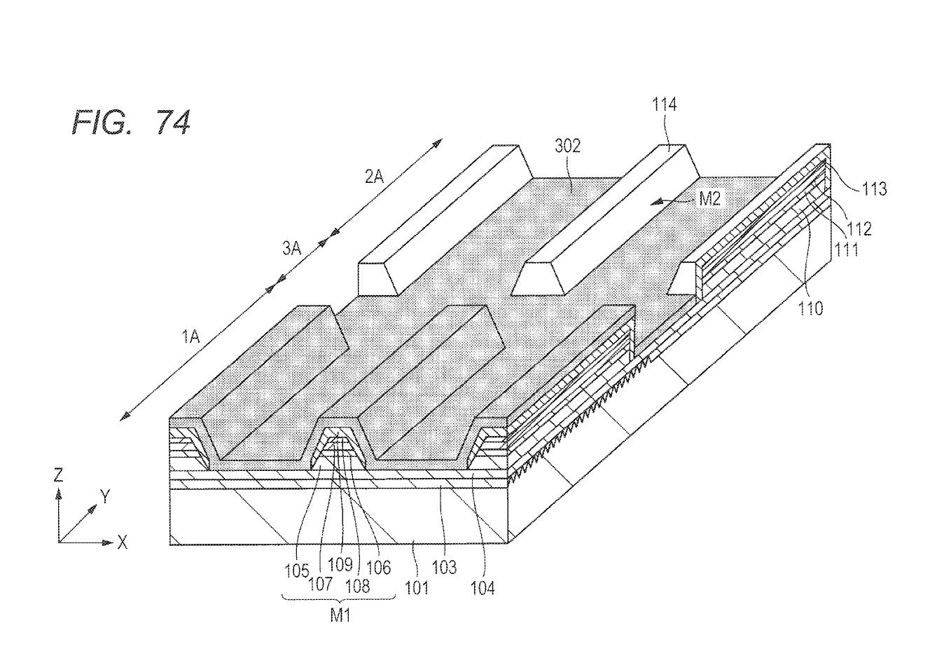

Next, as shown in FIGS. 74 to 78, over the n-type buffer layer (n-type InP layer) 104 exposed from the opening of the mask film 302, the mesa portion M2 is formed. In the same manner as in the case in the first embodiment, using an MOVPE method, the multi-layer body (the modulator n-type optical guide layer (n-type AlGaInAs layer) 110, the absorption layer (AlGaInAs well layers and AlGaInAs barrier layers) 111, the modulator p-type optical guide layer (p-type AlGaInAs layer) 112, and the modulator p-type semiconductor layer (p-type AlInAs layer) 113) is formed. The modulator p-type first clad layer (p-type InP layer) 114 is formed so as to cover the upper surface and each of the side surfaces of the multi-layer body.

Then, the substrate 101 is retrieved from the MOVPE device, and the mask film (silicon oxide film) 302 over the substrate 101 is removed therefrom by etching.

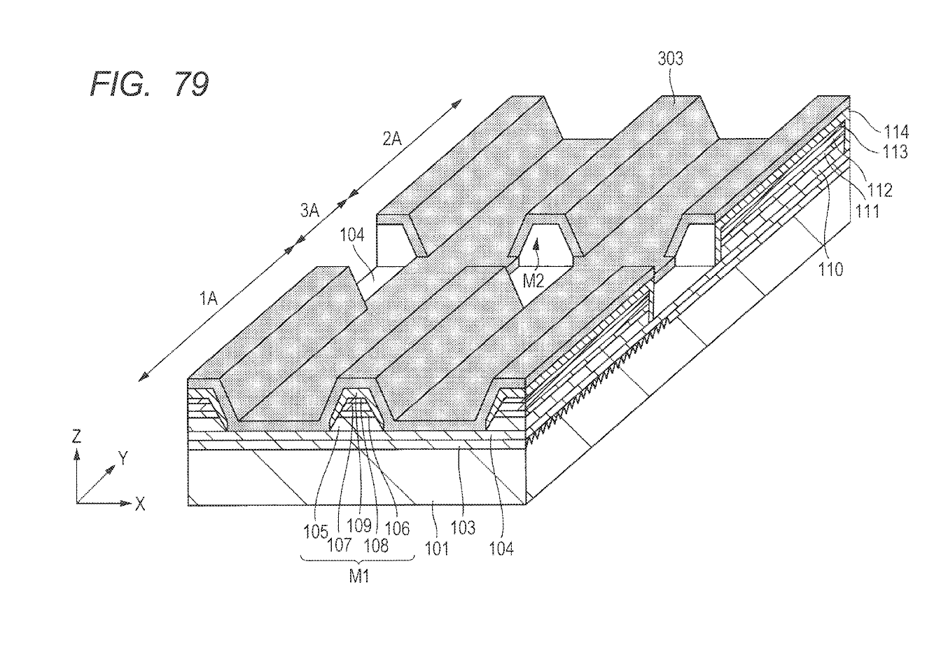

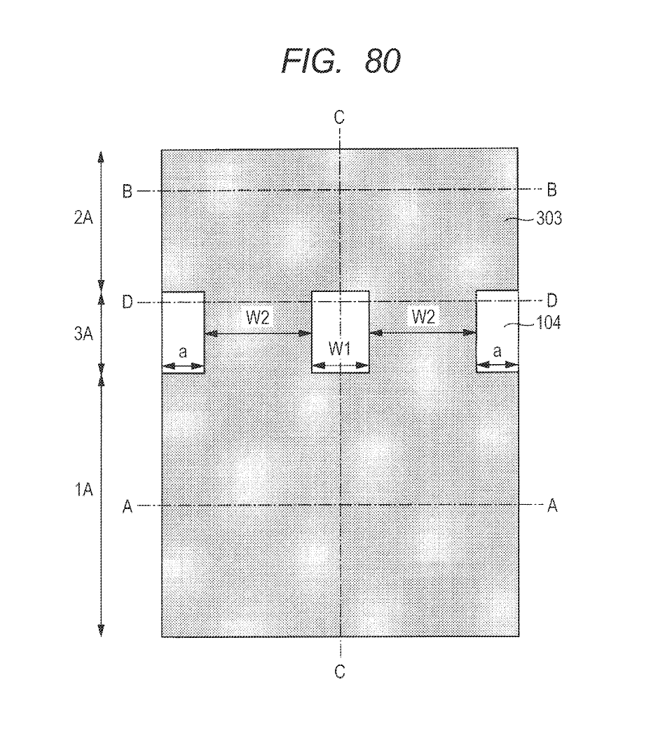

Next, as shown in FIGS. 79 to 84, the substrate 101 is retrieved from the MOVPE device and, over the mesa portions M1 and M2 and over the n-type buffer layer (n-type InP layer) 104, a mask film 303 having an opening corresponding to the region of the third area 3A where the mesa portion M3 is to be formed is formed. The mask film 303 is different from each of the mask films 301 and 302 in terms of the position of the opening, and can be formed similarly to the mask films 301 and 302. The region where the mesa portion M3 is to be formed has a generally rectangular shape in plan view and a width (W1) of, e.g., about 1 to 2 μm (FIG. 80). The mask film 303 in the third area 3A has a generally rectangular shape in plan view and a width (W2) of about 3 to 20 m. The direction in which the mask film 303 in the third area 3A extends is a [011] direction. Note that, outside the mask film 303, there is the area a where the n-type buffer layer (n-type InP layer) 104 is exposed.

Next, as shown in FIGS. 85 to 89, over the n-type buffer layer (n-type InP layer) 104 exposed from the opening of the mask film 303, the mesa portion M3 is formed. Then, the substrate 101 is retrieved from the MOVPE device, and the mask film (silicon oxide film) 303 over the substrate 101 is removed therefrom by etching.

For example, over the n-type buffer layer (n-type InP layer) 104 exposed from the opening of the mask film 303, the waveguide non-doped optical guide layer 215, the waveguide core layer 216, the waveguide non-doped optical guide layer 217, and the waveguide non-doped first clad layer 218 are successively grown (see FIG. 88). In the growth step, the layers are not grown over the mask film 303 so that the mesa portion M3 is formed over the n-type buffer layer (n-type InP layer) 104 exposed from the opening of the mask film 303.

Specifically, for example, the substrate 101 is placed in the MOVPE device and, over the n-type buffer layer (n-type InP layer) 104, as the waveguide non-doped optical guide layer 215, a non-doped AlGaInAs layer is formed. For example, the waveguide non-doped optical guide layer (non-doped AlGaInAs layer) 215 is crystal-grown, while a carrier gas and raw material gases are introduced into the device. As the carrier gas, hydrogen, nitrogen, or a gas mixture of hydrogen and nitrogen is used. As the raw material gases, trimethyl aluminum (TMAl), triethyl gallium (TEGa), trimethyl indium (TMIn), and AsH₃ as the gases containing the constituent elements of the group III-V compound semiconductor layer are used. The waveguide non-doped optical guide layer (non-doped AlGaInAs layer) 215 has a thickness of, e.g., about 50 nm.

Subsequently, over the waveguide non-doped optical guide layer 215, as the waveguide core layer 216, an AlInGaAs-based bulk semiconductor layer or a multiquantum well structure in which AlGaInAs well layers and AlGaInAs barrier layers are alternately stacked is crystal-grown. When the waveguide core layer (bulk AlGaInAs layer or the multiquantum well layer including AlGaInAs well layers and AlGaInAs barrier layers) 216 is deposited, as the respective raw materials of Al, Ga, In, and As, trimethyl aluminum (TMAl), triethyl gallium (TEGa), trimethyl indium (TMIn), and AsH₃ are used, and the flow rates of the raw materials of the group III elements (Al, Ga, In) are changed. This allows the AlGaInAs layers which are different in the composition of the group III elements to be stacked to have intended thicknesses. In the case of growing the multiquantum well structure, each of the AlGaInAs well layers is non-doped and has a film thickness of about 5 nm, while each of the AlGaInAs barrier layers is non-doped and has a film thickness of about 10 nm. The total thickness of the waveguide core layer 216 is about 0.1 μm to 1 μm. In the case of growing the bulk AlGaInAs layer, the total thickness of the waveguide core layer 216 is about 0.1 μm to 1 μm.

Subsequently, over the waveguide core layer (AlGaInAs well layers and AlGaInAs barrier layers) 216, as the waveguide non-doped optical guide layer 217, a non-doped AlGaInAs layer is formed. When the waveguide non-doped optical guide layer (non-doped AlGaInAs layer) 217 is deposited, as the respective raw materials of Al, Ga, In, and As, trimethyl aluminum (TMAl), triethyl gallium (TEGa), trimethyl indium (TMIn), and AsH₃ are used. The waveguide non-doped optical guide layer (non-doped AlGaInAs layer) 217 has a thickness of, e.g., about 50 nm.

By the steps described heretofore, over the n-type buffer layer (n-type InP layer) 104 exposed from the opening of the mask film 303, the multi-layer body is formed in which the waveguide non-doped optical guide layer 215, the waveguide core layer 216, and the waveguide non-doped optical guide layer 217 are successively stacked in the upward direction.

Subsequently, as the waveguide non-doped first clad layer 218, a non-doped InP layer is formed so as to cover the upper surface of the foregoing multi-layer body. For example, when the waveguide non-doped first clad layer (non-doped InP layer) 218 is deposited, as the respective raw materials of In and P, e.g., trimethyl indium (TMIn) and PH₃ are used. The waveguide non-doped first clad layer (non-doped InP layer) 218 has a thickness of, e.g., about 50 nm to 200 nm.

Thus, the mesa portion M3 including the foregoing multi-layer body (the waveguide non-doped optical guide layer 215, the waveguide core layer 216, and the waveguide non-doped optical guide layer 217) and the waveguide non-doped first clad layer 218 covering the foregoing multi-layer body can be formed. Thus, in accordance with the MOVPE method, by changing the raw material gases, it is possible to continuously form the individual layers included in the mesa portion. Note that, in the present second embodiment, over the n-type buffer layer (n-type InP layer) 104 exposed in the opening (area a in FIG. 80) outside the mask film 301 also, the same structure as the mesa portion M3 is grown, but does not function as an optical waveguide (see the both end portions in FIG. 85).

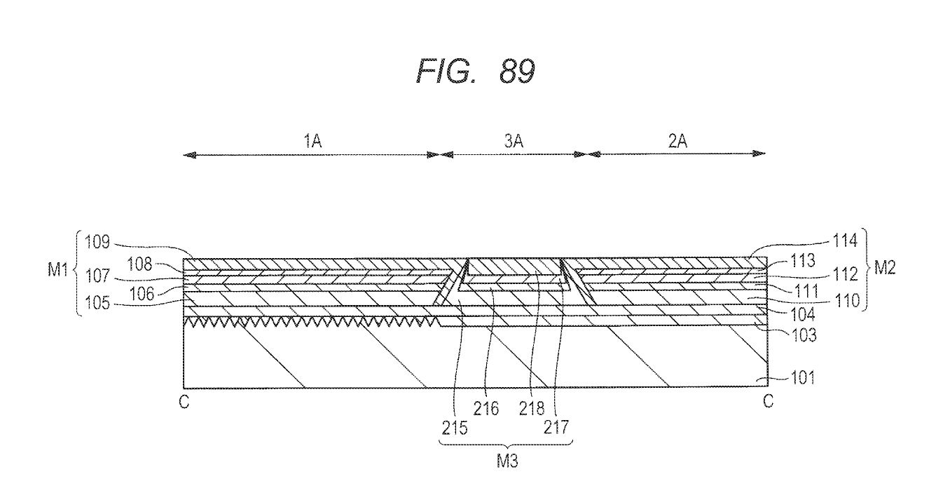

A description will be given herein of the respective shapes of the foregoing multi-layer body (the waveguide non-doped optical guide layer 215, the waveguide core layer 216, and the waveguide non-doped optical guide layer 217) and the mesa portion M3 including the foregoing multi-layer body. As shown in FIG. 88, the respective cross-sectional shapes of the foregoing multi-layer film and the mesa portion M3 in the X-direction (i.e., direction perpendicular to the mesa portion in the form of a stripe) are mesa shapes. In other words, the side walls of the foregoing multi-layer film and the mesa portion M3 extending in the X-direction have upwardly tapered shapes. As also shown in FIG. 89, the respective cross-sectional shapes of the foregoing multi-layer film and the mesa portion M3 in the Y-direction (i.e., direction parallel with the mesa portion in the form of a stripe) have mesa shapes. In other words, the side walls of the foregoing multi-layer film and the mesa portion M3 extending in the Y-direction have upwardly tapered shapes. In still other words, of the foregoing multi-layer film and the mesa portion M3, the side walls closer to the boundary with the mesa portion M1 or the mesa portion M2 have upwardly tapered shape. Note that, of the mesa portions M1 and M2, the side walls closer to the boundaries with the mesa portion M3 have downwardly tapered shapes or shapes closer thereto. Of the mesa portions M1 and M2, the side surfaces (end surfaces) opposite to those closer to the boundaries with the mesa portion M3 may also be the cleaved surfaces described later.

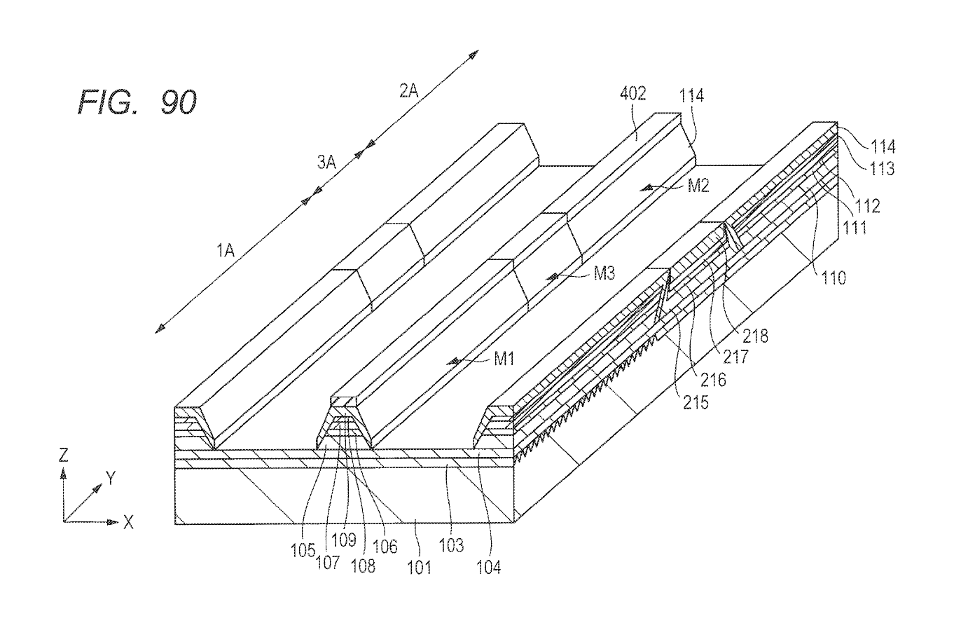

Thus, according to the present second embodiment, not only in the mesa portions M1 and M2, but also in the mesa portion M3, the waveguide non-doped first clad layer 218 is grown so as to cover the foregoing multi-layer body (the waveguide non-doped optical guide layer 215, the waveguide core layer 216, and the waveguide non-doped optical guide layer 217). Accordingly, even when the foregoing multi-layer body includes the semiconductor layers containing Al, it is possible to prevent these layers from being oxidized without exposing these layers to atmosphere. Next, as shown in FIG. 90, over the upper surfaces of the mesa portions M1, M2, and M3, a mask film 402 is formed.

For example, in the same manner as in the case in the first embodiment, a silicon oxide film is deposited over the entire surface using a thermal CVD method or the like and patterned to form the mask film 402 made of the silicon oxide film only over the upper surfaces of the mesa portions M1, M2, and M3.

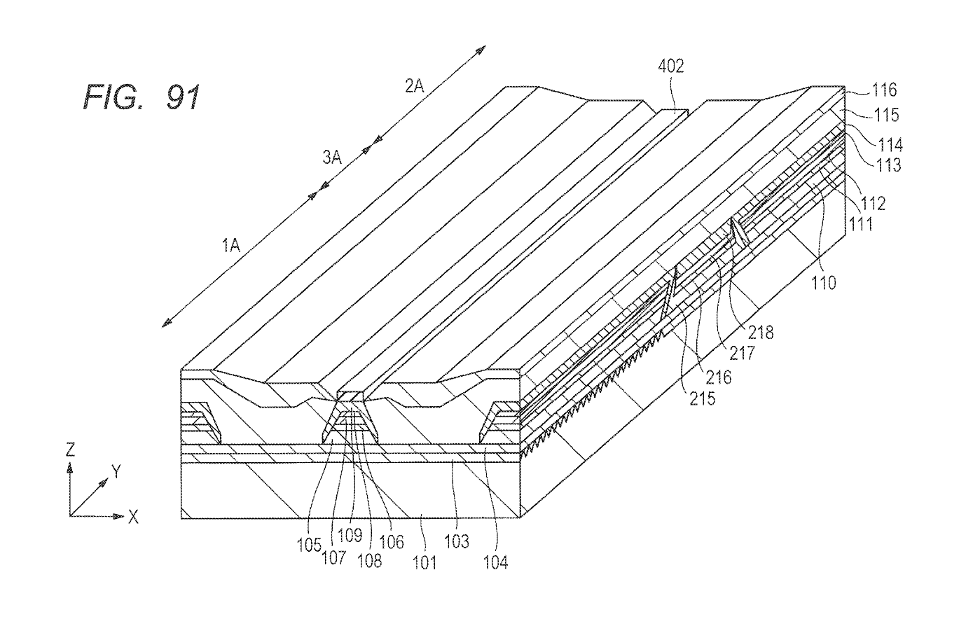

Next, as shown in FIG. 91, the current block layers 115 and 116 are formed so as to fill up the spaces on both sides of the mesa portions M1, M2, and M3. For example, in the same manner as in the case in the first embodiment, as the current block layer 115, an InP layer doped with Fe (Fe-doped InP layer) is formed. Subsequently, over the current block layer (Fe-doped InP layer) 115, an n-type InP layer is formed as the current block layer 116.

Next, the substrate 101 is retrieved from the MOVPE device, and the mask film (silicon oxide film) 402 over the substrate 101 is removed therefrom by etching.

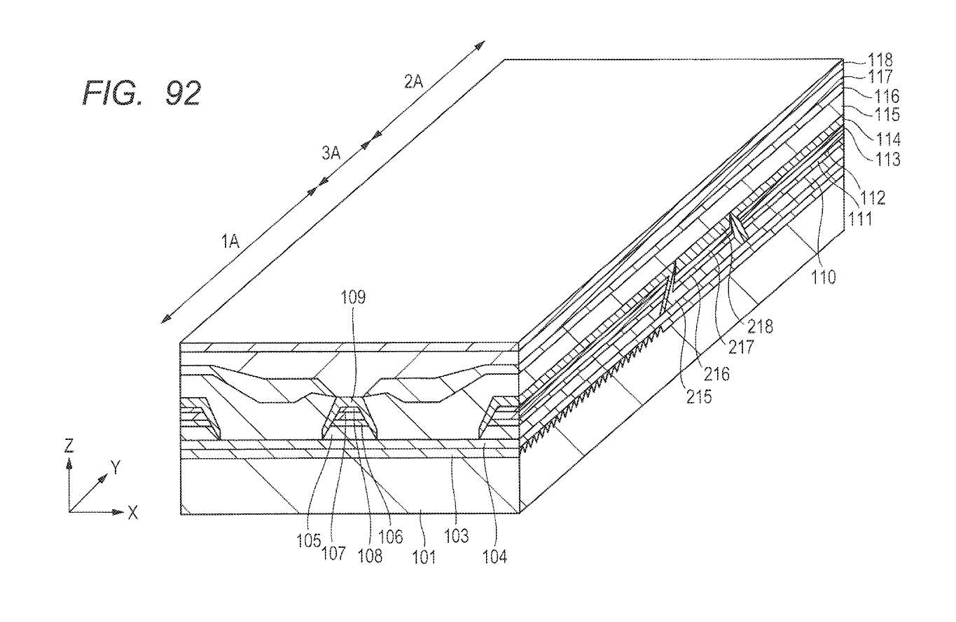

Next, as shown in FIGS. 92 to 96, in the same manner as in the case in the first embodiment, over the upper surfaces of the mesa portions M1, M2, and M3 and over the current block layer (n-type InP layer) 116, the p-type second clad layer (p-type InP layer) 117 is formed. Subsequently, the p-type contact layer (p-type InGaAs layer) 118 is formed thereover.

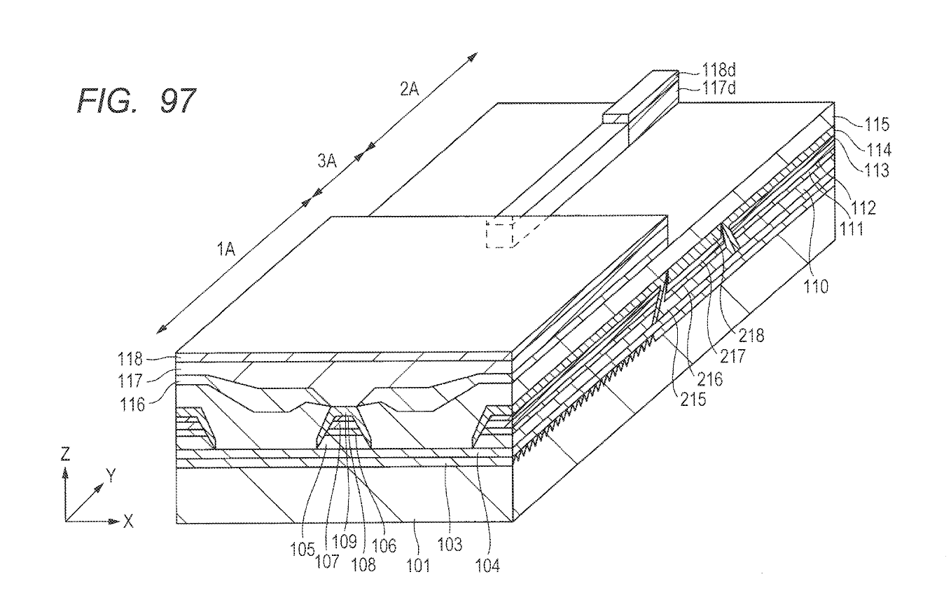

Next, as shown in FIG. 97, in the second area 2A and the third area 3A, the multi-layer body including the p-type second clad layer 117 and the p-type contact layer 118 is patterned. For example, in the same manner as in the case in the first embodiment, in the second area 2A and the third area 3A, the multi-layer body including the current block layer 116, the p-type second clad layer 117, and the p-type contact layer 118 except for the portions thereof located over the mesa portions M2 and M3 is etched. Then, in the third area 3A, the p-type contact layer 118 over the mesa portion M3 is etched.

Thus, in the second area 2A, a cubic multi-layer body including the p-type second clad layer 117d and the p-type contact layer 118d is formed. The multi-layer-body and the first area 1A are coupled together by the p-type second clad layer 117, but the p-type contact layer 118 in the first area 1A and the p-type contact layer 118d in the second area 2A are in discrete patterns.

Next, as shown in FIGS. 98 and 99, in the first area 1A, the LD insulating film 119 is formed while, in the second area 2A and the third area 3A, the modulator insulating film 120 is formed. For example, over the substrate 101, a silicon oxide film is deposited as the LD insulating film 119 using a CVD method or the like and patterned to be removed from over the mesa portion M1. Note that the silicon oxide film may also be left in the second area 2A and the third area 3A. Then, over the substrate 101, as the modulator insulating film 120, a polyimide film is formed by coating. By etching back the polyimide film in the first area 1A, the modulator insulating film (polyimide film) 120 is left in the second area 2A and the third area 3A.

Next, by removing the modulator insulating film 120 from over the p-type contact layer 118d by etching, the contact hole is formed (see FIG. 47). Then, over the substrate 101, e.g., a palladium (Pd) film and a platinum (Pt) film are successively formed by a vapor deposition method or the like.

Then, a multi-layer film (not shown) including the palladium (Pd) film and the platinum (Pt) film is patterned to form the LD p-side electrode 122 over the p-type contact layer 118 in the first area 1A and form the modulator p-type electrode 123 over the p-type contact layer 118d in the second area 2A. Then, a heating process is performed to alloy the respective metals forming the individual electrodes and make an ohmic contact with the semiconductor layer.

Next, assuming that the back surface of the substrate 101 is the upper surface thereof, the back surface of the substrate 101 is polished to reduce the film thickness of the substrate 101. Then, over the back surface of the substrate 101, e.g., a titanium (Ti) film and a gold (Au) film are successively formed by a vapor deposition method or the like. Then, a heating process is performed to alloy these metals and form the n-side electrode 121.

Then, the substrate 101 having a plurality of chip regions is cut into the individual chip regions. First, the substrate 101 is cleaved into the individual chip regions. Specifically, the substrate 101 is cleaved along a line of cleavage between a given chip region and a chip region adjacent thereto. Thus, cleavage surfaces (surfaces extending in the X-direction) are formed. Then, an anti-reflection film is formed over one of the cleavage surfaces, while a high-reflection film is formed over the other cleavage surface. As the anti-reflection film, a dielectric film having a reflectivity of, e.g., 0.1% is used. The film is formed by, e.g., a sputtering method or the like. As the high-reflection film, a dielectric multi-layer body having a reflectivity of not less than 75% is used. Each of the layers is formed by, e.g., a sputtering method or the like. Then, the substrate 101 is further cut along the sides of the chip regions extending in the Y-direction. Thus, the chip pieces are cut out. In the optical semiconductor integrated device, the length of the resonator of the laser element (length of the mesa portion in the Y-direction) is, e.g., 150 μm to 200 μm, while the length of the resonator of the modulator element (length of the mesa portion in the Y-direction) is, e.g., 50 μm to 200 μm. The length of the resonator of the optical waveguide (length of the mesa portion in the Y-direction) is, e.g., 50 μm to 200 μm.

By the foregoing steps, the optical semiconductor integrated device (EML in which the laser element and the modulator element are monolithically integrated) in the present second embodiment can be formed.

Note that, in the present second embodiment also, by growing the first clad layers (109, 114, and 218) as the semiconductor layers containing P (phosphorus) over the multi-layer bodies of the mesa portions M1, M2, and M3, it is possible to cover the multi-layer bodies with an excellent covering property. Also, as described with reference to FIG. 49, when the first clad layer (InP) is formed, the growth conditions are preferably a combination of the growth temperature and the growth speed which is determined within the region defined by connecting the four points (Tg,Rg)=(560,0.27) (660,0.27) (660,0.07) (560,0.07) (range enclosed by the solid line in FIG. 49).

### Third Embodiment

An object to which each of the optical semiconductor integrated devices (e.g., EMLs) described above in the first and second embodiment is applied is not limited. For example, the EML can be used in an optical communication system.

The optical communication system is applicable to, e.g., an optical communication system used for communication between data centers or the like. FIG. 100 is a block diagram showing an example of an optical communication system using an optical semiconductor integrated device in the present third embodiment.

As shown in FIG. 100, the optical communication system in the present third embodiment includes a transmitter 506, a receiver 513, and an optical fiber 507 coupling together the transmitter 506 and the receiver 513.

The transmitter 506 has a plurality of EMLs 501 to 504 having different oscillation wavelengths. Optical signals output from the EMLs 501 to 504 are joined together by an optical multiplexer 505 and transmitted to the optical fiber 507.

The receiver 513 has a plurality of light receiving elements 509 to 512 having different reception wavelengths. An optical signal transmitted from the transmitter 506 and propagated by the optical fiber 507 is divided on a per wavelength basis in an optical demultiplexer 508 and retrieved as information by each of the light receiving elements 509 to 512.

To the EMLs 501 to 504 in such an optical communication system, the laser elements described in the first and second embodiments can be applied.

By thus applying the optical semiconductor integrated device (e.g., EML) to the optical communication system, it is possible to implement a high-reliability optical communication system having excellent high-speed/high-temperature properties. For example, it is possible to implement an optical communication system for 100 GbE to 400 GbE data communication (e.g., a transceiver)).

While the invention achieved by the present inventors has been specifically described heretofore on the basis of the embodiments thereof, the present invention is not limited to the foregoing embodiments. It will be appreciated that various changes and modifications can be made in the invention within the scope not departing from the gist thereof.

For example, in each of the foregoing embodiments, the description has been given using the EML in which the laser element and the modulator element are formed in the same substrate. However, not only the modulator element, but also an optical amplification element, a photodiode such as a photodetector (light receiving element), or the like may be formed in the same substrate. The optical amplification element is allowed to have the same configuration (except that the structure has no diffraction grating) as that of the laser element (FIG. 47). The photodetector (light receiving element) is allowed to have the same configuration (in which the absorption layer may also be a bulk semiconductor layer) as that of the modulator element (FIG. 47).

Also, in each of the foregoing embodiments, the description has been given of the case where, in each of the elements other than the laser, the semiconductor layers containing Al (aluminum) are used as the semiconductor layers. However, as long as semiconductor layers containing Al (aluminum) are used at least in the laser element, the effects of the foregoing embodiments can be achieved. Accordingly, each of the elements other than the laser need not necessarily have semiconductor layers containing Al (aluminum).

1. An optical semiconductor integrated device, comprising:
a first mesa portion provided in a first area of a substrate and included in a laser element; and
a second mesa portion provided in a second area of the substrate and included in an element other than the laser,
wherein the first mesa portion includes:
a first semiconductor layer made of a group III-V compound semiconductor and formed over the first area of the substrate;
a second semiconductor layer made of a group III-V compound semiconductor and formed over the first semiconductor layer;
a third semiconductor layer made of a group III-V compound semiconductor and formed under the first semiconductor layer; and
a fourth semiconductor layer made of a group III-V compound semiconductor and covering an upper surface and each of side surfaces of a first multi-layer body including the first semiconductor layer, the second semiconductor layer, and the third semiconductor layer,
wherein the second mesa portion includes:
a fifth semiconductor layer made of a group III-V compound semiconductor and formed over the second area of the substrate;
a sixth semiconductor layer made of a group III-V compound semiconductor and formed over the fifth semiconductor layer; and
a seventh semiconductor layer made of a group III-V compound semiconductor and formed under the sixth semiconductor layer,
wherein the first semiconductor layer has a refractive index larger than that of each of the second semiconductor layer and the third semiconductor layer,
wherein at least any one of the first to third semiconductor layers contains an Al element as a constituent element, and
wherein the first semiconductor layer and the fifth semiconductor layer are optically coupled together, while the fourth semiconductor layer is provided between the first multi-layer body and a second multi-layer body including the fifth semiconductor layer, the sixth semiconductor layer, and the seventh semiconductor layer.

2. The optical semiconductor integrated device according to claim 1, further comprising:
an eighth semiconductor layer made of a group III-V compound semiconductor and covering an upper surface and each of side surfaces of the second multi-layer body including the fifth semiconductor layer, the sixth semiconductor layer, and the seventh semiconductor layer.

3. The optical semiconductor integrated device according to claim 2,
wherein the first mesa portion and the second mesa portion are connected in the form of a stripe.

4. The optical semiconductor integrated device according to claim 3,
wherein the first semiconductor layer is an active layer of the laser element, and
wherein the fifth semiconductor layer is an absorption layer of a modulator element.

5. The optical semiconductor integrated device according to claim 3,
wherein the first semiconductor layer is an active layer of the laser element, and
wherein the second mesa portion is included in an optical amplification element.

6. The optical semiconductor integrated device according to claim 3,
wherein the first semiconductor layer is an active layer of the laser element, and
wherein the second mesa portion is included in a photodiode.

7. The optical semiconductor integrated device according to claim 1, further comprising:
a third mesa portion provided between the first mesa portion and the second mesa portion,
wherein the third mesa portion includes:
a ninth semiconductor layer made of a group III-V compound semiconductor and formed over a third area of the substrate;
a tenth semiconductor layer made of a group III-V compound semiconductor and formed over the first semiconductor layer;
an eleventh semiconductor layer made of a group III-V compound semiconductor and formed under the first semiconductor layer; and
a twelfth semiconductor layer made of a group III-V compound semiconductor and covering a third multi-layer body including the ninth semiconductor layer, the tenth semiconductor layer, and the eleventh semiconductor layer.

8. The optical semiconductor integrated device according to claim 4,
wherein each of the first to third semiconductor layers contains an Al element and an As element as constituent elements, and
wherein the fourth semiconductor layer contains an In element and a P element as constituent elements.

9. A method of manufacturing an optical semiconductor integrated device, comprising the steps of:
(a) successively growing a first semiconductor layer, a second semiconductor layer, and a third semiconductor layer each made of a group Ill-V compound semiconductor in an upward direction in a first opening of a first mask film in a first area of a substrate to form a first multi-layer body;
(b) growing a fourth semiconductor layer covering an upper surface and each of side surfaces of the first multi-layer body;
(c) removing the first mask film; and
(d) successively growing a fifth semiconductor layer, a sixth semiconductor layer, and a seventh semiconductor layer each made of a group III-V compound semiconductor in the upward direction in a second opening of a second mask film in a second area of the substrate to form a second multi-layer body,
wherein the second semiconductor layer has a refractive index larger than that of each of the first semiconductor layer and the third semiconductor layer,
wherein at least any one of the first to third semiconductor layers includes an Al element as a constituent element, and
wherein, in the step (d), the first multi-layer body and the second multi-layer body are formed so as to be coupled together via the fourth semiconductor layer.

10. The method of manufacturing the optical semiconductor integrated device according to claim 9, further comprising, after the step (d), the steps of:
(e) removing the second mask film; and
(f) growing an eighth semiconductor layer covering an upper surface and each of side surfaces of the second multi-layer body.

11. The method of manufacturing the optical semiconductor integrated device according to claim 10,
wherein, in the step (d), a first mesa portion including the first multi-layer body and the fourth semiconductor layer and a second mesa portion including the second multi-layer body and the eighth semiconductor layer are connected in the form of a stripe.

12. The method of manufacturing the optical semiconductor integrated device according to claim 11,
wherein the second semiconductor layer is an active layer of a laser element, and
wherein the fifth semiconductor layer is an absorption layer of a modulator element.

13. The method of manufacturing the optical semiconductor integrated device according to claim 11,
wherein the second semiconductor layer is an active layer of a laser element, and
wherein the second mesa portion is included in an optical amplification element.

14. The method of manufacturing the optical semiconductor integrated device according to claim 11,
wherein the second semiconductor layer is an active layer of a laser element, and
wherein the second mesa portion is included in a photodiode.

15. The method of manufacturing the optical semiconductor integrated device according to claim 12,
wherein each of the first to third semiconductor layers contains an Al element and an As element as constituent elements, and
wherein the fourth semiconductor layer includes an In element and a P element as constituent elements.

16. A method of manufacturing an optical semiconductor integrated device, comprising the steps of:
(a) successively growing a first semiconductor layer, a second semiconductor layer, and a third semiconductor layer each made of a group III-V compound semiconductor in an upward direction in a first opening of a first mask film in a first area of a substrate to form a first multi-layer body;
(b) growing a fourth semiconductor layer covering an upper surface and each of side surfaces of the first multi-layer body;
(c) removing the first mask film; and
(d) successively growing a fifth semiconductor layer, a sixth semiconductor layer, and a seventh semiconductor layer each made of a group III-V compound semiconductor in the upward direction in a second opening of a second mask film in a second area of the substrate to form a second multi-layer body,
(e) growing an eighth semiconductor layer covering an upper surface and each of side surfaces of the second multi-layer body;
(f) removing the second mask film; and
(g) successively growing a ninth semiconductor layer, a tenth semiconductor layer, and an eleventh semiconductor layer each made of a group III-V compound semiconductor in the upward direction in a third opening of a third mask film in a third area of the substrate which is located between the first and second areas thereof to form a third multi-layer body,
wherein the second semiconductor layer has a refractive index larger than that of each of the first semiconductor layer and the third semiconductor layer,
wherein at least any one of the first to third semiconductor layers includes an Al element as a constituent element, and
wherein, in the step (d), the first multi-layer body and the second multi-layer body are formed so as to be coupled together via the fourth semiconductor layer.

17. The method of manufacturing the optical semiconductor integrated device according to claim 16,
wherein, in the step (g), the second multi-layer body and the third multi-layer body are formed so as to be coupled together via the eighth semiconductor layer.

18. The method of manufacturing the optical semiconductor integrated device according to claim 17, further comprising, after the step (g), the steps of:
(h) removing the third mask film; and
(i) growing a twelfth semiconductor layer covering the third multi-layer body.

19. The method of manufacturing the optical semiconductor integrated device according to claim 18,
wherein, in the step (i), a first mesa portion including the first multi-layer body and the fourth semiconductor layer, a second mesa portion including the second multi-layer body and the eighth semiconductor layer, and a third mesa portion including the third multi-layer body and the twelfth semiconductor layer are connected in the form of a stripe.

20. The method of manufacturing the optical semiconductor integrated device according to claim 16,
wherein the second semiconductor layer is an active layer of the laser element, and
wherein the sixth semiconductor layer is an absorption layer of a modulator element.

21. An optical communication system using the optical semiconductor integrated device according to claim 1.
